(19) United States
(12) Patent Application Publication
(10) Pub. No.: US 2018/0321493 A1
(43) Pub. Date: Nov. 8, 2018

(54) HMD AND METHOD FOR CONTROLLING SAME

(71) Applicant: LG ELECTRONICS INC., Seoul (KR)

(72) Inventors: Sumi KIM, Seoul (KR); Joonwon BYUN, Seoul (KR); Hyunju OH, Seoul (KR); Kyoungduck NAM, Seoul (KR); Yongjin KWON, Seoul (KR); Sangho KIM, Seoul (KR); Woochan JEONG, Seoul (KR); Sungjun PARK, Seoul (KR)

(73) Assignee: LG ELECTRONICS INC., Seoul (KR)

(21) Appl. No.: 15/773,230

(22) PCT Filed: Dec. 9, 2015
(86) PCT No.: PCT/KR2015/013413

§ 371 Date: May 3, 2018

(30) Foreign Application Priority Data
Nov. 11, 2015 (KR) 10-2015-0158307
Nov. 19, 2015 (KR) 10-2015-0162769
Nov. 19, 2015 (KR) 10-2015-0162771

(51) Int. Cl. G02B 27/01; G06F 3/01; G06F 3/041; H03K 17/955; G06T 19/00

(52) U.S. Cl. CPC G02B 27/0172; G06F 3/013; G06F 3/041; G02B 2027/0178; H03K 17/955; G06T 19/006; G02B 27/0176; G06F 3/017

(57) ABSTRACT

The present invention relates to a tethering type head mounted display (HMD) which is connected to a mobile terminal and a method for controlling the HMD. The HMD, which is connected to a mobile terminal, comprises: a communication unit for performing wired or wireless communication with the mobile terminal; a display unit for outputting image information; a detection unit for detecting a movement of the HMD; and a control unit for controlling the display unit so as to output image information which is controlled according to the result of detecting a movement of the HMD, wherein, when one of predetermined situations occurs, the control unit controls the display unit so as to output image information which is controlled according to a movement detected in the mobile terminal, and when the situation that has occurred ends, the control unit controls the display unit so as to output image information which is controlled according to a movement of the HMD.

### BACKGROUND OF THE INVENTION

### 1. Field of the Invention

The present disclosure relates to a tethering type HMD connected to a mobile terminal and a control method of the HMD.

### 2. Description of the Related Art

In recent years, wearable glasses-type terminals formed to be mountable on a part of a human body have been developed. Furthermore, a glasses-type terminal mounted on a head of a user may correspond to a head mounted display (HMD).

The head-mounted display (HMD) refers to a display device worn on a head of a user to present an image directly in front of the user's eyes, and the HMD may allow the user to enjoy image contents with an image larger than a TV or a screen or may display a virtual space screen to allow the user to enjoy a virtual space experience.

On the other hand, the functions of mobile terminals are becoming diversified these days due to the development of technologies. For example, the functions may include data and voice communication, photographing and video shooting through a camera, voice recording, music file playback through a speaker system, and displaying an image or video on a display unit. Some terminals further include an electronic game play function or perform a multimedia player function. In particular, in recent years, mobile terminals may receive multicast signals that provide visual content such as broadcast, video or television programs. Such a terminal has various functions according to the development of technologies. For example, a mobile terminal may be allowed to capture still images or moving images, play music or video files, play games, receive broadcast and the like, so as to be implemented as an integrated multimedia player.

Accordingly, a scheme of using such excellent mobile terminal functions in cooperation with the HMD is currently emerging. As a part of the effort of such a scheme, an HMD in which the HMD and the mobile terminal are connected to each other so that an amount of work of the HMD can be shared and processed by the mobile terminal, namely, tethering type HMD, has been developed.

The tethering type HMD connected to the mobile terminal as described above may reduce a workload of the HMD by allowing the connected mobile terminal and the HMD to cooperate with each other. Accordingly, the tethering type HMD does not require high performance as compared with a stand type HMD, in which the HMD carries out all tasks, and thus may be produced at a lower cost.

Meanwhile, such a mobile terminal may be used as an input device for entering an input signal to the tethering type HMD. Accordingly, a method for controlling a function executed in the HMD using a signal sensed or inputted from at least one of the HMD or the mobile terminal is being actively researched.

Furthermore, the tethering type HMD may provide various functions using the mobile terminal connected thereto. For example, the HMD may receive information on various functions executed in the connected mobile terminal, and display the received information, thereby allowing the user to check information on a function executed in the mobile terminal.

Accordingly, a method of allowing an HMD connected to the mobile terminal to more easily controlling a function executed in the mobile terminal, and allowing a user to check a function executed in the mobile terminal is being actively researched.

### SUMMARY OF THE INVENTION

An object of the present disclosure is to provide an HMD capable of preventing a problem of deadlock of control signals generated by simultaneously inputting control signals from a plurality of devices when there are the plurality of devices capable of inputting a control signal of the HMD, and a control method of the HMD.

Another object of the present disclosure is to provide an HMD for controlling the HMD through a device according to a user's selection or a device according to a specific situation sensed among the HMD or the controller device, and a control method of the HMD.

Still another object of the present disclosure is to provide an HMD capable of displaying an image in a virtual space in a direction difficult to display only by a head movement of a user wearing the HMD based on a user's input sensed from a mobile terminal connected to the HMD, and a control method of the HMD.

Yet still another object of the present disclosure is to provide an HMD capable of allowing a user to more easily check information related to a function executed in a mobile terminal according to the user's selection in the HMD connected to the mobile terminal, and a control method of the HMD.

In order to accomplish the foregoing or other objectives, according to an aspect of the present disclosure, there is provided an head mounted display (HMD) device connected to a mobile terminal, and the HMD may include a communication unit configured to perform wired or wireless communication with the mobile terminal, a display unit configured to display image information, a sensing unit configured to sense a movement of the HMD, and a controller configured to control the display unit to display image information controlled according to a result of sensing the movement of the HMD, wherein the controller controls the display unit to display image information controlled according to a movement sensed by the mobile terminal when any one of preset situations occurs, and controls the display unit to display image information controlled according to a movement of the HMD when the occurred situation is ended.

According to an embodiment, the display unit may display an image of a virtual space according to previously stored content, and the controller may control the display unit to display an image corresponding to a specific region of the virtual space according to a result of sensing the movement of the HMD, and control the display unit to display an image corresponding to another region of the virtual space, around an image of the virtual space displayed according to the movement of the HMD, according to a user input sensed from the mobile terminal when a specific situation is sensed, and control the display unit to display an image of the virtual space controlled according to the movement of the HMD when the sensed specific situation is ended.

According to an embodiment, the controller may display a menu screen for allowing a user to select an input for controlling an image of a virtual space displayed on the display unit on the display unit when the specific situation is sensed, and the menu screen may include menus for selecting either one of a movement of a user's head sensed through the HMD and a user input sensed through the mobile terminal or both the movement of the user's head and the user input as an input for controlling an image of the virtual space.

According to an embodiment, the controller may display either one menu according to the movement of the user's head sensed through the HMD or the user input sensed through the mobile terminal to be distinguished from the other menus, and control an image of a virtual space displayed on the display unit according to a control method corresponding to the either one of the menus displayed in a distinguished manner.

According to an embodiment, when the specific situation is sensed, the controller may display information on devices that control an additional graphic object or the displayed image of the virtual space on the displayed image, and indicate that the HMD is in a state where an image corresponding to another region of the virtual space is displayed based on both the user's head movement sensed by the HMD and the user input sensed by the mobile terminal.

According to an embodiment, the user's input sensed through the mobile terminal may be at least one of a drag input applied to a touch screen of the mobile terminal or an angular velocity or acceleration sensed by the mobile terminal.

According to an embodiment, the controller may control the display unit to display an image corresponding to another region of the virtual space according to the user's head movement sensed by the HMD or the user input sensed through the mobile terminal, based on a specific region preset to correspond to a forward direction of the HMD among regions of the virtual space, and change a preset specific region according to a user's selection to correspond to the forward direction of the HMD.

According to an embodiment, the display unit may display image information of content previously stored in the mobile terminal, and the controller may display image information controlled according to a result of sensing the movement of the HMD, execute a specific function of the mobile terminal according to a user's selection, display a screen related to the execution of the specific function controlled according to a user input sensed through the touch screen of the mobile terminal on the display unit, control the mobile terminal to restrict a user's control signal input when the image information of the content is displayed on the display unit, and control the mobile terminal to release the restricted user's control signal input when a specific user's input is sensed.

According to an embodiment, the specific function may be a function corresponding to an event occurred in the mobile terminal or a function selected according to a preset user's input among functions executable in the mobile terminal.

According to an embodiment, when the preset user's input is sensed, the controller may display graphic objects corresponding to functions executable in the mobile terminal, respectively, on at least a part of the display unit, and the specific function may be a function corresponding to any one of the graphic objects selected by a user.

According to an embodiment, the touch screen of the mobile terminal may be partitioned into a plurality of regions set to correspond to a plurality of different functions executable in the mobile terminal, respectively, and the specific function may be a function corresponding to any one of the plurality of regions in which the touch input is sensed.

According to an embodiment, the controller may display one point on the display unit corresponding to one point on the touch screen at which the touch input is sensed, on which a screen related to the execution of the specific function is displayed, in a distinguished manner, and determine that the touch input is applied to the one point displayed in a distinguished manner to control a function executed in the mobile terminal.

According to an embodiment, when a touch object that applies the touch input to the touch screen approaches within a predetermined distance from the touch screen, the controller may sense the touch object, and display a position of the sensed touch object on a screen related to the execution of the specific function.

According to an embodiment, the controller may set one region on the touch screen of the mobile terminal as a touch recognition region according to a user's input, and set each part of the touch recognition region to correspond to each part a region on the display unit displayed with a screen related to the execution of the specific function, and display one point on the display unit displayed with a screen related to the execution of the specific function corresponding to one point in the touch recognition region in which the touch input is sensed, in a distinguished manner.

According to an embodiment, when a touch recognition region is set on the touch screen, the controller may change the shape of a screen related to the execution of the specific function displayed on the display unit according to the shape of the set touch recognition region.

According to an embodiment, the controller may sense a case where a preset user's touch input is sensed on the touch screen of the mobile terminal or a specific touch input gesture is sensed through the mobile terminal as an event that the preset situation has occurred, and sense a case where a specific function executed according to the preset user's touch input or the specific touch input gesture is ended or the preset user's touch input or the specific touch input gesture is sensed again as an event that the occurred situation is ended.

According to an embodiment, the mobile terminal may operate in a doze mode when connected to the HMD, and the doze mode may be an operation state capable of sensing at least one of a touch input applied to the touch screen of the mobile terminal and a movement of the mobile terminal while a light emitting device of the touch screen of the mobile terminal is off.

According to an embodiment, the controller may further sense a case where specific image information is displayed on the display unit or the remaining amount of power of the HMD is less than a preset level as an event that any one of the preset situations has occurred, and sense a case where the display of the specific image information is ended or the remaining amount of power of the HMD is above the preset level as an event that the occurred situation is ended.

According to an embodiment, the specific image information may correspond to a specific graphic object, and the controller may display the specific image information corresponding to the specific graphic object on the display unit when a user gazes at one region on the display unit displayed with the specific graphic object for more than a predetermined period of time.

In order to accomplish the foregoing or other objectives, according to an aspect of the present disclosure, there is provided a method of controlling a head mounted display (HMD) connected to a mobile terminal, and the method may include displaying image information related to selected content on a display unit provided in the HMD, sensing a user's head movement through a sensor provided in the HMD, controlling image information displayed on the display unit according to the sensed movement, sensing an occurrence of a preset situation, sensing a movement of the mobile terminal based on the occurred specific situation, controlling image information displayed on the display unit according to the sensed movement of the mobile terminal, and controlling image information displayed on the display unit based on a movement sensed through the HMD when an end of the preset situation is sensed.

The effects of a mobile terminal according to the present disclosure and a control method thereof will be described as follows.

According to at least one of the embodiments of the present disclosure, the present disclosure may allow a specific device to be determined as a device for inputting a control signal of the HMD according to a user's selection or a sensed situation between the HMD and the controller device, thereby having an effect capable of preventing a problem that arises when control signals are input from the HMD and the controller device at the same time.

According to at least one of the embodiments of the present disclosure, the present disclosure may allow the HMD to be controlled through either one of the HMD and a controller device connected to the HMD, based on a user's selection or a sensed situation, thereby having an effect capable of controlling the HMD through a device according to the user's selection or a device more suitable for the detected situation.

According to at least one of the embodiments of the present disclosure, the present disclosure may allow screen information displayed on a display unit of the HMD to be controlled according to a user's head movement sensed through the HMD as well as a user's input received through a mobile terminal connected to the HMD, thereby displaying an image in a virtual space in a direction difficult to be displayed by only the head movement according to the user's input through the mobile terminal.

According to at least one of the embodiments of the present disclosure, the present disclosure may allow an execution screen of a specific function of a mobile terminal according to a user's selection to be displayed on the display unit of the HMD, thereby having an effect capable of allowing the user to more easily and conveniently check information on a function executed in the mobile terminal.

In addition, according to at least one embodiment of the present disclosure, the present disclosure may display one point on the execution screen corresponding to a point to which a touch input is applied on a touch screen of a mobile terminal in a distinguished manner, thereby allowing a user to control a function displayed on the execution screen by the touch input applied on the touch screen. Accordingly, the present disclosure may allow a desired function to be carried out in the mobile terminal even in a state in which the user wears the HMD, thereby having an effect capable of more easily controlling the executed function.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a block diagram for explaining a mobile terminal related to the present disclosure;

FIGS. 2A and 2B are block diagrams for explaining an HMD and a mobile terminal serving as a controller related to the present disclosure;

FIG. 3 is a flowchart for explaining an operation process of allowing an HMD related to the present disclosure to change a device for controlling image information displayed on the HMD;

FIG. 4 is a flowchart illustrating an operation process of allowing an HMD related to the present disclosure to change a device for controlling image information displayed on the HMD according to an amount of power of the HMD and a mobile terminal connected to the HMD;

FIG. 5 is a flowchart illustrating an operation process of allowing an HMD related to the present disclosure to change a device for controlling image information displayed on the HMD according to a graphic object displayed on a display unit;

FIG. 6 is an exemplary view illustrating an example of allowing an HMD related to the present disclosure to control screen information displayed on the HMD according to the movement of the HMD or controller device;

FIGS. 7A and 7B are exemplary views illustrating an example of allowing an HMD related to the present disclosure to sense a user input for changing a device that controls image information displayed on the HMD;

FIGS. 8A and 8B are exemplary views illustrating an example of screens displayed differently in an HMD related to the present disclosure according to a device that controls image information displayed in the HMD;

FIG. 9 is an exemplary view illustrating an example of allowing an HMD related to the present disclosure to change a device for controlling image information displayed in the HMD according to a graphic object displayed on a display unit;

FIGS. 10A and 10B are exemplary views illustrating an example of allowing an HMD related to the present disclosure to change a device for controlling image information displayed on the HMD according to the remaining amount of power of the devices;

FIG. 11 is a conceptual view for explaining an example of controlling image information displayed on a display unit according to a movement of a user wearing an HMD, in the HMD according to an embodiment of the present disclosure;

FIGS. 12A through 12D are conceptual views illustrating examples of allowing an HMD according to an embodiment of the present disclosure to display a virtual space image in different regions according to the movement of the HMD;

FIG. 13 is a flowchart illustrating an operation process of displaying an image in a virtual space according to an input sensed through an HMD and a mobile terminal connected thereto, in the HMD according to an embodiment of the present disclosure;

FIG. 14 is a flowchart illustrating an operation process of changing an image in a virtual space displayed on a display unit according to an input sensed through a mobile terminal during the operation process of FIG. 13;

FIGS. 15A through 15E are exemplary views illustrating examples of changing an image of a virtual space displayed on a display unit based on a user input sensed through an HMD and a mobile terminal connected thereto, in the HMD according to an embodiment of the present disclosure;

FIG. 16A is an exemplary view illustrating an example of screens displayed differently in an HMD related to the present disclosure according to a device that controls image information displayed in the HMD;

FIG. 16B is an exemplary view illustrating an example of displaying a menu for selecting device that controls image information displayed on a display unit, in an HMD 100 related to the present disclosure;

FIG. 17 is an exemplary view illustrating an example of setting an image of a virtual space corresponding to a front direction of an HMD, in the HMD according to an embodiment of the present disclosure;

FIG. 18 is a flowchart illustrating an operation process of displaying an execution screen of a specific function executed in a mobile terminal, in an HMD according to the embodiment of the present disclosure;

FIG. 19 is a flowchart illustrating an operation process of executing a specific function of a mobile terminal and displaying a screen related to the executed function according to a user's selection during the operation process of FIG. 18;

FIG. 20 is a flowchart illustrating an operation process of displaying one point on the execution screen corresponding to a touch input entered through a mobile terminal 200 in the HMD 100 according to the embodiment of the present disclosure;

FIGS. 21 through 23 are exemplary views illustrating examples of executing a specific function executable in a mobile terminal and displaying a screen related to the executed function on a display unit according to a user's selection, in the HMD according to an embodiment of the present disclosure;

FIG. 24 is an exemplary view illustrating an example of displaying contents being played back in an HMD or a menu for selecting a function execution of a mobile terminal according to a user's selection, in the HMD according to the embodiment of the present disclosure;

FIG. 25 is an exemplary view illustrating an example of displaying a touch input sensed through a region set in a mobile terminal on a display unit of an HMD, in the HMD according to the embodiment of the present disclosure; and

FIG. 26 illustrates an example of adjusting a size and shape of an execution screen of the specific function displayed on a display unit of an HMD according to a touch recognition region set through a mobile terminal, in the HMD according to the embodiment of the present disclosure.

### DETAILED DESCRIPTION OF THE INVENTION

Hereinafter, the embodiments disclosed herein will be described in detail with reference to the accompanying drawings, and the same or similar elements are designated with the same numeral references regardless of the numerals in the drawings and their redundant description will be omitted. A suffix “module” and “unit” used for constituent elements disclosed in the following description is merely intended for easy description of the specification, and the suffix itself does not give any special meaning or function. In describing the present disclosure, if a detailed explanation for a related known function or construction is considered to unnecessarily divert the gist of the present disclosure, such explanation has been omitted but would be understood by those skilled in the art. Also, it should be understood that the accompanying drawings are merely illustrated to easily explain the concept of the invention, and therefore, they should not be construed to limit the technological concept disclosed herein by the accompanying drawings, and the concept of the present disclosure should be construed as being extended to all modifications, equivalents, and substitutes included in the concept and technological scope of the invention.

Mobile terminals described herein may include cellular phones, smart phones, laptop computers, digital broadcasting terminals, personal digital assistants (PDAs), portable multimedia players (PMPs), navigators, slate PCs, tablet PCs, ultrabooks, wearable devices (for example, smart watches, smart glasses, head mounted displays (HMDs)), and the like.

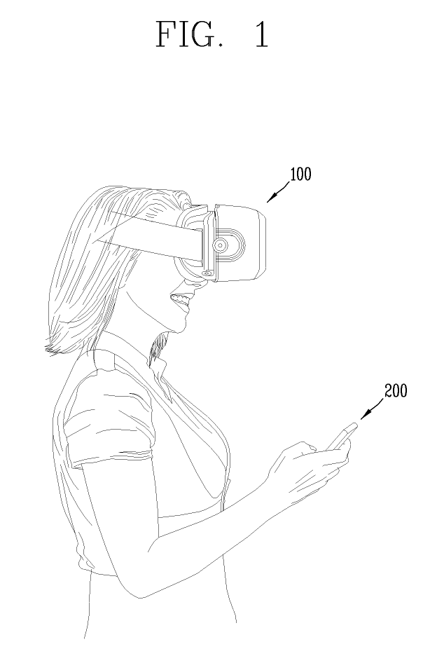

First, FIG. 1 illustrates an example of a tethering type HMD 100 according to the present disclosure connected to a mobile terminal 200.

As illustrated in FIG. 1, the HMD 100 according to an embodiment of the present disclosure may be connected to the mobile terminal 200. The mobile terminal 200 may be a variety of devices. For example, the mobile terminal 200 may be a smart phone, a tablet PC, or the like. Furthermore, the HMD 100 may receive information entered or signals sensed through the mobile terminal 200 or share various information, data or the like stored in the mobile terminal 200.

On the other hand, an image of a virtual space displayed on a display unit of the HMD 100 may be generated in the HMD 100 or may be generated in the mobile terminal 200 connected to the HMD 100. For example, when the image of the virtual space is generated in the HMD 100, the HMD 100 may perform image processing and rendering processing for processing an image in the virtual space, and display image information generated as a result of the image processing and rendering processing through the display unit. On the contrary, when the image of the virtual space is generated in the mobile terminal 200, the mobile terminal 200 may perform the image processing and rendering processing, and transmit image information generated as a result thereof to the HMD 100. Then, the HMD 100 may display image information received from the mobile terminal 200.

Meanwhile, the HMD 100 according to an embodiment of the present disclosure may receive a control signal for controlling a function of the HMD 100 from the mobile terminal 200. For example, the HMD 100 may receive a result of sensing the movement of the mobile terminal 200 from the mobile terminal 200, and control a function of the HMD 100 based on the sensing result. Alternatively, this control signal may be sensed by the HMD 100 itself. In other words, the HMD 100 may sense a head movement of a user wearing the HMD 100 using sensors provided in the HMD 100, and control a function of the HMD 100 based on the sensing result.

Here, controlling a function of the HMD 100 according to the movement of the mobile terminal 200 or the movement of the HMD 100 may denote displaying image information controlled according to the sensed movement of the mobile terminal 200 or the movement of the HMD 100. In other words, the HMD 100 according to the embodiment of the present disclosure may display an image of a virtual space in a direction corresponding to the movement of the mobile terminal 200 or the movement of the HMD 100 in the virtual space displayed on the display unit of the HMD 100. Using this, the HMD 100 may simulate the movement of the user in the virtual space or display a virtual space image in another direction according to the movement of the user's head.

Meanwhile, the mobile terminal 200 may share various information with the HMD 100. Accordingly, various information related to the mobile terminal 200 may be displayed on the display unit of the HMD 100, and the user may check events sensed in the mobile terminal 200 while viewing contents through the HMD 100.

In addition, various information related to the controller device 200 may be provided to the HMD 100 according to a function that can provided by the mobile terminal 200. Accordingly, as illustrated in FIG. 1, when the mobile terminal 200 is connected to the HMD 100 to perform the role of a controller device, functions that can be provided through the mobile terminal 200, including an e-mail function, a call function, a social network service (SNS) function, a message function such as a short messaging service (SMS) or a multimedia messaging service (MMS), and information related to a function according to various applications installed in the mobile terminal 200, and the like, may be displayed through the HMD 100.

As a result, the user may check an event occurred in the mobile terminal 200, such as receiving a call or message, news of SNS communities, various status information related to the mobile terminal 200 through the HMD 100.

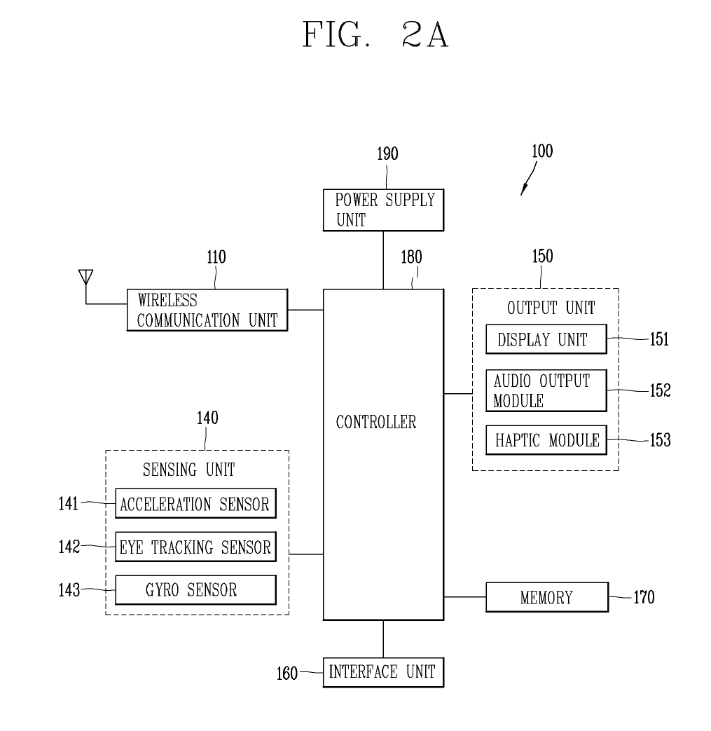

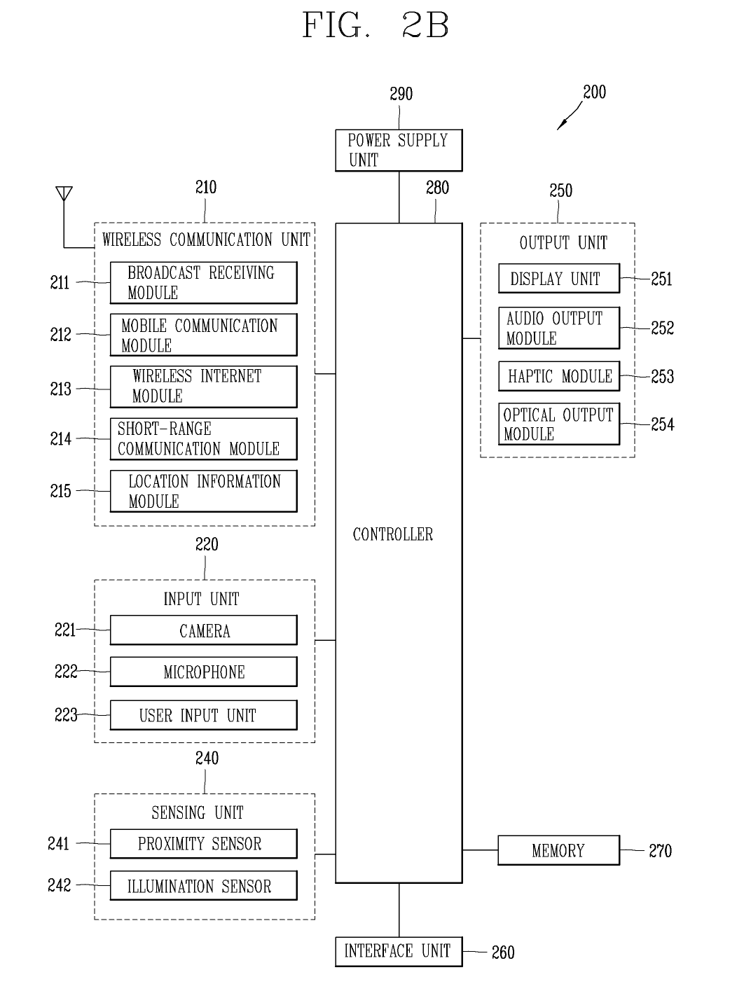

FIG. 2A is a block diagram for explaining the HMD 100 related to the present disclosure.

Referring to FIG. 2A, the HMD 100 according to an embodiment of the present disclosure may include a wireless communication unit 110, a sensing unit 140, an output unit 150, an interface unit 160, a memory 170, a controller 180, and a power supply unit 190 and the like. The components illustrated in FIG. 2A may not be necessarily required to implement the HMD 100 according to an embodiment of the present disclosure, and the HMD described herein may have a greater or less number of components than those illustrated above.

More specifically, the wireless communication unit 110 among the foregoing components may include one or more modules allowing wireless communications between the HMD 100 and various peripheral devices, for example, between the mobile terminal 200 and the HMD 100, or between the HMD 100 and an external server. Furthermore, the wireless communication unit may include at least one module connecting the HMD 100 to one or more networks.

Meanwhile, the sensing unit 140 may include at least one sensor for sensing a head movement of a user wearing the HMD 100. For example, the sensing unit 140 may include an acceleration sensor 141 and a gyro sensor 143. Here, the acceleration sensor 141 and the gyro sensor 143 may sense the acceleration and the angular velocity according to the head movement of the user.

In addition, the sensing unit 140 may further include an eye tracking sensor 142 for tracking a user's eyes and sensing where the user's eyes stay. For example, the eye tracking sensor 142 may detect a region on the display unit 151 corresponding to the position of the user's eyes to sense a direction of the user's gaze toward a specific region on the display unit 151.

The output unit 150 may be configured to output an audio signal, a video signal or a tactile signal. The output unit 150 may include a display unit 151, an audio output unit 152, a haptic module 153, and the like. The display unit 151 may be installed at a position corresponding to the user's both eyes when the user wears the HMD 100 so as to provide a larger size image to the user. The audio output unit 152 may be formed in the form of a headphone that can be brought into close contact with both ears of the user when the user wears the HMD 100 to transmit an audio signal related to the contents being played back. In addition, the haptic module 153 may generate vibrations related to the contents currently being played back to the user, as the need arises, thereby allowing the user to view the contents more realistically.

On the other hand, the interface unit 160 serves as an interface with various types of external devices that can be coupled to the HMD 100. The interface unit 160 may include at least one of various ports such as a wired/wireless headset port, an external charger port, and a wired/wireless data port. For example, when the HMD 100 and the mobile terminal 200 are connected in a wired manner, the interface unit 160 may serve an interface through which various data and information are exchanged between the HMD 100 and the mobile terminal 200.

In addition, the memory 170 stores data supporting various functions of the HMD 100. The memory 170 is typically implemented to store data to support various functions or features of the HMD 100. For instance, the memory 170 may be configured to store application programs executed in the HMD 100, data or instructions for operations of the HMD 100, and the like. At least part of those application programs may be downloaded from an external server via wireless communication. Moreover, at least part of those application programs may exist on the HMD 100 from the time of shipment for basic functions of the HMD 100 (for example, playback of contents and output of video signals and audio signals of contents being played back, and the like). On the other hand, the application programs may be stored in the memory 170, installed in the HMD 100, and executed by the controller 180 to perform an operation (or a function) of the HMD 100.

The controller 180 of the HMD 100 may typically control an overall operation of the HMD 100 in addition to the operations related to the application programs. The controller 180 may provide or process information or functions appropriate for a user in a manner of processing signals, data, information and the like, which are input or output by the aforementioned components, or activating the application programs stored in the memory 170.

Furthermore, the controller 180 may control at least part of the components illustrated in FIG. 2A, in order to drive the application programs stored in the memory 170. In addition, the controller 180 may drive the application programs by combining at least two of the components included in the HMD 100 for operation.

The power supply unit 190 may receive external power or internal power and supply appropriate power required for operating respective elements and components included in the HMD 100 under the control of the controller 180. The power supply unit 190 may include a battery, and the battery may be an embedded battery or a replaceable battery.

On the other hand, FIG. 2B is a block diagram for explaining the mobile terminal 200 connected to the HMD 100 associated with the present disclosure.

The mobile terminal 200 may include components, such as a wireless communication unit 210, an input unit 220, a sensing unit 240, an output unit 250, an interface unit 260, a memory 270, a controller 280, a power supply unit 290 and the like. The components illustrated in FIG. 2B may not be necessarily required to implement the HMD 200, and the HMD 200 described herein may have a greater or less number of components than those illustrated above.

More specifically, the wireless communication unit 210 of those components may typically include one or more modules which permit wireless communications between the mobile terminal 200 and a wireless communication system, between the mobile terminal 200 and another mobile terminal, or between the mobile terminal 200 and an external server. In addition, the wireless communication unit 210 may include one or more modules for connecting the mobile terminal 200 to one or more networks.

The wireless communication unit 210 may include at least one of a broadcast receiving module 211, a mobile communication module 212, a wireless Internet module 213, a short-range communication module 214, a location information module 215 and the like.

The input unit 220 may include a camera 221 for inputting an image signal, a microphone 222 or an audio input module for inputting an audio signal, or a user input unit 223 (for example, a touch key, a push key (or a mechanical key), etc.) for allowing a user to input information. Audio data or image data collected by the input unit 220 may be analyzed and processed by a user's control command.

The sensing unit 240 may include at least one sensor for sensing at least one of internal information of the mobile terminal 200, a surrounding environment of the mobile terminal 200 and user information. For example, the sensing unit 240 may include a proximity sensor 241, an illumination sensor 242, a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, refer to the camera 221), a microphone 222, a battery gage, an environment sensor (for example, a barometer, a hygrometer, a thermometer, a radiation detection sensor, a thermal sensor, a gas sensor, etc.), and a chemical sensor (for example, an electronic nose, a health care sensor, a biometric sensor, etc.). On the other hand, the mobile terminal disclosed herein may utilize information in such a manner of combining information sensed by at least two sensors of those sensors.

The output unit 250 may be configured to output an audio signal, a video signal or a tactile signal. The output unit 250 may include a display unit 251, an audio output unit 252, a haptic module 253, an optical output unit 254 and the like. The display unit 251 may have an inter-layered structure or an integrated structure with a touch sensor in order to facilitate a touch screen. The touch screen may provide an output interface between the mobile terminal 200 and a user, as well as functioning as the user input unit 223 which provides an input interface between the mobile terminal 200 and the user.

The interface unit 260 may serve as an interface with various types of external devices connected with the mobile terminal 200. The interface unit 260, for example, may include wired or wireless headset ports, external power supply ports, wired or wireless data ports, memory card ports, ports for connecting a device having an identification module, audio input/output (I/O) ports, video I/O ports, earphone ports, or the like. The mobile terminal 200 may execute an appropriate control associated with a connected external device, in response to the external device being connected to the interface unit 260.

In addition, the memory 270 stores data that support various functions of the mobile terminal 200. The memory 270 is typically implemented to store data to support various functions or features of the mobile terminal 200. For instance, the memory 170 may be configured to store application programs executed in the mobile terminal 200, data or instructions for operations of the mobile terminal 100, and the like. At least part of those application programs may be downloaded from an external server via wireless communication. Some others of those application programs may be installed within the mobile terminal 200 at the time of being shipped for basic functions of the mobile terminal 200 (for example, receiving a call, placing a call, receiving a message, sending a message, etc.). On the other hand, the application programs may be stored in the memory 270, installed in the mobile terminal 200, and executed by the controller 280 to perform an operation (or a function) of the mobile terminal 200.

The controller 280 may typically control an overall operation of the mobile terminal 200 in addition to the operations associated with the application programs. The controller 280 may provide or process information or functions appropriate for a user in a manner of processing signals, data, information and the like, which are input or output by the aforementioned components, or activating the application programs stored in the memory 270.

Furthermore, the controller 280 may control at least part of the components illustrated in FIG. 2B, in order to drive the application programs stored in the memory 270. In addition, the controller 280 may drive the application programs by combining at least two of the components included in the mobile terminal 200 for operation.

The power supply unit 290 may receive external power or internal power and supply appropriate power required for operating respective elements and components included in the mobile terminal 200 under the control of the controller 280. The power supply unit 290 may include a battery, and the battery may be an embedded battery or a replaceable battery.

At least part of those elements and components may be combined to implement the operation, control or control method of the mobile terminal 200 according to various exemplary embodiments described herein. Furthermore, the operation, control or control method of the mobile terminal 200 may be implemented in the mobile terminal in such a manner of activating at least one application program stored in the memory 270.

Hereinafter, each aforementioned component will be described in more detail with reference to FIG. 2B, prior to explaining various exemplary embodiments implemented by the mobile terminal 200 having the configuration.

First, the wireless communication unit 210 will be described. The broadcast receiving module 211 of the wireless communication unit 210 may receive a broadcast signal and/or broadcast associated information from an external broadcast managing entity via a broadcast channel. The broadcast channel may include a satellite channel and/or a terrestrial channel. At least two broadcast receiving modules may be provided in the HMD 200 to simultaneously receive at least two broadcast channels or switch the broadcast channels.

The mobile communication module 212 may transmit/receive wireless signals to/from at least one of network entities, for example, a base station, an external terminal, a server, and the like, on a mobile communication network, which is constructed according to technical standards or transmission methods for mobile communications (for example, Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), etc.)

The wireless signals may include audio call signal, video (telephony) call signal, or various formats of data according to transmission/reception of text/multimedia messages.

The wireless Internet module 213 refers to a module for supporting wireless Internet access, and may be built-in or externally installed on the mobile terminal 200. The wireless Internet module 213 may transmit and/or receive wireless signals via communication networks according to wireless Internet technologies.

Examples of such wireless Internet access may include Wireless LAN (WLAN), Wireless-Fidelity (Wi-Fi), Wireless Fidelity Direct (Wi-Fi Direct), Digital Living Network Alliance (DLNA), Wireless Broadband (WiBro), World Interoperability for Microwave Access (WiMAX), High Speed Downlink Packet Access (HSDPA), High Speed Uplink Packet Access (HSUPA), LTE (Long Term Evolution), LTE-A (Long Term Evolution-Advanced), and the like. The wireless Internet module 213 may transmit/receive data according to at least one wireless Internet technology within a range including even Internet technologies which are not aforementioned.

From the perspective that the wireless Internet accesses according to Wibro, HSDPA, GSM, CDMA, WCDMA, LTE, LTE-A and the like are executed via a mobile communication network, the wireless Internet module 213 which performs the wireless Internet access via the mobile communication network may be understood as a type of the mobile communication module 212.

The short-range communication module 214 denotes a module for short-range communications. Suitable technologies for implementing the short-range communications may include BLUETOOTH™, Radio Frequency IDentification (RFID), Infrared Data Association (IrDA), Ultra-WideBand (UWB), ZigBee, Near Field Communication (NFC), Wireless-Fidelity (Wi-Fi), Wi-Fi Direct, and the like. The short-range communication module 214 may support wireless communications between the mobile terminal 200 and a wireless communication system, between the mobile terminal 200 and another mobile terminal, or between the mobile terminal and a network where another mobile terminal (or an external server) is located wireless personal area networks. The short-range communication module 114 denotes a module for short-range communications.

Here, the another mobile terminal may be a wearable device, for example, a smart watch, smart glasses or a head mounted display (HMD), which is able to exchange data with the mobile terminal 200 (or to link data with the mobile terminal). The short-range communication module 214 may sense (recognize) a wearable device, which is able to communicate with the mobile terminal 200), near the mobile terminal 200. In addition, when the sensed wearable device is a device which is authenticated to communicate with the mobile terminal 200 according to the present disclosure, the controller 280 may transmit at least part of data processed in the mobile terminal 200 to the wearable device via the short-range communication module 214. Hence, a user of the wearable device may use the data processed in the mobile terminal 200 on the wearable device. For example, when a call is received in the mobile terminal 200, the user may answer the call using the wearable device. Also, when a message is received in the mobile terminal 200, the user can check the received message using the wearable device.

The location information module 215 is generally configured to detect, calculate, derive or otherwise identify a position of the mobile terminal 200. As an example, the location information module 115 includes a Global Position System (GPS) module, a Wi-Fi module, or both. For example, when the mobile terminal uses the GPS module to acquire a location of the mobile terminal 200 using a signal sent from a GPS satellite. As another example, when the mobile terminal 200 uses the Wi-Fi module, a position of the mobile terminal 200 may be acquired based on information related to a wireless access point (AP) which transmits or receives a wireless signal to or from the Wi-Fi module. According to the need, the location information module 215 may perform any function of the other modules of the wireless communication unit 210 to obtain data on the location of the mobile terminal 200. As a module used to acquire the location (or current location) of the mobile terminal 200, the location information module 215 may not be necessarily limited to a module for directly calculating or acquiring the location of the mobile terminal 200.

Next, the input unit 220 may be configured to provide image information (or signal), audio information (or signal), data, or enter information received from the user, and the mobile terminal 200 may include one or a plurality of cameras 221 to enter image information. The camera 221 processes a image frame, such as still picture or video, obtained by an image sensor in a video phone call or image capturing mode. The processed image frames may be displayed on the display unit 251 or stored in the memory 270. On the other hand, the plurality of cameras 221 disposed in the mobile terminal 200 may be arranged in a matrix configuration. By use of the cameras 221 having the matrix configuration, a plurality of image information having various angles or focal points may be input into the mobile terminal 200. As another example, the cameras 221 may be located in a stereoscopic arrangement to acquire left and right images for implementing a stereoscopic image.

The microphone 222 may process an external audio signal into electric audio data. The processed audio data may be utilized in various manners according to a function being executed in the mobile terminal 200 (or an application program being executed). On the other hand, the microphone 222 may include assorted noise removing algorithms to remove noise generated in the course of receiving the external audio signal.

The user input unit 223 may receive information input by a user. When information is input through the user input unit 223, the controller 280 may control an operation of the mobile terminal 200 to correspond to the input information. The user input unit 223 may include one or more of a mechanical input element (for example, a key, a button located on a front and/or rear surface or a side surface of the mobile terminal 200, a dome switch, a jog wheel, a jog switch, and the like), or a touch-sensitive input, among others. As one example, the touch-sensitive input may be a virtual key or a soft key, which is displayed on a touch screen through software processing, or a touch key which is located on the mobile terminal at a location that is other than the touch screen. On the other hand, the virtual key or the visual key may be displayed on the touch screen in various shapes, for example, graphic, text, icon, video, or a combination thereof.

On the other hand, the sensing unit 240 may sense at least one of internal information of the mobile terminal 200, surrounding environment information of the mobile terminal 200 and user information, and generate a sensing signal corresponding to it. The controller 280 may control an operation of the mobile terminal 200 or execute data processing, a function or an operation associated with an application program installed in the mobile terminal 200 based on the sensing signal. Hereinafter, description will be given in more detail of representative sensors of various sensors which may be included in the sensing unit 240.

First, a proximity sensor 241 refers to a sensor to sense presence or absence of an object approaching to a surface to be sensed, or an object disposed near a surface to be sensed, by using an electromagnetic field or infrared rays without a mechanical contact. The proximity sensor 241 may be arranged at an inner region of the mobile terminal 200 covered by the touch screen, or near the touch screen.

The proximity sensor 241, for example, may include any of a transmissive type photoelectric sensor, a direct reflective type photoelectric sensor, a mirror reflective type photoelectric sensor, a high-frequency oscillation proximity sensor, a capacitance type proximity sensor, a magnetic type proximity sensor, an infrared rays proximity sensor, and the like. When the touch screen is implemented as a capacitance type, the proximity sensor 241 may sense proximity of a pointer to the touch screen by changes of an electromagnetic field, which is responsive to an approach of an object with conductivity. In this case, the touch screen (touch sensor) may also be categorized as a proximity sensor.

On the other hand, for the sake of brief explanation, a behavior in which the pointer is positioned to be proximate onto the touch screen without contact will be referred to as “proximity touch,” whereas a behavior in which the pointer substantially comes into contact with the touch screen will be referred to as “contact touch.” For the position corresponding to the proximity touch of the pointer on the touch screen, such position will correspond to a position where the pointer faces perpendicular to the touch screen upon the proximity touch of the pointer. The proximity sensor 241 may sense proximity touch, and proximity touch patterns (e.g., distance, direction, speed, time, position, moving state, etc.). On the other hand, the controller 280 may process data (or information) corresponding to the proximity touches and the proximity touch patterns sensed by the proximity sensor 241, and output visual information corresponding to the process data on the touch screen. In addition, the controller 280 may control the mobile terminal 200 to execute different operations or process different data (or information) according to whether a touch with respect to the same point on the touch screen is either a proximity touch or a contact touch.

A touch sensor can sense a touch applied to the touch screen, such as display unit 251, using any of a variety of touch methods. Examples of such touch methods include a resistive type, a capacitive type, an infrared type, and a magnetic field type, among others.

As one example, the touch sensor may be configured to convert changes of pressure applied to a specific part of the display unit 251 or a capacitance occurring from a specific part of the display unit 151, into electric input signals. Also, the touch sensor may be configured to sense not only a touched position and a touched area, but also touch pressure. Here, the touch object body may be a finger, a touch pen or stylus pen, a pointer, or the like as an object through which a touch is applied to the touch sensor.

When a touch input is sensed by a touch sensor, corresponding signals may be transmitted to a touch control device. The touch control device may process the received signals, and then transmit corresponding data to the controller 280. Accordingly, the controller 280 may sense which region of the display unit 251 has been touched. Here, the touch control device may be a component separate from the controller 280 or the controller 280 itself.

On the other hand, the controller 280 may execute a different control or the same control according to a type of an object which touches the touch screen (or a touch key provided in addition to the touch screen). Whether to execute the different control or the same control according to the object which gives a touch input may be decided based on a current operating state of the mobile terminal 200 or a currently executed application program.

Meanwhile, the touch sensor and the proximity sensor may be executed individually or in combination, to sense various types of touches, such as a short (or tap) touch, a long touch, a multi-touch, a drag touch, a flick touch, a pinch-in touch, a pinch-out touch, a swype touch, a hovering touch, and the like.

An ultrasonic sensor may be configured to recognize position information relating to a sensing object by using ultrasonic waves. The controller 280 may calculate a position of a wave generation source based on information sensed by an illumination sensor and a plurality of ultrasonic sensors. Since light is much faster than ultrasonic waves, a time for which the light reaches the optical sensor may be much shorter than a time for which the ultrasonic wave reaches the ultrasonic sensor. The position of the wave generation source may be calculated using this fact. For instance, the position of the wave generation source may be calculated using the time difference from the time that the ultrasonic wave reaches the sensor based on the light as a reference signal.

The camera 221 constructing the input unit 220 may be a type of camera sensor. The camera sensor may include at least one of a photo sensor (or image sensor) and a laser sensor.

Implementing the camera 221 with a laser sensor may allow detection of a touch of a physical object with respect to a 3D stereoscopic image. The camera 121 and the laser sensor may be combined to detect a touch of the sensing object with respect to a 3D stereoscopic image. More specifically, the photo sensor is integrated with photo diodes and transistors in the rows and columns thereof, and a content placed on the photo sensor may be scanned by using an electrical signal that is changed according to the amount of light applied to the photo diode. In other words, the photo sensor may calculate the coordinates of the sensing object according to variation of light to thus obtain position information of the sensing object.

The display unit 251 may display (output) information processed in the mobile terminal 200. For example, the display unit 251 may display an execution screen information of an application program driven by the mobile terminal 200 or user interface (UI) or graphic user interface (GUI) information based on the execution screen information.

Furthermore, the display unit 251 may also be implemented as a stereoscopic display unit for displaying stereoscopic images.

The stereoscopic display unit may employ a stereoscopic display scheme such as stereoscopic scheme (a glass scheme), an auto-stereoscopic scheme (glassless scheme), a projection scheme (holographic scheme), or the like.

The audio output module 252 is generally configured to output audio data. Such audio data may be obtained from any of a number of different sources, such that the audio data may be received from the wireless communication unit 210 or may have been stored in the memory 270. Also, the audio output module 252 may also provide audible output signals associated with a particular function (e.g., a call signal reception sound, a message reception sound, etc.) carried out by the mobile terminal 200. The audio output module 252 may include a receiver, a speaker, a buzzer or the like.

A haptic module 253 may generate various tactile effects the that user may feel. A typical example of the tactile effect generated by the haptic module 253 may be vibration. Strength, pattern and the like of the vibration generated by the haptic module 253 may be controllable by a user selection or setting of the controller. For example, the haptic module 253 may output different vibrations in a combining manner or a sequential manner.

Besides vibration, the haptic module 253 may generate various other tactile effects, including an effect by stimulation such as a pin arrangement vertically moving with respect to a contact skin, a spray force or suction force of air through a jet orifice or a suction opening, a touch on the skin, a contact of an electrode, electrostatic force, etc., an effect by reproducing the sense of cold and warmth using an element that can absorb or generate heat, and the like.

The haptic module 253 may be configured to transmit tactile effects through a user's direct contact, or a user's muscular sense using a finger or a hand. Two or more haptic modules 253 may be provided according to the particular configuration of the mobile terminal 200.

An optical output module 254 may output a signal for indicating an event generation using light of a light source of the mobile terminal 200. Examples of events generated in the mobile terminal 200 may include a message reception, a call signal reception, a missed call, an alarm, a schedule notice, an email reception, an information reception through an application, and the like.

A signal output by the optical output module 254 may be implemented in such a manner that the mobile terminal 200 emits monochromatic light or light with a plurality of colors. The signal output may be terminated as the mobile terminal 200 senses a user's event checking.

The interface unit 260 serves as an interface for external devices to be connected with the mobile terminal 200. For example, the interface unit 260 can receive data transmitted from an external device, receive power to transfer to elements and components within the mobile terminal 200, or transmit internal data of the mobile terminal 200 to such external device. The interface unit 260 may include wired or wireless headset ports, external power supply ports, wired or wireless data ports, memory card ports, ports for connecting a device having an identification module, audio input/output (I/O) ports, video I/O ports, earphone ports, or the like.

The identification module may be a chip that stores various information for authenticating authority of using the mobile terminal 200 and may include a user identity module (UIM), a subscriber identity module (SIM), a universal subscriber identity module (USIM), and the like. In addition, the device having the identification module (also referred to herein as an “identification device”) may take the form of a smart card. Accordingly, the identifying device may be connected with the mobile terminal 200 via the interface unit 260.

Furthermore, when the mobile terminal 200 is connected with an external cradle, the interface unit 260 may serve as a passage to allow power from the cradle to be supplied to the mobile terminal 200 therethrough or may serve as a passage to allow various command signals input by the user from the cradle to be transferred to the mobile terminal therethrough. Such various command signals or power inputted from the cradle may operate as signals for recognizing that the mobile terminal 200 has accurately been mounted to the cradle.

The memory 270 can store programs to support operations of the controller 280 and store input/output data (for example, phonebook, messages, still images, videos, etc.). The memory 270 may store data associated with various patterns of vibrations and audio which are output in response to touch inputs on the touch screen.

The memory 270 may include at least one type of storage medium including a Flash memory, a hard disk, a multimedia card micro type, a card-type memory (e.g., SD or DX memory, etc.), a Random Access Memory (RAM), a Static Random Access Memory (SRAM), a Read-Only Memory (ROM), an Electrically Erasable Programmable Read-Only Memory (EEPROM), a Programmable Read-Only memory (PROM), a magnetic memory, a magnetic disk, and an optical disk. Also, the mobile terminal 200 may be operated in relation to a web storage device that performs the storage function of the memory 270 over the Internet.

As aforementioned, the controller 280 may typically control the general operations of the mobile terminal 200. For example, the controller 280 may set or release a lock state for restricting a user from inputting a control command with respect to applications when a state of the mobile terminal meets a preset condition.

Furthermore, the controller 280 may also perform controlling and processing associated with voice calls, data communications, video calls, and the like, or perform pattern recognition processing to recognize a handwriting input or a picture drawing input performed on the touch screen as characters or images, respectively. In addition, the controller 280 may control one or combination of those components in order to implement various exemplary embodiment disclosed herein on the mobile terminal 200.

The power supply unit 290 may receive external power or internal power and supply appropriate power required for operating respective elements and components included in the HMD 100 under the control of the controller 280. The power supply unit 190 may include a battery, which is typically rechargeable or be detachably coupled to the terminal body for charging.

Furthermore, the power supply unit 290 may include a connection port. The connection port may be configured as one example of the interface unit 260 to which an external (re)charger for supplying power to recharge the battery is electrically connected.

As another example, the power supply unit 290 may be configured to recharge the battery in a wireless manner without use of the connection port. Here, the power supply unit 290 may receive power, transferred from an external wireless power transmitter, using at least one of an inductive coupling method which is based on magnetic induction or a magnetic resonance coupling method which is based on electromagnetic resonance.

Various embodiments described herein may be implemented in a computer-readable or its similar medium using, for example, software, hardware, or any combination thereof.

Meanwhile, the mobile terminal 200 according to the present disclosure may operate in a specific mode in which the minimum current or power is consumed even in a state where the display unit 251 of the mobile terminal 200 is in an inactive state, to sense the type through the acceleration sensor or the touch sensor. Such a specific mode may be referred to as a “doze mode.”

For example, the doze mode may be a state in which only a light emitting device for displaying a screen in the display unit 251 is turned off, and the sensor maintains an on state in a touch screen structure in which the touch sensor and the display unit 251 constitutes an interlayer structure. Alternatively, the doze mode may be a mode in which the display unit 251 is turned off and the acceleration sensor maintains an on state. Alternatively, the doze mode may be a mode in which the display unit 251 is turned off and both the touch sensor and the acceleration sensor maintain an on state.

Therefore, in the doze mode state, that is, when the illumination of the display unit 251 is turned off, or when the display unit 251 is turned off (the display unit 251 is in an inactive state), when the tap is applied to at least one point on the display unit 251 or a specific point of the main body of the mobile terminal 200, it may be possible to sense that the tap is applied from the user through at least one of the touch sensor or acceleration sensor that is turned on.

Hereinafter, embodiments related to a control method that can be implemented in the HMD 100 according to an embodiment of the present disclosure will be described with reference to the accompanying drawings. It should be understood by those skilled in the art that the present disclosure can be embodied in other specific forms without departing from the concept and essential characteristics thereof.

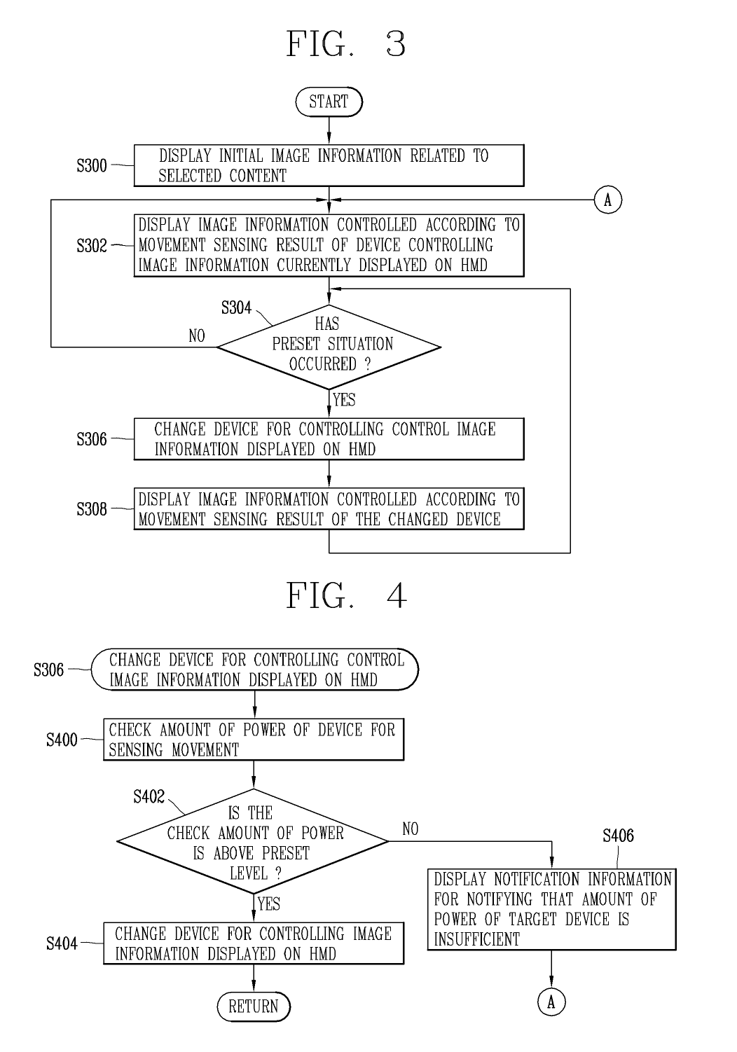

FIG. 3 is a flowchart for explaining an operation process of allowing an HMD related to the present disclosure to change a device that controls image information displayed on the HMD.

Referring to FIG. 3, the controller 180 of the HMD 100 according to the embodiment of the present disclosure may display initial image information corresponding to the selected content on the display unit 151 (S300). Here, the image information may be generated in the HMD 100 or may be generated in the mobile terminal 200 connected to the HMD 100. Then, if the image information is generated from the mobile terminal 200, the controller 180 may control the mobile terminal 200 to generate the image information through the mobile terminal 200, and receive the image information generated from the mobile terminal 200, and display the received image information on the display unit 151 of the HMD 100. On the other hand, image information generated as described above may be related to a virtual space experience or related to a specific multimedia data according to the selected content. However, in the following description, it will be described on the assumption that image information is related to a virtual space experience for the sake of convenience of explanation.

Meanwhile, when the image information is displayed as described above, the controller 180 of the HMD 100 may sense the movement of a device set to an object to sense a current movement. Then, the controller 180 may control image information displayed on the display unit 151 according to the sensed movement result (S302).

As described above, it has been mentioned that the HMD 100 according to an embodiment of the present disclosure can control image information displayed on the display unit 151 of the HMD 100 according to an input signal sensed from the HMD 100 or the mobile terminal 200. Furthermore, here, the input signal sensed from the HMD 100 or the mobile terminal 200 may be a result of sensing the movement of the HMD 100 or the mobile terminal 200.

In other words, when the HMD 100 is set as a device to control image information currently displayed on the HMD 100, the HMD 100 may sense the movement of the HMD 100 generated according to a movement of the user's head, through at least one of sensors (for example, the acceleration sensor 141 and the gyro sensor 143) included in the sensing unit 140. Then, the controller 180 may display a virtual space image in a direction corresponding to the sensed movement on the display unit 151 to display image information controlled according to a result of sensing the movement of the HMD 100 on the display unit 151.

Here, if the image information is generated from the HMD 100, the controller 180 of the HMD 100 may display image information on the virtual space image in a specific direction based on a result of sensing the movement of the HMD 100. On the contrary, when the image information is generated from the mobile terminal 200, the controller 180 of the HMD 100 may transmit a result of sensing the movement of the HMD 100 to the mobile terminal 200. Then, the mobile terminal 200 may control the mobile terminal 200 to generate image information for a virtual space image in a specific direction based on a result of sensing the movement of the HMD 100. Then, image information generated from the mobile terminal 200 may be received and displayed on the display unit 151. On the contrary, when the mobile terminal 200 is set as a device to control image information currently displayed on the HMD 100, the HMD 100 may display image information controlled according to a result of sensing the movement of the mobile terminal 200 on the display unit 151. In this case, the HMD 100 may allow the controller 280 of the mobile terminal 200 to sense the movement of the mobile terminal 200. The controller 280 of the mobile terminal 200 may sense the movement of the mobile terminal 200 using at least one sensor included in the sensing unit 240 of the mobile terminal 200.

Here, when the image information is generated from the HMD 100, the controller 180 of the HMD 100 may receive a result of sensing the movement from the mobile terminal 200. Then, the controller 180 may display image information for a virtual space image in a specific direction corresponding to the movement sensing result of the mobile terminal 200. On the contrary, when the image information is generated from the mobile terminal 200, the controller 180 of the HMD 100 may control the mobile terminal 200 to generate image information for a virtual space image in a specific direction corresponding to the movement sensing result of the mobile terminal 200. Then, image information generated from the mobile terminal 200 may be received and displayed on the display unit 151.

Meanwhile, in the step S302, the controller 180 may sense whether or not a preset specific situation has occurred in a state where image information is displayed according to a result of sensing the movement of any one device (S304). Then, the controller 180 may change a device (hereinafter, referred to as a “control device”) for controlling image information displayed on the HMD 100 when the preset situation occurs as a sensing result of the step S304 (S306).

Here, the preset specific situation may include various situations.

For an example, the preset specific situation may be a preset gesture or touch input or a user, or the like. In other words, when a user takes a specific gesture while wearing the HMD 100 or takes a specific gesture while holding the mobile terminal 200, the controller 180 of the HMD 100 may sense that a specific situation has occurred. Alternatively, when a preset touch input is sensed on a touch screen of the mobile terminal 200, the controller 180 may sense that a preset specific situation has occurred. The gesture may be sensed through sensors provided in the HMD 100 and sensors provided in the mobile terminal 200, and when the gesture or touch input is sensed, the controller 180 may sense the sensed user's gesture or touch input as a user's input for changing a target device, namely, a controller, to sense the movement.

In addition, according to the user's input, the controller 180 may change a currently set control device to another control device. Moreover, the controller 180 may sense the movement of the changed control device, and display image information controlled according to the sensed movement on the display unit 151 (S308).

Therefore, when the control device is set as the HMD 100 in the step S302, the controller 180 may change the control device to the mobile terminal 200 in the step S306. Then, in the step S308, the controller 180 may sense the movement of the mobile terminal 200 and display image information controlled according to the sensed movement on the display unit 151. On the contrary, if the control device is set as the mobile terminal 200 in the step S302, the controller 180 may change the control device to the HMD 100 in the step S306. In addition, in the step S308, the controller 180 may sense the movement of the HMD 100 and display image information controlled according to the sensed movement on the display unit 151.

Then, the controller 180 may proceed to the step S304 to sense whether or not a preset situation has occurred. Then, when a preset situation has not occurred as a sensing result in the step S304, the controller 180 may proceed to the step S302 to sense the movement of the currently set control device, and display screen information controlled according to the movement sensing result on the display unit 151. On the contrary, when a preset situation has occurred as a sensing result in the step 304, the controller 180 may may proceed to the step S306 to change the currently set control device to another control device. Then, the controller 180 may proceed to the step S308 to sense the movement of the changed control device, and display image information controlled according to the sensed movement on the display unit 151.

On the other hand, in the above description, it has been described on the assumption that a preset situation is generated according to a user's selection, that is, the user takes a specific gesture or applies a specific touch input while wearing the HMD 100 or holding mobile terminal 200, but on the contrary, it is needless to say that a situation occurring irrespective of the user's selection may also be the preset condition.

For example, the preset specific situation may be a situation where an amount of power of the currently set control device drops below a preset level. In this case, even when the specific gesture or the touch input is not sensed, the controller 180 may proceed to the step S306 to change the control device to another device.

Alternatively, the controller 180 may sense that the preset specific situation has occurred according to a function currently being executed in the HMD 100. The controller 180 of the HMD 100 may sense that the preset specific situation has occurred when image information related to a specific function is displayed on the display unit 151 based on the movement of the HMD 100 or the mobile terminal 200 and the direction of the user's gaze.

Meanwhile, in the above description, it has been described that only the currently set control device is changed to another device when a preset specific situation occurs in the step S304, but on the contrary, it is needless to say that the step 304 is a step for sensing whether the preset specific situation is finished.

For example, when image information related to a specific function is displayed on the display unit 151 as described above, the controller 180 may sense that a preset situation has occurred, and change the currently set control device. In this state, when the display of image information related to the specific function is finished on the display unit 151, the controller 180 may sense that the currently occurred situation has finished. In this case, the controller 180 may change the currently set control device again.

Accordingly, when a specific situation occurs, the present disclosure may allow image information displayed on the display unit 151 to be controlled through a different device other than the currently set control device from the time when the occurrence of the specific situation is sensed until the occurrence of the specific situation is finished. In other words, when the currently set control device is the HMD 100, the controller 180 may allow image information displayed on the display unit 151 to be controlled based on a movement sensed through the mobile terminal 200 until the specific situation is finished.

Accordingly, when image information related to a specific function, that is, specific image information, is displayed on the display unit 151 as described above, the controller 180 may control the display unit 151 to display image information controlled according to the sensed movement of the mobile terminal 200 on the display unit 151 until the display of the specific image information is finished.

In addition, when the preset situation occurs based on the remaining amount of power of the HMD 100 as described above, the controller 180 may change the control device 180 to the mobile terminal 200 until the amount of power of the HMD 100 reaches a preset level. Then, image information controlled according to the movement sensed by the mobile terminal 200 may be displayed on the display unit 151. Then, when the mobile terminal 200 is set as a controller and the amount of power of the HMD 100 is above a preset level according to the charging of the HMD 100 or the like, the controller 180 may change the control device back to the HMD 100.

On the contrary, when the currently set control device is the mobile terminal 200, the controller 180 may allow image information displayed on the display unit 151 to be controlled based on a movement sensed through the HMD 100 until the specific situation is finished. In this case, the controller 180 may display image information controlled according to the movement sensed by the HMD 100 on the display unit 151 while the specific image information is displayed on the display unit 151. Furthermore, when the remaining amount of power of the mobile terminal 200 is less than a preset level, the control device may be changed to the HMD 100.

On the other hand, according to the foregoing description, it has been mentioned that the preset specific situation may be a preset gesture or touch input or a user, or the like. In this case, the end of the preset specific situation may be a case where a specific function executed by a preset user's gesture or touch input is ended. In other words, for example, when a specific function is executed according to the user's gesture or touch input, a device controlling image information displayed on the display unit 151 may be changed to another device while the specific function is being executed, and when the specific function is ended, it may be changed again such that image information can be controlled according to a movement sensed by an original device.

In other words, when a specific function corresponding to the gesture or touch input is an image browsing function or a function of browsing specific information in case where the currently set controller is the HMD 100, the controller 180 may control image information displayed on the display unit 151 according to a movement sensed through the mobile terminal 200 while the image browsing function or information browsing function is carried out. Furthermore, when the image browsing function or information browsing function is ended, the controller 180 may control image information displayed on the display unit 151 according to a movement sensed through the HMD 100.

Meanwhile, the preset specific situation may be a situation itself where the user's gesture or touch input is sensed. Accordingly, when the user's gesture or touch input is sensed, the controller 180 may change the currently set control device to another device. In this situation, the controller 180 may sense that the situation where the user's gesture or touch input is sensed is ended when the user's gesture or touch input is sensed again.

Accordingly, the controller 180 may control image information displayed on the display unit 151 according to a movement sensed through the mobile terminal 200 when a specific function according to the gesture or touch input is sensed in case where the currently set control device is the HMD 100. In addition, when a specific function according to the gesture or touch input is sensed again, the controller 180 may control image information displayed on the display unit 151 according to a movement sensed through the HMD 100 again.

On the other hand, in the above description, it has been described as an example that the control device is changed to a control device different from the currently set control device in case where the preset situation occurs, but on the contrary, a specific control device corresponding to a specific situation may of course be set in advance.

For example, a specific gesture sensed from the HMD 100 worn on a user's head may be a gesture for setting the HMD in advance as a device for controlling image information displayed on the HMD 100, and a specific gesture sensed by the mobile terminal 200 may be a gesture for setting the mobile terminal 200 in advance as a device for controlling image information displayed on the HMD 100.

Alternatively, when the user's touch input sensed through a touch screen of the mobile terminal 200, the controller 180 may accordingly set the mobile terminal 200 in advance as a device for controlling image information displayed on the HMD 100. However, here, when the touch input forms a preset pattern, the controller 180 may of course set a specific device corresponding to the touch input pattern as a device for controlling image information displayed on the HMD 100.

Alternatively, when image information related to a specific function is displayed on the display unit 151 based on the movement of the mobile terminal 200 and the direction of the user's gaze, the HMD 100 or the mobile terminal 200 may be selected in advance as a device for controlling image information displayed on the HMD 100. For example, in case where the displayed image information requires more precise control of a user (for example, a specific graphic object is selected or specific content is selected), when the image information is displayed on the display unit 151, the controller 180 may set the mobile terminal 200 as a device for controlling image information displayed on the HMD 100. On the other hand, if a specific control device corresponding to a specific situation is set in advance as described above, the controller 180 may check whether or not a specific control device corresponding to the currently occurred situation is a device set as a device for controlling image information currently displayed on the HMD. Furthermore, as a result of the check, the currently set control device may of course be changed to another control device in the step S306 only when a specific control device previously set to correspond to the current occurred situation is different from a device currently set to control image information.

On the other hand, either one of the HMD 100 and the mobile terminal 200 may be preset as a basic control device for controlling image information displayed on the display unit 151. In this case, the controller 180 may sense the movement of either one device set as the basic control device, and display image information according to the sensing result on the display unit 151 without the user's selection or the occurrence of the specific situation. Here, the basic control device may be set by the user, and changed at any time according to the user's selection.

Meanwhile, when image information controlled according to a movement sensed by either one device of the HMD 100 and the mobile terminal 200 is displayed in the step S302, the controller 180 of the HMD 100 may disallow the other device to sense the movement. For example, the controller 180 of the HMD 100 may turn off a movement sensing function of the mobile terminal 200 when image information is controlled according to the movement of the HMD 100 in the step S302. In this case, the controller 281 of the mobile terminal 200 may turn off an acceleration sensor or a gyroscope sensor for sensing the movement of the mobile terminal 200.

On the contrary, when image information is controlled according to the movement of the mobile terminal 200 in the step S302, the controller 180 of the HMD 100 may turn off the movement sensing function of the HMD 100. In this case, the HMD 100 may turn off the acceleration sensor, the gyro sensor, or the like for sensing the movement of the HMD 100.

On the other hand, FIG. 4 is a flowchart illustrating an operation process of changing a device for controlling image information displayed on an HMD 100 according to an amount of power of the HMD 100 and a mobile terminal 200 connected to the HMD 100, in the HMD 100 related to the present disclosure. Referring to FIG. 4, when it is sensed that a preset specific situation has occurred according to the sensing result of the step S304 in FIG. 3, the controller 180 of the HMD 100 according to an embodiment of the present disclosure may check an amount of power of the “target device” (S400). Here, the “target device” may be a device that controls image information currently displayed on the HMD 100, that is, a device different from a device set as a control device or a device corresponding to the sensed specific situation.

Then, as a result of checking an amount of power in the step S400, the controller 180 may check whether or not the amount of power of the target device for sensing the movement is greater than a preset level (S402). Then, as a result of the check in the step S402, when the checked amount of power is above a preset level, the controller 180 may change the currently set control device to the “target device” (S404). Then, the controller 180 may proceed to the step S308 in FIG. 3, to sense the movement of the “target device” and display image information controlled according to the sensed movement on the display unit 151.

On the contrary, when the checked power of the “target device” is less than a preset level, the controller 180 may not change the currently set control device. In this case, the controller 180 may display notification information for notifying that the amount of power of the “target device” is insufficient on the display unit 151.

Meanwhile, it is explained whether or not the currently set control device is changed according to an amount of power of the “target device” in case where a preset situation occurs in FIG. 4, but on the contrary, the control device may of course be changed according to the amount of power of the currently set control device. Furthermore, in this case, the controller 180 may display notification information for notifying the user that the amount of power of the battery is insufficient and the controller is changed accordingly on the display unit 151.

In addition, even when the remaining power of the battery is insufficient, image information displayed on the display unit 151 may of course be controlled according to a movement sensed from a device currently set as a control device according to the user's selection. Alternatively, when the HMD 100 and the mobile terminal 200 are both in an insufficient amount of power, the controller 180 may of course control image information displayed on the HMD 100 based on a movement sensed by a device with little more remaining power or either one of the HMD 100 and the mobile terminal 200 according to the user's selection.

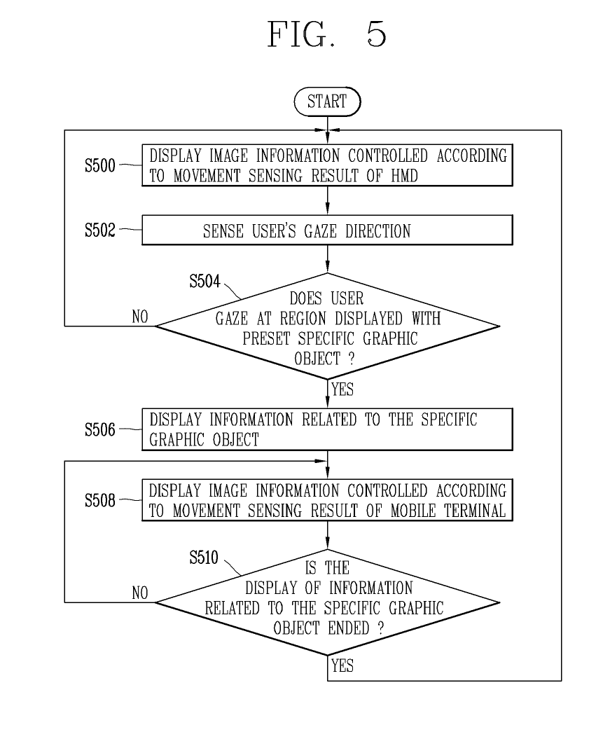

On the other hand, according to the foregoing description, it has been described that the controller 180 of the HMD 100 according to an embodiment of the present disclosure can change the currently set control device based on specific image information displayed on the display unit 151. FIG. 5 is a flowchart illustrating an operation process of allowing an HMD related to the present disclosure to change a device that control image information displayed on the HMD according to a graphic object displayed on a display unit. In the following description, it will be described on the assumption that the HMD 100 is set as a control device for the sake of convenience of explanation. In this case, the controller 180 may sense the movement of the HMD 100, for example, a rotational movement state or a linear movement state, and display a virtual space image in a specific direction corresponding to the sensed result on the display unit 151.

Referring to FIG. 5, the controller 180 of the HMD 100 according to an embodiment of the present disclosure may display image information controlled according to the movement sensing result of the HMD 100 (S500). Accordingly, the controller 180 may display a virtual space image in a direction of the movement of the HMD 100 on the display unit 151.

In this state, the controller 180 may sense a direction in which the user's gaze is directed. For example, the controller 180 may track the position of the user's pupil using a sensing value of the eye tracking sensor 142, and recognize one region on the display unit 151 that the user is gazing at according to the tracked pupil position. For example, when the user looks at the one region on the display unit 151 for more than a preset period of time, the controller 180 may determine that the user is gazing at the one region.

In this case, the controller 180 may detect whether or not a specific graphic object is displayed in a region on the display unit 151 that the user is gazing at (S504). Then, when it is detected that the user is gazing at a region displayed with the specific graphic object as a result of the detection in the step S504, information related to the preset specific graphic object may be displayed on the display unit 15 (S506).

Here, when information related to the preset graphic object is displayed, the controller 180 may determine it as the occurrence of the preset situation in the step S304. Then, the currently set control device may be changed accordingly from the HMD 100 to the mobile terminal 200.

Accordingly, the controller 180 may display image information controlled according to the sensed movement of the mobile terminal 200 on the display unit 151 (S506). For example, when the image information is generated and displayed by the HMD 100, the controller 180 may receive a result of sensing the movement of the mobile terminal 200 from the mobile terminal 200 in the step S506, and generate image information according to the received movement sensing result, and display the generated image information. However, when the image information is generated by the mobile terminal 200, the controller 180 may control the mobile terminal 200 to generate image information according to a result of sensing the movement of the mobile terminal 200 in the step S506, and receive the generated image information from the mobile terminal 200 and display the received image information.

In this state, the controller 180 may check whether or not the display of information related to the specific graphic object is ended (S510). For example, when the user gazes at a display region other than a region displayed with the image information, or when a voice command or a preset touch input or touch gesture of the user applied to the touch screen of the mobile terminal 200 is sensed, the controller 180 may terminate the display of information related to the specific graphic object. Then, when the display of information related to the specific graphic object is ended, the controller 180 may change the currently set control device from the mobile terminal 200 to the HMD 100 again. In this case, image information according to the movement of the head of the user, which is sensed through the HMD 100, may be displayed on the display unit 151.

On the other hand, in the above description, it has been described as an example that a preset situation in which the currently set control device is changed is a case where a touch gesture or touch input according to the user's selection is sensed, or a case where specific information is displayed or the remaining power is insufficient, but the present disclosure is not limited thereto.

For example, the preset situation may be a situation in which a specific event is generated in the mobile terminal 200. In this case, the controller 280 of the mobile terminal 200 may transmit information related to an event occurred in the mobile terminal 200 to the HMD 100. In this case, the controller 180 of the HMD 100 may display notification information for notifying an event occurred in the mobile terminal 200 on the display unit 151 of the HMD 100. In this case, the notification information may include information related to the occurred event, and the situation in which the notification information is displayed may be a “preset situation in which the control device is changed.”

Accordingly, the controller 180 may set the mobile terminal 200 as a control device for controlling image information displayed on the display unit 151. Then, the controller 180 of the HMD 100 may receive information on a specific event according to the user's selection from the mobile terminal 200. Here, the user's selection may be applied through the touch screen of the mobile terminal 200.

Then, the controller 180 of the HMD 100 may display information received from the mobile terminal 200 on the display unit 151. Accordingly, information on an event that has occurred in the mobile terminal 200 may be displayed on the display unit 151 of the HMD 100. In this case, the user's touch input sensed through the touch screen of the mobile terminal 200 may of course be displayed in a region corresponding to image information displayed on the display unit 151 of the HMD 100 (event related information received from the mobile terminal 200).

In the above description, in the HMD 100 according to an embodiment of the present disclosure, an operation process of changing a control device that controls image information displayed on the HMD 100 to the HMD 100 or the mobile terminal 200 according to the user's selection or a preset specific situation, in the HMD 100 according to an embodiment of the present disclosure, has been described in detail with reference to a plurality of flowcharts.

In the following description, an example of changing a control device that controls image information displayed on the HMD 100 according to the user's selection or a preset specific situation, in the HMD 100 according to an embodiment of the present disclosure, will be described in more detail with reference to the drawings.

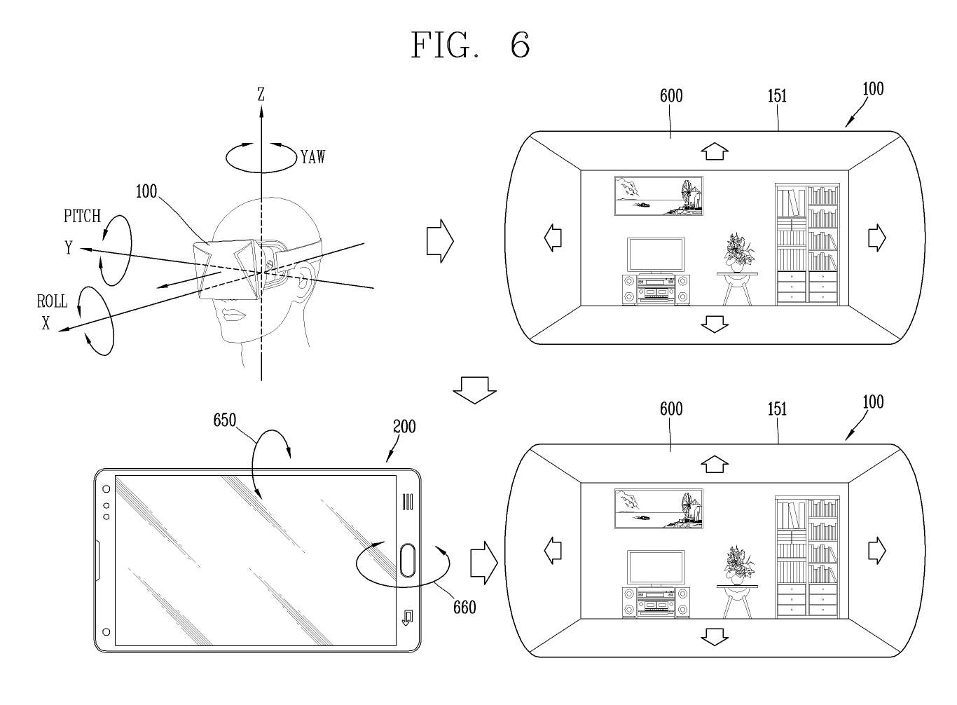

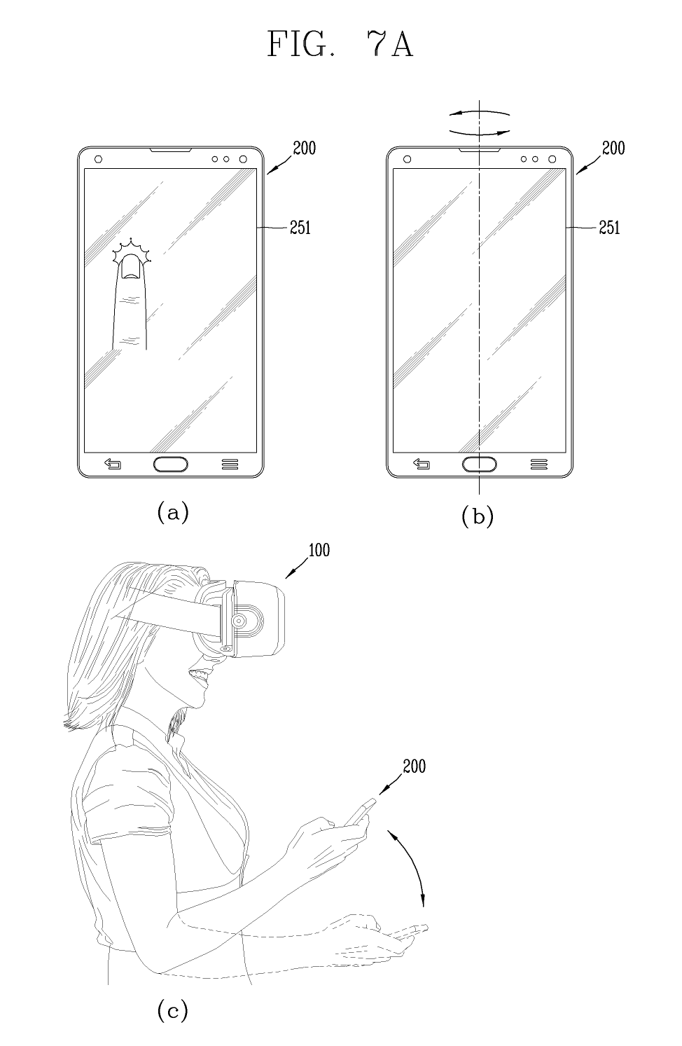

First, FIG. 6 is an exemplary view illustrating an example of allowing an HMD related to the present disclosure to control the HMD according to the movement of the HMD or controller device.

Referring to FIG. 6, first, a first view of FIG. 6 illustrates an example in which a control device for controlling image information displayed on the HMD 100 is set as the HMD 100. In this case, as shown in the first drawing of FIG. 6, roll, yaw, and pitch may be sensed according to the movement of the head of the user wearing the HMD 100, and image information displayed on the display unit 151 of the HMD 100 may be controlled according to the sensed roll, yaw, and pitch values.

For example, a vertical gaze angle of an image 600 in a virtual space displayed on the display unit 151 of the HMD 100 may be changed according to a change of the pitch value. In other words, as the pitch value increases, the gaze angle of the user looking at the image 600 of the virtual space may increase, and accordingly, as the user looks at a ceiling portion of the virtual space image 600, image information may be changed such that the ceiling portion is seen to be larger.

Furthermore, a horizontal gaze angle of an image 600 in a virtual space displayed on the display unit 151 of the HMD 100 may be changed according to a change of the yaw value. In other words, as the yaw value increases, the gaze angle of the user looking at the image 600 in the virtual space may be further shifted to the left or right side, and accordingly, as the user looks at the left or right side of the virtual space image 600, image information may be changed such that the left side wall or the right side wall is seen to be larger.

Meanwhile, in this state, when a preset situation occurs, a control device for controlling image information displayed on the HMD 100 may be changed to the mobile terminal 200. In this case, the controller 180 of the HMD 100 may change image information displayed on the display unit 151 based on the movement of the mobile terminal 200. In other words, as shown in the second drawing of FIG. 6, when the user rotates the mobile terminal 200 forward or backward in the longitudinal direction 650, a vertical gaze angle of the image 600 in the virtual space displayed on the display unit 151 may be changed accordingly. In other words, as the user tilts the mobile terminal 200 forward or backward, a gaze angle of the user looking at the image 600 of the virtual space may increase or decrease, and accordingly, image information may be changed such that the ceiling or the floor is seen to be larger as if the user looks at the ceiling or the floor of the virtual space image 600.

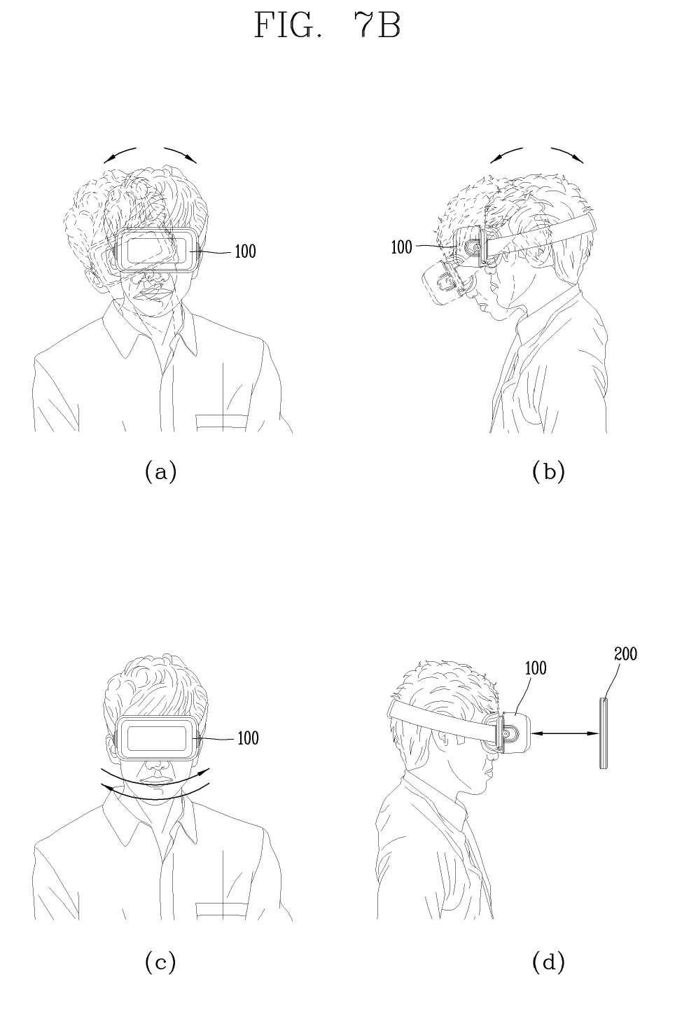

In addition, when the user rotates the mobile terminal 200 in a lateral direction 660 to the left or to the right, a horizontal gaze angle of the image 600 in the virtual space displayed on the display unit 151 of the HMD 100 may be changed. In other words, as an angle being rotated to the left or the right side increases, a gaze angle of the user looking at the image 600 in the virtual space may be further shifted to the left or right side, and accordingly, as the user looks at the left or right side of the virtual space image 600, image information may be changed such that the left side wall or the right side wall is seen to be larger. On the other hand, FIGS. 7A and 7B are exemplary views illustrating an example of sensing a user input for changing a device that controls an HMD 100, in the HMD 100 related to the present disclosure.

First, FIG. 7A shows an example in which a user enters an input for changing a control device that controls image information displayed on the HMD 100 through the mobile terminal 200. For example, as shown in FIG. 7A, for such a user's input, there may be a case where the user applies a preset touch input to the touch screen of the mobile terminal 200, or takes a specific gesture while holding the mobile terminal 200.

First, referring to (a) of FIG. 7A, (a) of FIG. 7A illustrates an example in which the user applies a preset touch input to the touch screen 251 of the mobile terminal 200 connected to the HMD 100 in a wired or wireless manner while the user views content through the HMD 100.

For example, when the user is viewing content through the HMD 100, the mobile terminal 200 may be in a dose mode state described above. Accordingly, the mobile terminal 200 may be in a state in which only a light emitting device for displaying a screen on the touch screen 251 is turned off, and the touch sensor or the acceleration sensor 252 and the gyroscope sensor or the like are in a state of maintaining an on state as shown in (a) of FIG. 7A. Accordingly, although there is no image information to be displayed, it may be in a state capable of sensing a touch input applied thereto or sensing a positional movement of the mobile terminal 200 or the like.

Accordingly, as shown in (a) of FIG. 7A, when a touch input is applied, the controller 280 of the mobile terminal 200 may sense the touch input and inform the controller 180 of the HMD 100 of the touch input. Then, the controller 180 of the HMD 100 may sense the touch input as the user's input for changing the control device that controls the currently displayed image information. Accordingly, the controller 180 may set a device other than the currently set control device as a device that controls image information displayed on the HMD 100. Alternatively, when a touch input as shown in (a) of FIG. 7A is applied, the controller 180 of the HMD 100 may sense the touch input as the user's input for setting the control device as the mobile terminal 200.

On the other hand, (a) of FIG. 7 (a) may be a plurality of touch inputs forming a preset touch pattern. Furthermore, the touch pattern may be set to correspond to a specific device. Accordingly, when a plurality of touch inputs sensed through the touch screen 251 form a preset pattern, the controller 180 of the HMD 100 may set a device corresponding thereto as a device that controls image information displayed on the HMD 100.

Meanwhile, as described above, when the mobile terminal 200 is in a doze mode, the controller 280 of the mobile terminal 200 may sense the movement of the mobile terminal 200. Accordingly, as shown in (b) and (c) of FIG. 7A, the mobile terminal 200 may sense a rotational movement generated while the user rotates the mobile terminal 200 or a positional movement generated according to a gesture or the like while the user holds the mobile terminal 200. Furthermore, the controller 180 of the mobile terminal 200 may notify the controller 180 of the HMD 100 of the sensed gesture.

Then, the controller 180 of the HMD 100 may sense the gesture as the user's input for changing the control device that controls the currently displayed image information. Accordingly, the controller 180 may set a device other than the currently set control device as a device that controls image information displayed on the HMD 100.

Meanwhile, FIG. 7B illustrates an example of sensing a user's head gesture from the HMD 100 other than the mobile terminal 200. For example, such a user's gesture may be a gesture in which the user shakes his head left or right or back and forth, or the like, as shown in (a), (b), or (c) of FIG. 7B. Furthermore, when the user's gesture is sensed above a preset number of times or a preset period of time, the controller 180 may sense that the user's gesture is to change the currently set control device.

Accordingly, when a gesture similar to that shown in (a), (b), or (c) of FIG. 7B is repeated above a preset period of time or a preset number of times, the controller 180 may set a device different from the currently set control device as a device for controlling image information displayed on the HMD 100. Alternatively, when such a gesture is sensed, the controller 180 of the HMD 100 may sense the gesture as a user's input for setting the control device as the HMD 100.

On the other hand, as shown in (d) of FIG. 7B, when a specific surface (for example, front or rear surface) of the mobile terminal 200 faces a front surface of the HMD 100, the controller 180 of the HMD 100 may sense it as a state for changing the currently set control device. For example, the controller 180 of the HMD 100 may sense that a specific surface of the mobile terminal 200 faces the HMD 100 within a preset distance using a camera provided in the HMD 100. Alternatively, the controller 180 of the mobile terminal 200 may sense that a specific surface of the HMD 100 faces a specific surface of the mobile terminal 200 within a preset distance from a camera provided on a front surface of the mobile terminal 200 (a surface on which the display unit 251 is formed) or a rear surface thereof. Furthermore, it may be notified to the controller 180 of the HMD 100. For example, the sensing may be performed through an infrared sensor, a laser sensor, an optical sensor (or a photo sensor) provided in the HMD 100 or the mobile terminal 200, and the like.

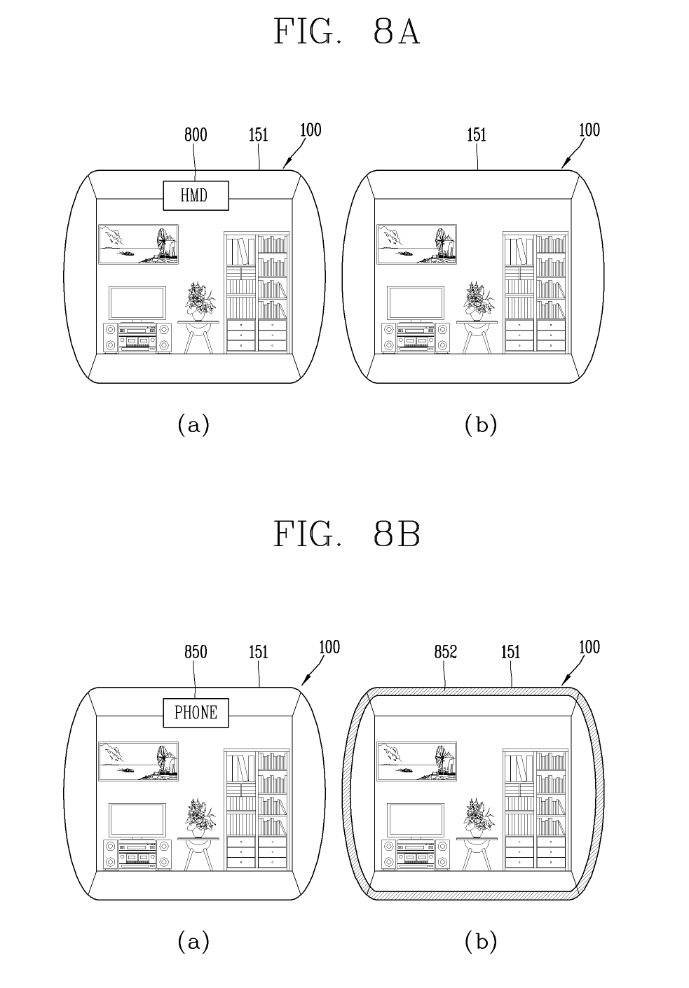

On the other hand, when a control device for controlling image information displayed on the display unit 151 of the HMD 100 is set as described above, the controller 180 of the HMD 100 may display information related to a device currently set as the control device. FIGS. 8A and 8B are exemplary views illustrating an example of screens displayed differently in an HMD related to the present disclosure according to a device that controls image information displayed in the HMD.

First, referring to FIG. 8A, FIG. 8A illustrates an example of a screen displayed when the control device is set as the HMD 100. Here, the case where the controller is set as the HMD 100 may denote that image information displayed on the display unit 151 of the HMD 100 is controlled according to a movement of a head of the user wearing the HMD 100.

In this case, the controller 180 may display a graphic object 800 including information on a control device currently set in at least part of the display unit 151. (a) of FIG. 8A illustrates an example in which the control device is set as the HMD 100 in this case.

Meanwhile, the HMD 100 may be set as a basic controller by the user. In this case, when image information displayed on the display unit 151 is controlled by a movement sensed by the HMD 100 (when the HMD 100 is set as a control device), the controller 180 may not display information for notifying it on the display unit 151. Thus, as shown in (b) of FIG. 8A, image information without special display may be displayed on the display unit 151.

On the contrary, when the currently set control device is the mobile terminal 200, the controller 180 may display information for notifying it on the display unit 151. In other words, as shown in (a) of FIG. 8B, the controller 180 may display a graphic object 850 on the display unit 151 to indicate that the currently set control device is the mobile terminal 200. In addition, when the control device is changed to the mobile terminal 200, the controller 180 may display image information controlled by a movement sensed from the mobile terminal 200 on the display unit 151, regardless of the movement of the user's head sensed from the HMD 100.

On the other hand, as shown in (b) of FIG. 8A, when the control device is changed to the mobile terminal 200 while the HMD 100 is set as a basic control device, the controller 180 may display information indicating that the control device is not a device set as a basic control device on the display unit 151. In this case, the controller 180 may display image information displayed on the display unit 151 to be different from each other in a state in which the control device is set as a basic control device (e.g., the HMD 100) and a state in which it is not as a basic control device (e.g., the mobile terminal 200).

In other words, as illustrated in the foregoing assumption, when the control device is changed to the mobile terminal 200 according to a specific situation or the user's selection when a device set as a basic control device is the HMD 100, the controller 180 may display a frame-shaped graphic object 852 formed at a boundary of a region displayed with image information on the display unit 151 as shown in (b) of FIG. 8B. In this case, the frame-shaped graphic object 852 may be an object for indicating to the user that a device currently set as a control device is not a device set as a basic control device.

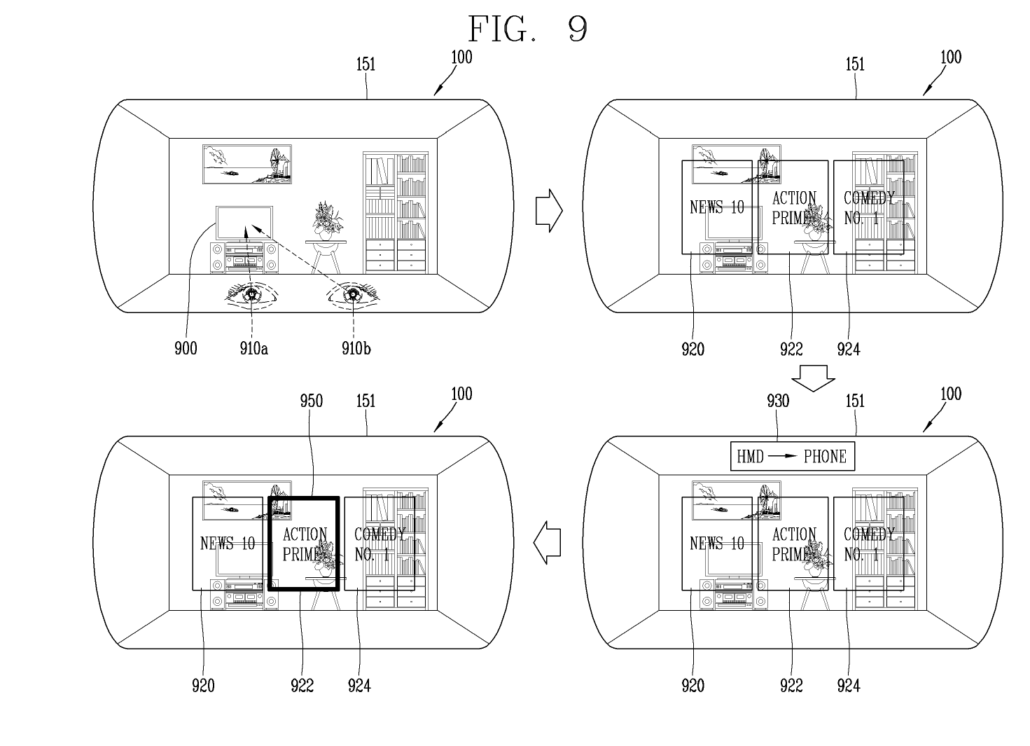

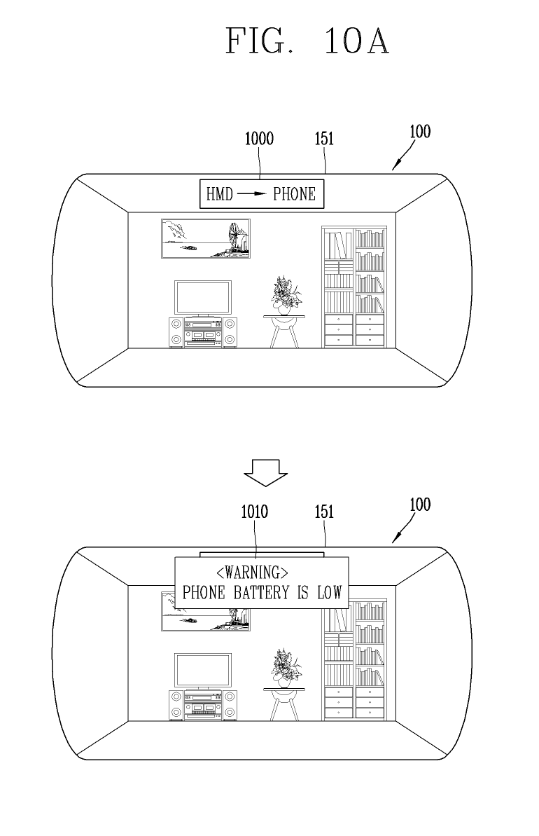

On the other hand, according to the above description, it has been mentioned that the controller 180 of the HMD 100 according to an embodiment of the present disclosure can control image information displayed in the HMD 100 when information related to a specific graphic object is displayed on the display unit 151 as well as based on the user's selection. FIG. 9 illustrates an example of such a case. In the following description, a case where the HMD 100 is set as a control device for controlling image information displayed for the sake of convenience of explanation.

First, referring to the first drawing of FIG. 9, the controller 180 of the HMD 100 according to an embodiment of the present disclosure may sense the movement of the user's head based on sensors provided in the HMD 100, that is, the acceleration sensor 141 and/or the gyro sensor 143. Then, the controller 180 may control image information displayed on the display unit 151 according to the sensed head movement.

In addition, the controller 180 may track the position of the user's pupil through the eye tracking sensor 142 and recognize a specific region on the display unit 151 gazed by the user. Accordingly, as shown in the first drawing of FIG. 9, when the user gazes at a region in which the TV 900 is displayed, among virtual objects in a virtual space displayed on the display unit 151, the controller 180 may recognize it. For example, when the user views the region on the display unit 151 in which the TV 900 is displayed for more than a preset period of time, the controller 180 may recognize it as gazing at the TV 900.

Meanwhile, in this case, the controller 180 may determine that the TV 900 is selected by the user among the virtual objects. Then, the controller 180 may display a virtual object selected by the user, that is, information related to a function of the TV 900 on the display unit 151. Accordingly, as shown in the second drawing of FIG. 9, the controller 180 may display a function related to the TV 900, namely, different graphic objects 920, 922, 924 corresponding region corresponding to information on different broadcast programs, respectively, on the display unit 151.

On the other hand, when information 920, 922, 924 related to a specific graphic object (TV 900) is displayed on the display unit 151 as described above, the controller 180 may determine that a specific situation for changing the currently set control device has occurred. It is because, as shown in the second drawing of FIG. 9, when a plurality of information are displayed, more precise w control for selecting any one of them may be required for the user.

Accordingly, the controller 180 may change a device currently set as the control device to another device. As a result, when the currently set control device is the HMD 100 as in the foregoing assumption, the controller 180 may change the control device to the mobile terminal 200. Furthermore, when the control device is changed as described above, the controller 180 may display information for notifying the change of the control device on the display unit 151. For example, the controller 180 may display a graphic object 930 including information on the currently set control device and a control device to be changed on the display unit 151 as shown in the third drawing of FIG. 9.

In addition, as shown in the third drawing of FIG. 9, when the control device is changed to the mobile terminal 200, the controller 180 may control image information displayed on the display unit 151 according to a movement sensed by the mobile terminal 200 Accordingly, the controller 180 may display any one graphic object 922 corresponding to the movement of the mobile terminal 200 to be distinguished from the other graphic objects 920, 924 displayed on the display unit 151. In other words, as shown in the fourth drawing of FIG. 9, the controller 180 may further display a frame-shaped graphic object 950 around any one graphic object 922 corresponding to the movement of the mobile terminal 200 to indicate that the any one graphic object 922 is selected by the user.

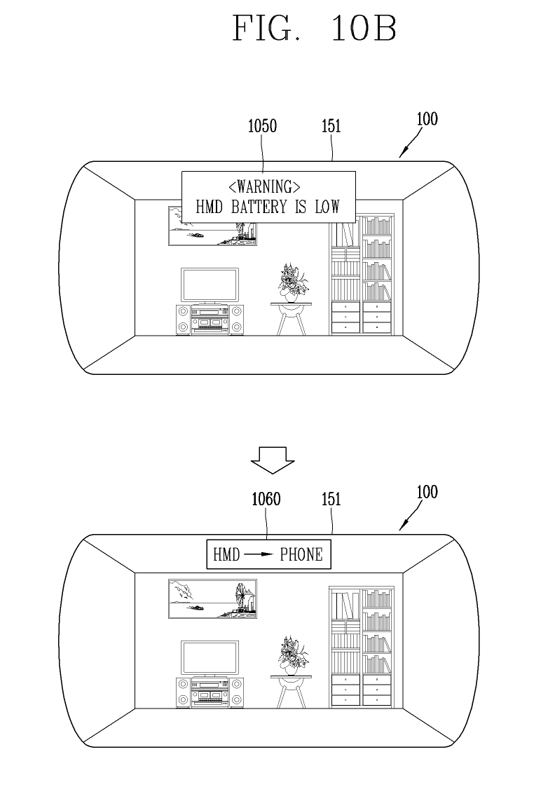

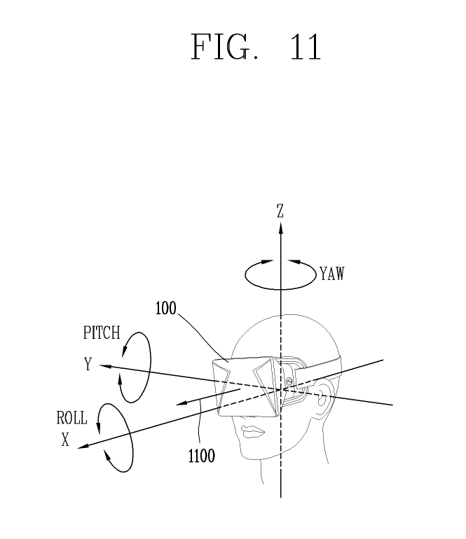

Meanwhile, according to the above description, it has been mentioned that the controller 180 of the HMD 100 according to an embodiment of the present disclosure can determine whether or not to change the control device according to an amount of power remaining in each device. FIGS. 10A and 10B are exemplary views illustrating an example of changing a device for controlling image information displayed on the HMD 100 according to a state of power of devices, in the HMD 100 related to the present disclosure in this case.

First, referring to FIG. 10A, the first drawing of FIG. 10A illustrates an example in which when the currently set control device is changed from the HMD 100 to the mobile terminal 200, notification information 1000 for notifying it is displayed on the display unit 151. In this case, the controller 180 may check an amount of power remaining in a device to be set as the control device, that is, the mobile terminal 200.

Then, when the amount of power remaining in the mobile terminal 200 is less than a preset level as a result of the check, the controller 180 may display information 1010 for notifying it for the user. Moreover, when the amount of power of a device to be set as the control device is insufficient, the controller 180 may not change the currently set control device.

Meanwhile, as described above, a change of the control device according to the amount of power may be carried out even when the of the control device occurs as well as when the user views content. In other words, the controller 180 may measure the amount of power remaining in the HMD 100 while the user is viewing the content. Besides, when the measured amount of power is less than a preset level, the controller 180 displays notification information 1050 indicating that the current amount of power of the HMD 100 is insufficient on the display unit 151, as shown in the first drawing of FIG. 10B.

Then, the controller 180 may change a device currently set as the control device. In other words, as shown in the first drawing of FIG. 10B, when a device currently set as the control device is the HMD 100, the controller 180 may change the control device to the mobile terminal 200. In addition, when the control device is changed as described above, the controller 180 may display information 1060 for notifying it on the display unit 151 as shown in the second drawing of FIG. 10B.

On the other hand, in the description of FIGS. 10A and 10B, a case where a device currently set as the control device is maintained as the control device even when a specific situation occurs according to the remaining amount of power of a device or a case where the device currently set as the control device is changed to another device even when the specific situation does not occur. However, on the contrary, it is needless to say that the device set as the control device may be determined according to the user's selection. In other words, it is needless to say that even though the amount of power of a specific device is insufficient, the specific device may be set as a control device or may continuously maintain a state of being set as the control device.

Meanwhile, in the above description, a case where image information displayed on the display unit 151 is controlled only in accordance with the movement of either one of the HMD 100 or the mobile terminal 200, but, both the movements of the HMD 100 and the mobile terminal 200 may of course be sensed according to the selected function or the user's selection. In this case, a device for generating image information between the HMD 100 and the mobile terminal 200 may of course receive the movement sensing result from the HMD 100 and the mobile terminal 200, respectively, and generate image information reflecting the received movement. In this case, functions controlled according to the respective movements of the HMD 100 and the mobile terminal 200 may be respectively linked with each other on the image information or content, and image information according to the movements of the HMD 100 and the mobile terminal 200 for controlling the functions linked with each other may also be displayed on the display unit 151.

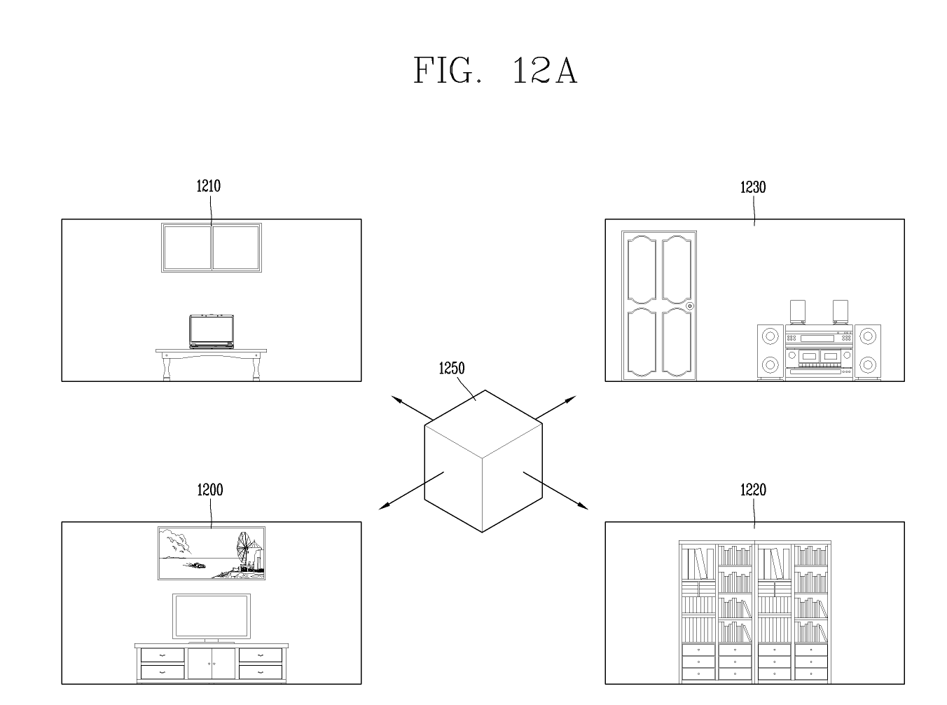

FIG. 11 is a conceptual view for explaining an example of controlling image information displayed on the display unit 151 according to a movement of a user wearing the HMD 100, in the HMD 100 according to an embodiment of the present disclosure in this case.

Referring to FIG. 11, FIG. 11 illustrates a head of a user wearing the HMD 100. Furthermore, when the user wears the HMD 100, the controller 180 of the HMD 100 may display an image of the virtual space generated according to content selected by the user through the display unit 151 of the HMD 100. In this case, the controller 180 may display an image in the virtual space in a specific direction currently set to correspond to a front side 1100 of the HMD 100 on the display unit 151.

In this state, the controller 180 may sense a roll, a yaw, and a pitch according to the movement of the user. In addition, a viewing angle of the user viewing the virtual space may be changed according to the sensed roll, yaw, and pitch values. For example, when the user lifts his/her head, a vertical gaze angle (a direction in which a front side 1100 of the HMD 100 faces) in which the user looks at the virtual space may be changed according to a change of the pitch value. Furthermore, an image of the virtual space displayed on the display unit 151 of the HMD 100 may be changed according to the changed gaze angle. In other words, an image of another region in the virtual space may be displayed on the display unit 151 according to the changed gaze angle. It is because a region in the virtual space corresponding to the changed viewing angle has been changed.

Furthermore, a horizontal gaze angle of an image 600 in a virtual space displayed on the display unit 151 of the HMD 100 may be changed according to a change of the yaw value. In other words, as the yaw value is changed, a gaze angle of the user looking at the virtual space (a direction in which the front side 1100 of the HMD 100 faces) may be changed to the left direction or the right direction. Accordingly, the controller 180 may display a virtual space image in a region located on the right or left side of a region in the virtual space corresponding to the front side 1100 in the HMD 100 on the display unit 151 according to a change of the yaw value.

As described above, the controller 180 of the HMD 100 may display an image in another region (a region corresponding to the user's gaze angle changed according to the movement of the head) in the virtual space according to the movement of the user's head sensed through the HMD 100. Accordingly, the user may take an action of wearing the HMD 100, and then turn his or her head or lifting his or her head to view an image in another region in the virtual space through the display unit 151.

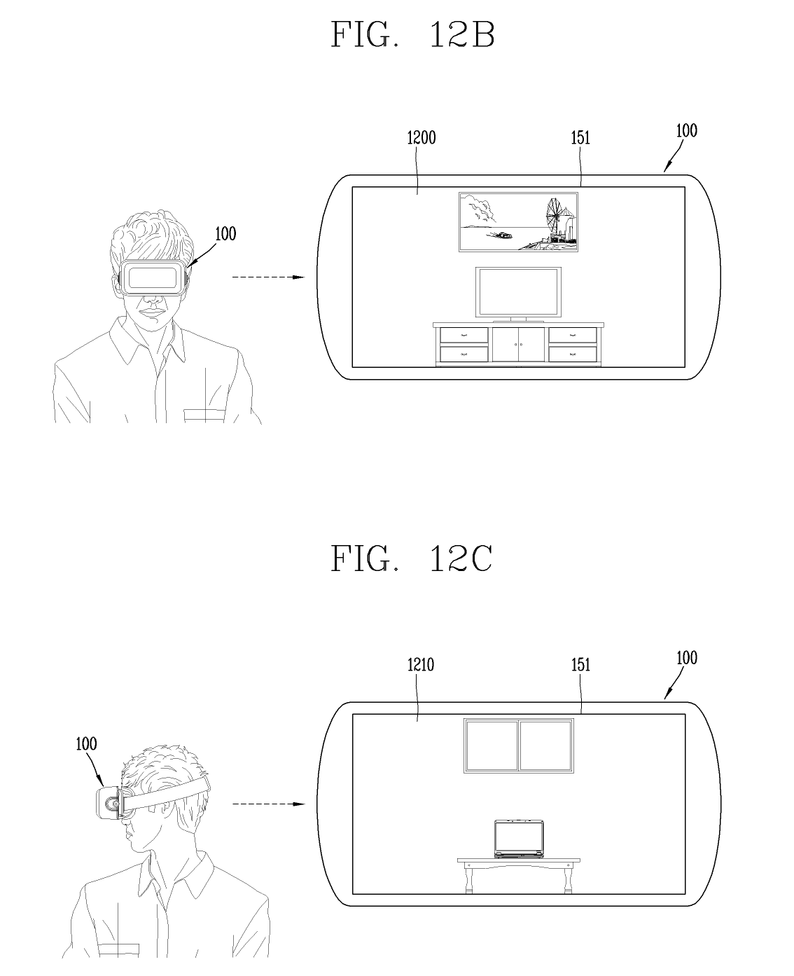

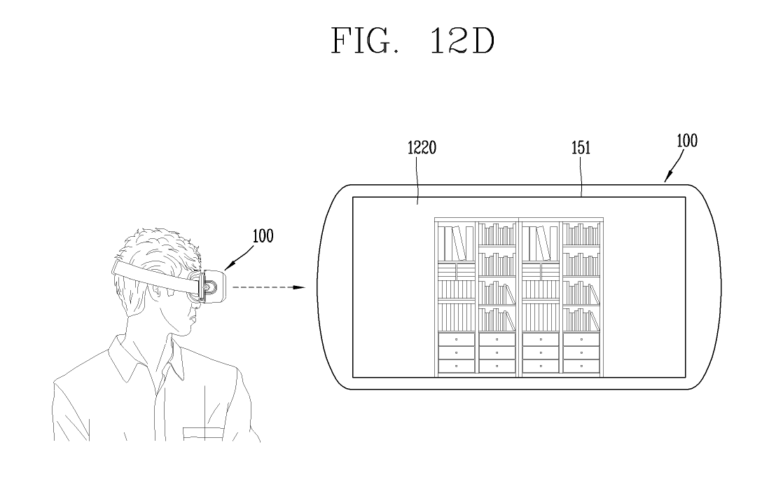

FIGS. 12A through 12D are conceptual views illustrating examples of displaying a virtual space image in different regions according to the movement of an HMD, in the HMD according to the embodiment of the present disclosure.

First, FIG. 12A illustrates an example of a virtual space 1250 formed in the HMD 100 according to an embodiment of the present disclosure. Here, the virtual space 1250 may be a virtual space formed around the user when the user wears the HMD 100 and plays back content related thereto. In other words, the user may be located at the center of the virtual space 1250.

On the other hand, it will be described on the assumption that the virtual space 1250 is generated in a hexahedral shape having four sides as shown in FIG. 12A for the sake of convenience of explanation, and each side includes different contents as a different region in the virtual space configured to include different graphic objects, respectively. Furthermore, a region of the virtual space (first region 1200) corresponding to a first side of the sides is assumed as a region corresponding to a direction 1100 set to a front surface of the HMD 100 according to an embodiment of the present disclosure.

Accordingly, as shown in the first drawing of FIG. 12B, when the user is looking at the front side while wearing the HMD 100, an image of a specific region in the virtual space 1250 currently set to correspond to the direction of the front side 1100 of the HMD 100 may be displayed. In this case, when the first side of the virtual space 1250 is set to correspond to the front side of the HMD 100, as shown in the second drawing of FIG. 12B, an image of a virtual space region corresponding to the first side of the virtual space 1250, namely, the first region 1200, may be displayed on the display unit 151.

On the contrary, as shown in the first drawing of FIG. 12C, when the user rotates his or her head so as to face the right side, an image of another region in the virtual space 1250 may be displayed on the display unit 151. In other words, as shown in the second drawing of FIG. 12C, according to the rotation of the user's head in a right direction, an image of a virtual space region located on the right side of the first side (first region 1200), that is, a second region 1210 corresponding to a second side, in the virtual space 1250, may be displayed on the display unit 151.

However, as shown in the first drawing of FIG. 12D, when the user rotates his or her head so as to face the left side, an image of another region in the virtual space 1250 may be displayed accordingly on the display unit 151. In other words, as shown in the second drawing of FIG. 12D, an image of a virtual space region located on the left side of the first side (first region 1200), that is, a region 1220 corresponding to a third side, in the virtual space 1250, may be displayed on the display unit 151.

On the other hand, in this case, it may be difficult to display a region (fourth region 1230) in the virtual space corresponding to a side, namely, fourth side, in a direction currently opposite to the front side 1100 of the HMD 100 is displayed on the display unit 151. It is because since an angle capable of allowing the user to move his or her head is limited in the human body structure, the user is unable to change a gaze angle up to the fourth region 1230 corresponding to a backward side of the user wearing the HMD 100. As the angle capable of allowing the user to move his or her head is limited, an image of the virtual space displayed based on the movement of the head may also be limited.

Meanwhile, the HMD 100 according to an embodiment of the present disclosure may display a virtual space image in a region out of a region of the virtual space that can be displayed according to the movement of the user's head on the display unit 151 using the mobile terminal 200 connected to the HMD 100 as described.

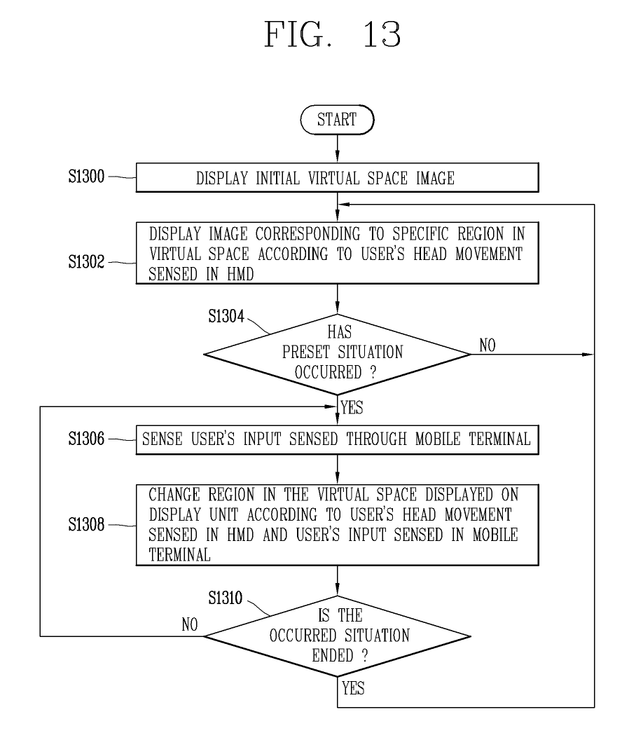

FIG. 13 illustrates an operation process of displaying an image in a virtual space according to an input sensed through the HMD 100 and a mobile terminal 200 connected thereto, in the HMD 100 according to an embodiment of the present disclosure as described above.

Referring to FIG. 13, the controller 180 of the HMD 100 according to the embodiment of the present disclosure may display an image of an initial virtual space corresponding to the selected content on the display unit 151 (S1300). In this case, as shown in FIG. 12B, an image of a specific region in the virtual space currently set to correspond to a direction of the front side 1100 of the HMD 100 may be displayed on the display unit 151.

Here, the image of the virtual space may be generated in the HMD 100 or may be generated in the mobile terminal 200 connected to the HMD 100. Then, if the image information is generated from the mobile terminal 200, the controller 180 may control the mobile terminal 200 to generate the image of the virtual space through the mobile terminal 200, and receive the image of the virtual space generated from the mobile terminal 200, and display the received image of the virtual space on the display unit 151 of the HMD 100.

Meanwhile, when the image of the virtual space is displayed on the display unit 151, the controller 180 may display an image corresponding to a specific area in the virtual space according to the movement of the user's head sensed through the HMD 100 (S1302). In other words, as shown in FIGS. 12C and 12D, when the user turns his/her head to the left or turns his/her head to the right, the controller 180 may control an image of another region in the virtual space according to the movement of the user's head, that is, an image of the left or right region in the virtual space set to correspond to the forward direction of the HMD 100, may be displayed on the display unit 151.

Meanwhile, in this state, the controller 180 may sense whether or not a preset situation has occurred (S1304). Furthermore, when a preset situation is sensed as a result of sensing in the step S1304, an image in a region of the virtual space currently displayed on the display unit 151 may be changed to an image in another region based on a sensing value sensed through the mobile terminal 200.

Here, the preset situation may include various situations. For example, the preset situation may be a situation where a specific input is sensed by the user. In addition, the specific input may be a preset gesture of the user.

The gesture may be sensed through the HMD 100. For an example, such a gesture may be an action in which the user shakes his or her head more than a predetermined number of times to the left or right or back and forth, or repeats his or her head more than a predetermined number of times to the left or right. In this case, the controller 180 may sense the movement of the user through the sensing unit 140. Then, it may be sensed that the preset situation has occurred according to the sensing result.

Alternatively, the gesture may be sensed through the mobile terminal 200 connected to the HMD 100. For example, when the user takes a gesture of shaking the mobile terminal 200 up or down or left or right above a predetermined number of times and above a predetermined speed while holding the mobile terminal 200, the user's gesture may be sensed through the sensing unit 240 provided in the mobile terminal 200. Then, it may be sensed that the preset situation has occurred according to the sensing result.

Alternatively, the preset condition may be determined according to a region of the virtual space currently displayed on the HMD 100. For example, as shown in FIGS. 12C and 12D, the controller 180 may display an image in a virtual space region corresponding to the left or right side, from a region of the virtual space currently set to correspond to a direction of the front side 1100 of the HMD 100 according to a direction in which the user's head is rotated. In addition, the controller 180 may sense an angle of the HMD 100 rotated from the forward direction 1100 to the left or right while the image of the virtual space region corresponding to the left or right side is displayed. Besides, when the rotated angle is above a predetermined angle, or when the rotated angle is rotated by a predetermined angle or more and a predetermined period of time has elapsed, it may be sensed that the preset situation has occurred.

Moreover, the preset situation may be a situation in which a preset touch input is applied to the mobile terminal 200. For example, when a plurality of touch inputs forming a preset pattern are applied from the mobile terminal 200, or when a touch input maintaining a hold state for more than a preset period of time, or when a drag input forming a preset trace is applied to the display unit 251 of the mobile terminal 200, the controller 180 may sense that the preset situation has occurred.

As a result of the sensing in the step S1306, when it is sensed that the preset situation has occurred, the controller 180 may sense the user's input through the mobile terminal 200. For example, the user's input may be a touch input, a hold input, or a drag input of a user applied to the display unit 251 of the mobile terminal 200. Alternatively, the user's input may be a movement of the mobile terminal 200 sensed through the gyro sensor or the acceleration sensor of the mobile terminal 200. In other words, the user's input may be an inclination sensed when one side of the mobile terminal 200 is tilted in a specific direction, or a rotational force or a rotated angle that allows the mobile terminal 200 to rotate in a specific direction. Alternatively, it may be an acceleration occurring when the mobile terminal 200 moves in a specific direction above a constant speed.

Meanwhile, when a user's input applied through the mobile terminal 200 is sensed in the step S1306, the controller 180 may change a region in a virtual space displayed on the display unit 151 according to the movement of the user's head sensed by the HMD 100 and the user's input sensed by the mobile terminal 200 (S1308).

In other words, the controller 180 may display an image of a region corresponding to the user's gaze angle changed from a region of the virtual space corresponding to the forward direction 1100 of the HMD 100 to the left or right by the rotation of the user's head. In this state, for example, when the user's input sensed in the step S1306 is a drag input applied in a specific direction on the display unit 251 of the mobile terminal 200, the controller 180 may change the user's gaze angle in the left or right direction according to a direction in which the drag input is applied, and display an image of the virtual space corresponding to the changed gaze angle.

Accordingly, in the present disclosure, when a preset situation occurs in the step S1304, the user's gaze angle may be changed to the right side or the left side of the direction 1100 in which the front side 1100 of the HMD 100 faces. Accordingly, when the preset situation occurs, the controller 180 of the HMD 100 according to an embodiment of the present disclosure may display each region in the virtual space based on a user input sensed through the mobile terminal 200 irrespective of a direction in which the front side of the HMD 100 faces. In other words, even when the user's head is not rotated (a state shown in the first drawing of FIG. 12B) in case where the preset situation occurs, the controller 180 may display an image of the virtual space corresponding to a rear side of the user (for example, an image of the fourth region 1230 in the virtual space 1250) based on a user input sensed in the step S1306.

On the other hand, when a region in the virtual space displayed on the display unit 151 is changed according to the movement of the user's head sensed through the HMD 100 and the user's input sensed from the mobile terminal 200 in the step S1308, the controller 180 may sense whether or not the currently occurred situation has terminated (S1310).

For example, when the preset situation occurred in the step S1304 is generated by the user's touch input or gesture, the step S1310 may be a step of sensing the preset user's touch input or gesture again. Alternatively, it may be a step of sensing a specific touch input or gesture corresponding to the end of the currently occurred situation. In this case, when the preset user's touch input or gesture is sensed again or a touch input corresponding to the end of the currently occurred situation is sensed, the controller 180 may sense that the current occurred situation is ended.

Then, the controller 180 may proceed to the step S1302, and display an image corresponding to a specific region in the virtual space on the display unit 151 according to the movement of the user's head sensed by the HMD 100. Moreover, the controller 180 may proceed to the step S1304 to sense whether or not a preset situation has occurred, and repetitively perform the processes of the steps S1306 through S1310 according to the sensing result.

On the other hand, when the preset situation has not been terminated as a result of sensing in the step S1310, the controller 180 may proceed to the step S1306 and sense the user's input through the mobile terminal 200, and display an image of a specific region in the virtual space on the display unit 151 according to the user's input sensed through the mobile terminal 200 and the user's head movement sensed by the HMD 100 in the step S1308.

Meanwhile, in the above description, it has been described as an example that the gaze angle is further changed to the left or right according to the user input sensed in the step S1306, but the present disclosure is not limited thereto. In other words, as described above, the user's input may be a drag input in a specific direction or a movement or tilting of the mobile terminal 200 moving in a specific direction, or a user's touch input applied to the display unit 251. Accordingly, the gaze angle may be changed not only to the left or right but also to an upward direction (for example, a direction opposite to a direction in which gravity is applied) or downward direction (for example, a direction in which gravity is applied), and as a result, an image of the virtual space according to the gaze angle changed in the various directions may be displayed on the display unit 151.

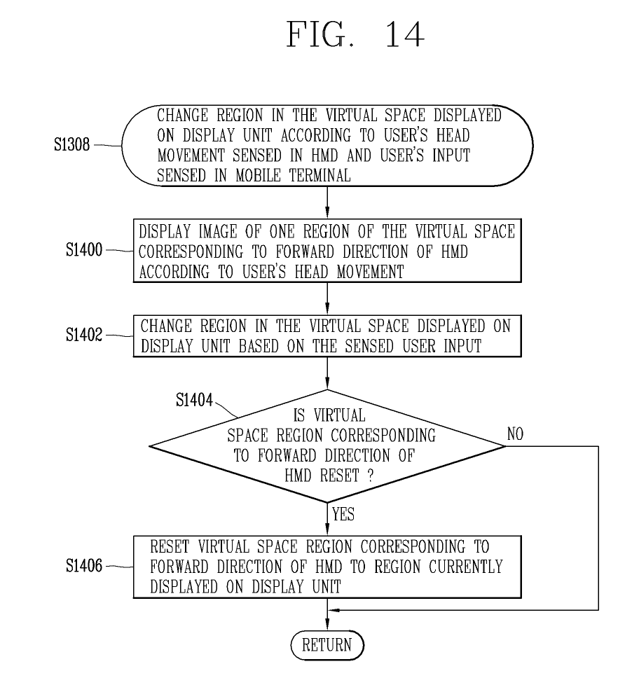

On the other hand, FIG. 14 is a flowchart illustrating an operation process of changing an image in a virtual space displayed on a display unit according to an input sensed through a mobile terminal during the operation process of FIG. 13.

Referring to FIG. 14, the controller 180 of the HMD 100 according to an embodiment of the present disclosure firstly may display an image of one region in the virtual space currently corresponding to the forward direction of the HMD 100 on the display unit 151 according to the user's head movement (S1400). Accordingly, when the user turns his or her head to the right or left or lifts his or her head or lowers his or her head, an image in the virtual space corresponding to the forward direction of the HMD 100 according to the user's head movement, namely, an image of one region in in the virtual space, may be displayed on the display unit 151.

In this state, the controller 180 may change a region in the virtual space displayed on the display unit 151 according to the user's input sensed through the mobile terminal 200 in the step S1306 of FIG. 13 (S1402). In other words, as described above, the controller 180 may change a direction in which the user looks at the virtual space, i.e., a gaze angle, according to the user's input sensed through the mobile terminal 200. Furthermore, a region in the virtual space displayed on the display unit 151 may be changed to an image of another region according to the changed gaze angle.

On the other hand, when the user's gaze angle viewing a region in the virtual space is changed, the controller 180 may sense whether or not there is a user's input for changing a region in a preset virtual space to correspond to the forward direction of the HMD 100 (S1404).

The input may be sensed through the user's specific gesture sensed through the HMD 100 or a preset touch input or an input of a specific key sensed through the mobile terminal 200 input through a predetermined touch input sensed through the mobile terminal 200, or a preset gesture sensed through the mobile terminal 200.

On the other hand, when there is a user's input for changing a region of the virtual space corresponding to the front side of the HMD 100 as a result of sensing in the step S1404, the controller 180 may reset the region of the virtual space to a “region corresponding to the forward direction of the HMD 100” (S1406). In this case, a region currently displayed on the display unit 151 may be set as a region corresponding to the forward direction of the HMD 100, and an image of the virtual space according to the user's head movement may be displayed on the display unit 151 based on a region currently displayed on the display unit 151.

For example, when an image (second region 1210) of the virtual space as shown in FIG. 12C is currently displayed on the display unit 151 in the step S1402, the user may set an image of the second region 1210 as a “region corresponding to the forward direction of the HMD 100.” In this case, an image of the second region 1210 corresponding to the forward direction of the HMD 100 may be set, and it may be a region in the virtual space 1250 corresponding to a case where the user looks at the front side of the HMD 100 while wearing the HMD 100. In addition, it may be a region of the virtual space 1250 initially displayed on the display unit 151 when the user wears the HMD 100 for the first time and plays back the content of the virtual space 1250.

Accordingly, when the user rotates his or her head to the left, an image of the first region 1200 may be displayed on the display unit 151. Moreover, when the user rotates his or her head to the right, an image of the fourth region 1230 of FIG. 12A may be displayed on the display unit 151. In addition, since an image of the third region 1220 of FIG. 12A is located behind the user's head (HMD 100), it may be difficult to display it only by the user's head movement.

Meanwhile, when there is no user's input for changing a region of the virtual space corresponding to the forward direction of the HMD 100 as a result of sensing in the step S1404, the controller 180 may proceed directly to the step S1310 of FIG. 13. Then, the controller 180 may sense the user's input through the mobile terminal 200 (step S1306) as a result of sensing in step S1310, or change an image in the virtual space displayed on the display unit 151 according to the movement of the user's head sensed by the HMD 100 (step S1302).

Meanwhile, in the above description, an operation process of allowing the HMD 100 according to an embodiment of the present disclosure to change a region in the virtual space displayed on the display unit 151 based on the user's head movement as well as the user's input sensed from the mobile terminal 200 according to whether or not a preset situation has occurred has been described in detail with reference to a flowchart.

In the following description, an example of allowing the HMD 100 according to an embodiment of the present disclosure to change a region of the virtual space displayed on the display unit 151 based on the movement of the user's head as well as the user's input sensed from the mobile terminal 200 will be described in more detail with reference to the exemplary views.

First, as described above, the user's input sensed through the mobile terminal 200 may include various inputs. For example, the user input may be a touch input sensed on the display unit 251 of the mobile terminal 200 or a touch-and-drag input applied in a specific direction. Alternatively, the user input may be a movement of the mobile terminal 200 sensed through the gyro sensor or the acceleration sensor of the mobile terminal 200.

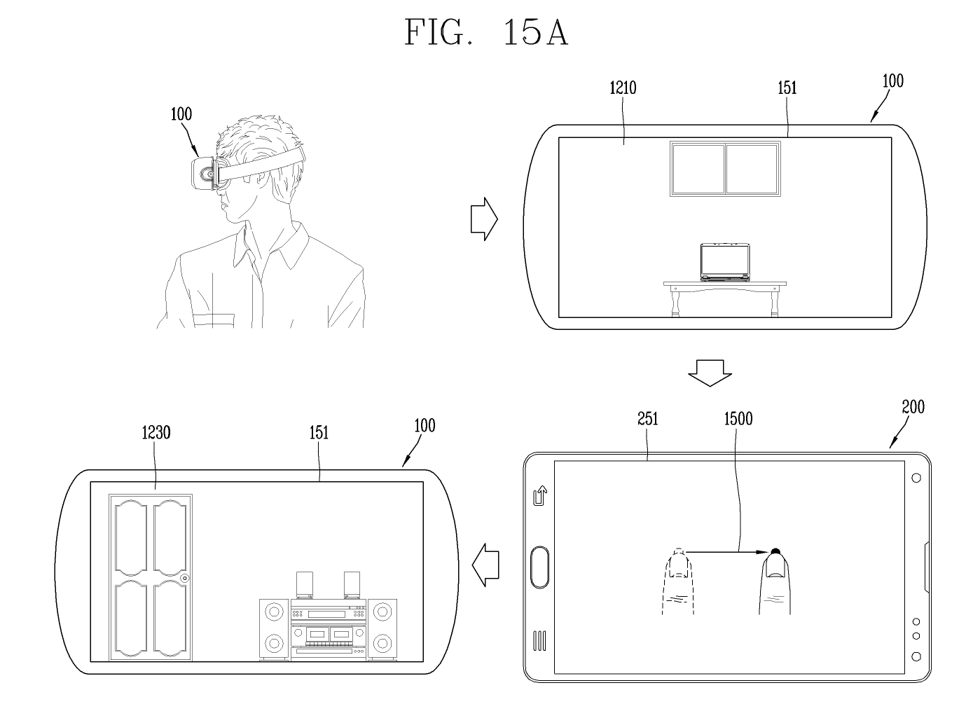

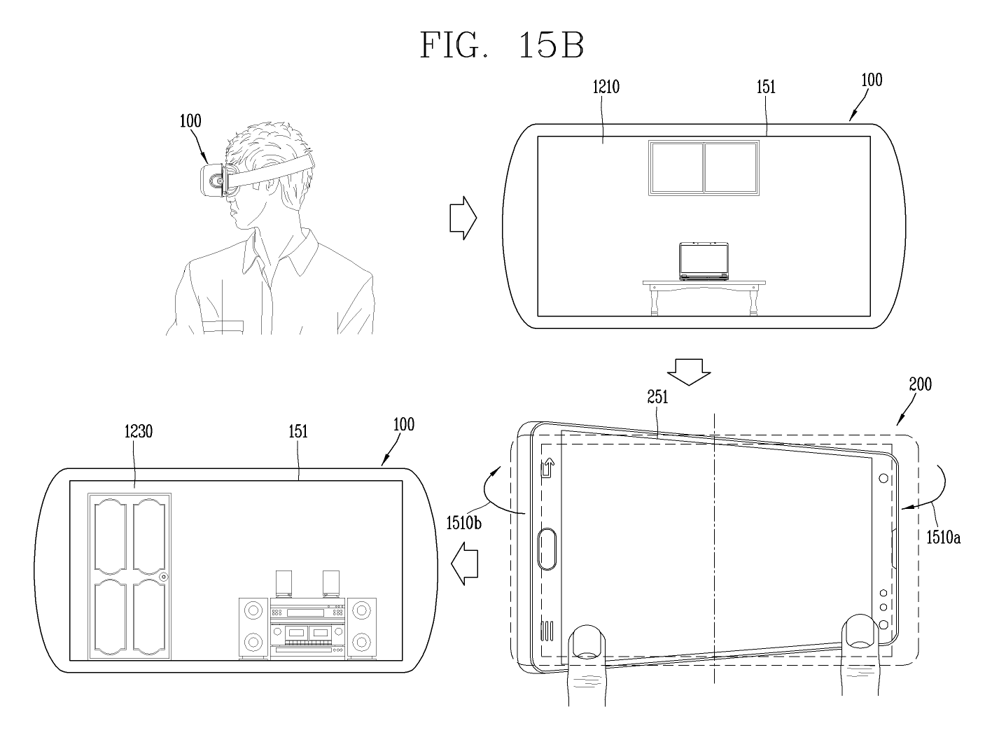

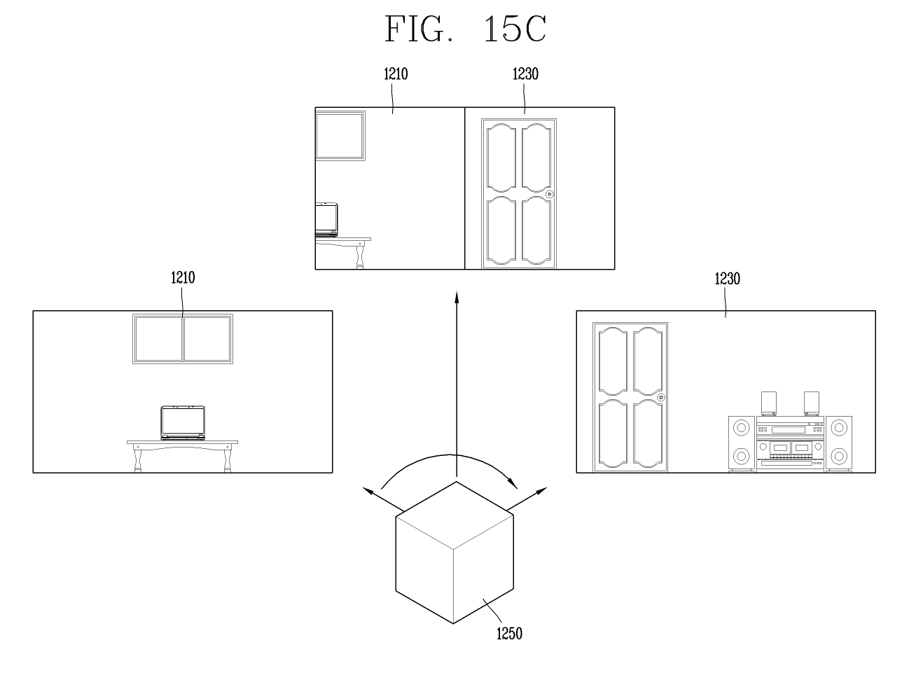

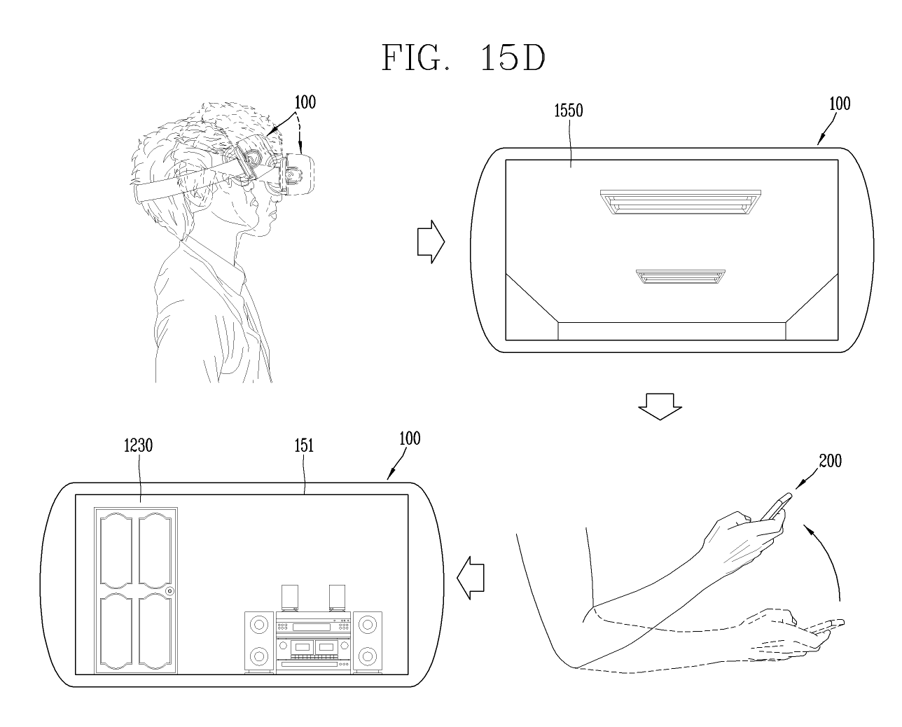

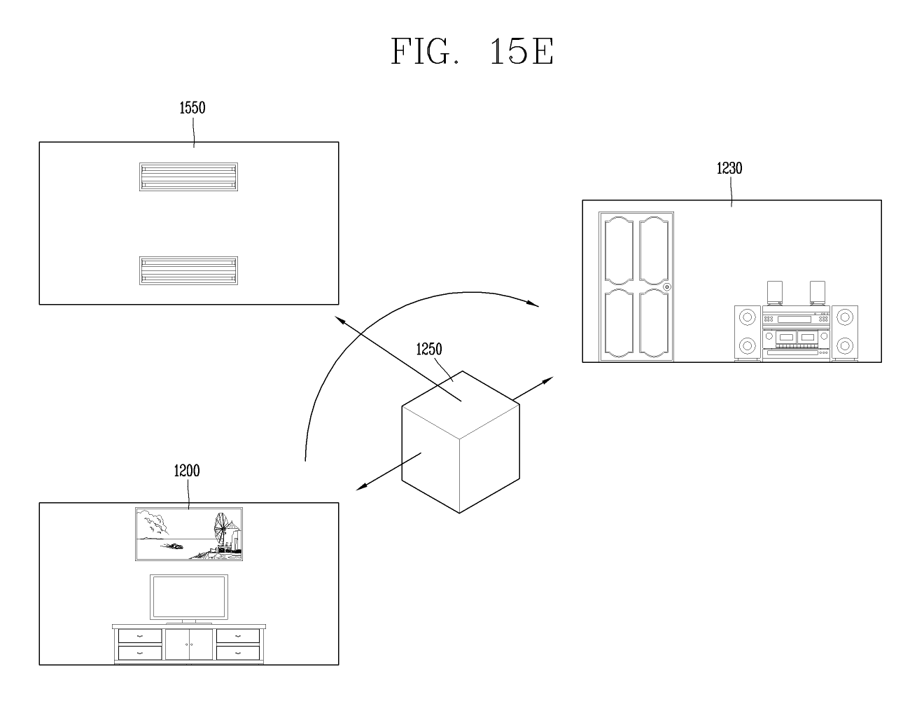

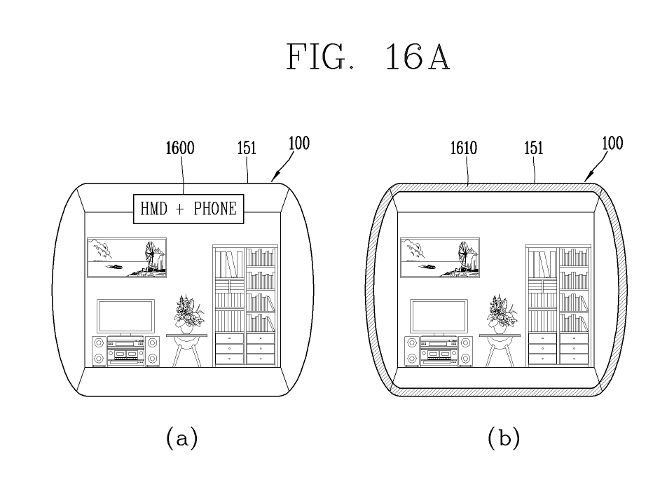

FIGS. 15A through 15E illustrate examples of allowing the HMD 100 according to an embodiment of the present disclosure to change an image of the virtual space displayed based on such a user input sensed through the HMD 100 and a mobile terminal 200 connected thereto. For the sake of convenience of explanation, it is assumed that the virtual space is generated in a hexahedral shape including four sides as shown in FIG. 12A, and it is assumed that an image in the virtual space 1250 corresponding to the four sides correspond to a first region 1200, a second region 1210, a third region 1220, and a fourth region 1230, respectively. Furthermore, here, it will be described as an example that the first region 1200 is set as a region currently corresponding to the forward direction of the current HMD 100.

First, FIG. 15A illustrates an example in which a drag input is applied as such a user input.

Referring to FIG. 15A, first, the first drawing of FIG. 15A shows an example in which the user rotates his or her head to the right while wearing the HMD 100. In this case, the controller 180 may display an image of a region of the virtual space 1250 located on the right side of the first region 1200, that is, an image of the second region 1210 on the display unit 151. The second drawing of FIG. 15A illustrates such an example.

In this state, the controller 180 may sense whether or not a preset situation has occurred. For example, as shown in the first drawing of FIG. 15A, the controller 180 may sense that a preset situation has occurred when the user maintains a state for more than a preset period of time while the user turns his or her head to the right. Alternatively, when sensing a preset touch input or a specific movement (e.g., a movement corresponding to a specific gesture taken by the user while holding the mobile terminal 200) through the mobile terminal 200, the controller 180 may sense that a preset situation has occurred in the step S1304.

Meanwhile, when sensing that the preset situation has occurred, the controller 180 may sense the user's input through the mobile terminal 200. In addition, as shown in the third drawing of FIG. 15A, when a drag input 1500 in a specific direction being applied from one point to another point on the display unit 251, the controller 180 may change an region in the virtual space 1250 displayed on the display unit 151 according to the sensed drag input 1500. In other words, as shown in the third drawing of FIG. 15A, when the drag input 1500 draws a trace in a right direction, the controller 180 may display an image of a region in the virtual space 1250 currently displayed on the display unit 151, that is, the fourth region 1230 located on the right side of the second region 1210, on the display unit 151.

In this case, an image of the virtual region 1250 displayed on the display unit 251 may of course be determined based on a length of the drag input. In other words, as the length of the drag input increases, an image of one region in the virtual space 1250 located on the right side than a region (second region 1210) of the virtual space 1250 currently displayed on the display unit 151 may be displayed on the display unit 151. In addition, a speed at which an image of another region in the virtual space 1250 is displayed on the display unit 151 may of course be determined based on a speed at which a trace according to the drag input is applied. In other words, as the speed at which the drag trace is applied increases, an image of another region in the virtual space 1250 may be displayed on the display unit 151 more quickly.

On the other hand, the user's input may include various inputs other than the drag input as described above. FIG. 15B illustrates an example of using a movement sensed by the mobile terminal 200 as an example of another user input.

Referring to FIG. 15A, first, the first drawing of FIG. 15A shows an example in which the user rotates his or her head to the right while wearing the HMD 100. In this case, the controller 180 may display an image of the second region 1210 on the display unit 151 based on the movement of the user's head, similarly to the second drawing of FIG. 15A.

In this state, the controller 180 may sense whether or not a preset situation has occurred. For example, when the user maintains a state for more than a preset period of time while turning his or her head to the right as described above, or when a preset touch input or a specific movement is sensed by the mobile terminal 200, the controller 180 may sense that the preset situation has occurred in the step S1304 of FIG. 13.

Meanwhile, when sensing that the preset situation has occurred, the controller 180 may sense the user's input through the mobile terminal 200. Furthermore, the user's input may be an input for rotating the mobile terminal 200 to tilt the mobile terminal 200 in a specific direction, as shown in the third drawing of FIG. 15B. In other words, as shown in the third drawing of FIG. 15B, when the user rotates the mobile terminal 200 to the right by more than a predetermined angle (1510a, 1510b), the controller 180 may sense a rotation speed, a rotation angle and a rotation direction through the sensing unit (for example, gyro sensor) of the mobile terminal 200. In addition, the controller 180 may change a region in the virtual space 1250 displayed on the display unit 151 according to the sensed rotation speed and rotation direction.

In other words, as shown in the third drawing of FIG. 15B, when the mobile terminal 200 is rotated on the right to be tilted in the gravity direction (1510a, 1510b), the controller 180 may display an image of a region in the virtual space 1250 currently displayed on the display unit 151, that is, the fourth region 1230 located on the right side of the second region 1210, on the display unit 151 according to the rotation of the mobile terminal 200 as shown in the fourth drawing of FIG. 15B.

In this case, an image of the virtual region 1250 displayed on the display unit 151 may of course be determined based on the sensed rotation angle, namely, angular velocity. In other words, as an angle at which the mobile terminal 200 is rotated for a predetermined period of time, that is, an angular velocity, increases, an image of one region in the virtual space 1250 located on the right from a region (second region 1210) of the virtual space 1250 currently displayed on the display unit 151 may be displayed on the display unit 151. Moreover, it is needless to say that a speed at which an image of another region in the virtual space 1250 is displayed on the display unit 151 may be determined based on a rotation speed of the mobile terminal 200, that is, an angular acceleration. In other words, as a rotation speed of the mobile terminal 200 increases, an image of another region in the virtual space 1250 may be displayed on the display unit 151 more quickly.

On the other hand, FIG. 15C is a conceptual view for explaining a process of displaying an image of the fourth region 1230 while an image of the second region 1210 is displayed on the display unit 151 according to a drag input sensed through the mobile terminal 200 or a rotation of the mobile terminal 200 in FIGS. 15A and 15B.

Referring to FIG. 15C, when the user is looking at the right side as shown in the first drawing of FIGS. 15A and 15B, an image of the second region 1210 of the virtual space 1250 may be displayed on the display unit 151. In this state, when the drag input 1500 or the rotation 1510a, 1510b in the rightward direction is sensed from the mobile terminal 200 as described above, the controller 180 may gradually display an image of a region of the virtual space 1250 located on the right side of the second region 1210 accordingly.

In other words, as shown in FIG. 15C, as the displayed region is gradually changed to the right, an image of the virtual space 1250 including a part of the second region 1210 on the left and a part of the fourth region 1230 on the right may be displayed on the display unit 151. Furthermore, as the length of the drag input increases or the rotation angle of the mobile terminal 200 increases, the image of the second region 1210 included in the image displayed on the display unit 151 may be decreased, and the image of the fourth region 1230 may be increased. In addition, only the image of the fourth region 1230 may be displayed on the display unit 151 as shown in the fourth drawing of FIGS. 15A and 15B.

On the other hand, the user's input may include various inputs other than the drag input as described above. FIG. 15D illustrates another example of using a movement sensed by the mobile terminal 200 as an example of such a user input.

First, referring first to the first drawing of FIG. 15D, the first drawing of FIG. 15D shows an example of lifting the head while the user wearing the HMD 100 looks at the front side. In this case, the controller 180 may display an image 1550 corresponding to the ceiling of the virtual space 1250 on the display unit 151 according to the user's gaze angle changed according to the movement of the user's head while an image of a region corresponding to the front side of the HMD 100, namely, the first region 1200, is displayed according to the movement of the user's head. The second drawing of FIG. 15D illustrates such an example.

In this state, the controller 180 may sense the occurrence of a preset situation as described above. Besides, when sensing that the preset situation has occurred, the controller 180 may sense the user's input through the mobile terminal 200. Moreover, such a user's input may be an input for moving the mobile terminal 200 in a specific direction.

In other words, as shown in the third drawing of FIG. 15D, when the user lifts the mobile terminal 200 in an upward direction, the controller 180 may sense a magnitude and direction of acceleration generated by the movement of the mobile terminal 200 through the sensing unit 240 (for example, acceleration sensor) of the mobile terminal 200. In addition, the controller 180 may change a region in the virtual space 1250 displayed on the display unit 151 according to the sensed magnitude and direction of acceleration.

In other words, as shown in the third drawing of FIG. 15D, when the mobile terminal 200 is moved to sense an acceleration applied by the user in an upward direction (a direction opposite to the gravity direction), the controller 180 may display an image 1550 corresponding to the ceiling of the virtual space 1250 and an image of the fourth region 1230 located behind the user on the display unit 151 as shown in the fourth drawing of FIG. 15D.

Referring to FIG. 15E showing a process of displaying the image 1550 corresponding to the ceiling of the virtual space 1250 and the image of the fourth region 1230 located behind the user on the display unit 151, when the user looks at the front side, an image of the first region 1200 of the virtual space 1250 may be displayed on the display unit 151 as shown in FIG. 15E. In this state, when an acceleration applied from the mobile terminal 200 in an upward direction (a direction opposite to the gravity direction) is sensed, the controller 180 may display an image of another region of the virtual space 1250, namely, the region 1550 corresponding to the ceiling, according to the sensed direction of acceleration. In this case, as shown in the second drawing of FIG. 15D, the controller 180 may display an image such as looking up the region 1550 corresponding to the ceiling. Furthermore, when the acceleration continuously applied in the upward direction from the mobile terminal 200 is continuously sensed, as shown in FIG. 15E, an image looking at the ceiling region 1550 of the virtual space 1250 in a vertical direction may be displayed on the display unit 151.

In this state, when the acceleration continuously applied from the mobile terminal 200 is continuously sensed, the controller 180 may change the user's gaze angle to be gradually moved backward through the ceiling of the virtual space 1250. Then, an image of the virtual space 1250 gradually generated in the back of the user, that is, the fourth region 1210, may be displayed according to the changed gaze angle. FIG. 15E illustrates an example in which an image of the fourth region 1230 located behind the user through the ceiling region 1550 is displayed on the display portion 151.

In this case, it is needless to say that the controller 180 can determine a speed at which an image of another region in the virtual space 1250 is displayed on the display unit 151 according to the sensed magnitude of acceleration. In other words, as a rotation speed of the mobile terminal 200 increases, an image of another region in the virtual space 1250 may be displayed on the display unit 151 more quickly.

On the other hand, in the above description, an example of displaying an image of another virtual space region in the right direction of the virtual space region currently displayed on the display unit 151 based on the drag input or rotation sensed from the mobile terminal 200 has been described. In addition, an example of displaying an image of another virtual space region in an upward direction of the virtual space region displayed on the display unit 151 based on an acceleration sensed by the mobile terminal 200 has been described. However, it merely described one example of the operation of the present disclosure for the sake of convenience of explanation, it should be understood that the present disclosure is not limited thereto.

In other words, according to the present disclosure, based on the drag input or rotation sensed by the mobile terminal 200, an image of another virtual space region in the leftward, upward or downward direction as well as the rightward direction of the virtual space region currently displayed on the display unit 151 may of course be displayed. Moreover, based on the acceleration sensed by the mobile terminal 200, an image of another virtual space region in the downward, rightward or leftward direction as well as the upward direction of the virtual space region currently displayed on the display unit 151 may of course be displayed.

Meanwhile, in the above description, the mobile terminal 200 sensing the preset situation or the user's input may be in a state of operating in the dose mode described above. In other words, the mobile terminal 200 may operate in a mode in which the display unit 251 consumes a minimum current or power in an inactive state to sense the touch input through the acceleration sensor or the touch sensor. In other words, the mobile terminal 200 may operate in a mode in which only the display unit 251 is turned off, and both the touch sensor and the acceleration sensor maintain an on state.

Meanwhile, when a preset situation occurs, the mobile terminal 200 according to an embodiment of the present disclosure may display the current state, which is in a state of controlling image information according to the user's head movement sensed from the HMD 100 and the user's input sensed through the mobile terminal 200, on the display unit 151.

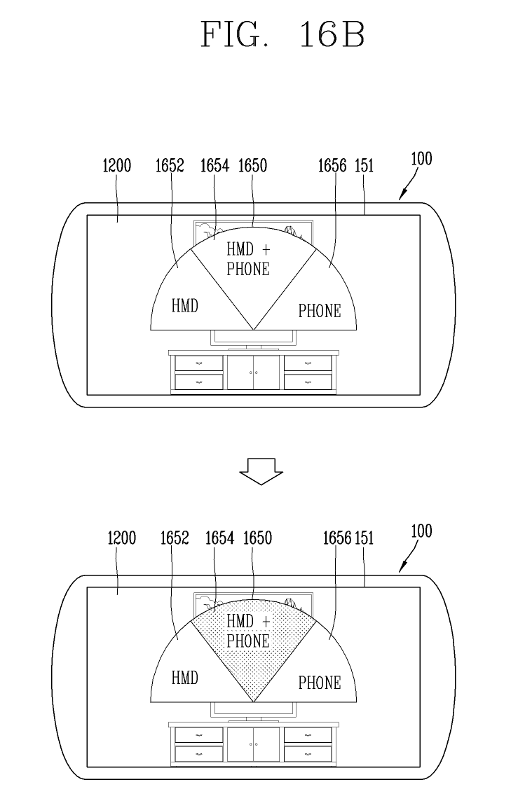

FIG. 16A illustrates an example of allowing the HMD 100 related to the present disclosure to display screens differently according to a device controlling image information displayed in the HMD 100.

For example, when a preset situation occurs as described above, the controller 180 may display a state of the HMD 100 being currently driven according to a sensing value sensed by the HMD 100 and the mobile terminal 200. In this case, as shown in (a) of FIG. 16A, the controller 180 may display information 1600 on all control devices that control image information currently displayed on the display unit 151, such as “HMD+PHONE.”

Alternatively, on the contrary, as shown in (b) of FIG. 16A, the controller 180 may display a state in which the preset situation occurs and a state in which the preset situation does not occur on the display unit 151 to be distinguished using a graphic object 1610. In this case, the user may determine whether or not image information displayed on the display unit 151 is controlled by all sensing values currently sensed by the HMD 100 and the mobile terminal 200 according to whether or not the graphic object 1610 is displayed.

Meanwhile, the controller 180 of the HMD 100 according to an embodiment of the present disclosure may display a menu screen for allowing the user to select a device for controlling image information displayed on the display unit 151 when a preset situation occurs.

FIG. 16B is an exemplary view illustrating an example of allowing the HMD 100 related to the present disclosure to display a menu for selecting a device that controls image information, that is, an image of the virtual space, displayed on the display unit, in this case.

Referring to the first drawing of FIG. 16B, the first drawing of FIG. 16B illustrates an example of displaying a menu screen 1650 for allowing the user to select a device that controls image information displayed on the display unit 151 when the preset situation occurs. As shown above in FIG. 16B, the menu screen 1650 may include a plurality of regions that are respectively distinguished, and each of the regions may respectively correspond to a different method for controlling image information displayed on the display unit 151.

For example, a first region 1652 of the menu screen 1650 may correspond to a control method of controlling image information displayed on the display unit 151 according to a movement sensed by the HMD 100. Accordingly, the first region 1652 may display information (“HMD”) for indicating that the device controlling the display of image information is the HMD. On the contrary, a third region 1656 of the menu screen 1650 may correspond to a control method of controlling image information displayed on the display unit 151 according to a user input sensed by the mobile terminal 200. Accordingly, the third region 1656 may display information (“phone”) for indicating that the device controlling the display of image information is the mobile terminal.

Furthermore, a second region 1654 of the menu screen 1650 may correspond to a control method of controlling image information displayed on the display unit 151 based on both a movement sensed by the HMD 100 and a user's input sensed through the mobile terminal 200. Accordingly, the third region 1654 may display information (“HMD+Phone”) for indicating that the device controlling the display of image information is the mobile terminal as well as the HMD.

Meanwhile, in this state, the controller 180 of the HMD 100 may select any one of the region 1652, 1654, 1656 of the menu screen 1650 according to the user's selection. For example, the controller 180 may select any one of the regions 1652, 1654, 1656 of the menu screen 1650 based on the user's head movement sensed through the HMD 100 or the user's input sensed through the mobile terminal 200. In this case, the controller 180 may display any one region selected by the user to be distinguished from the other regions. The second drawing of FIG. 16B shows an example in which any one region of the menu screen 1650 is selected as described above.

On the other hand, according to the above description, it has been described that the HMD 100 according to an embodiment of the present disclosure can reset a specific region of the virtual space 1250 set to correspond to the forward direction 1100 of the HMD 100 according to the user's selection.

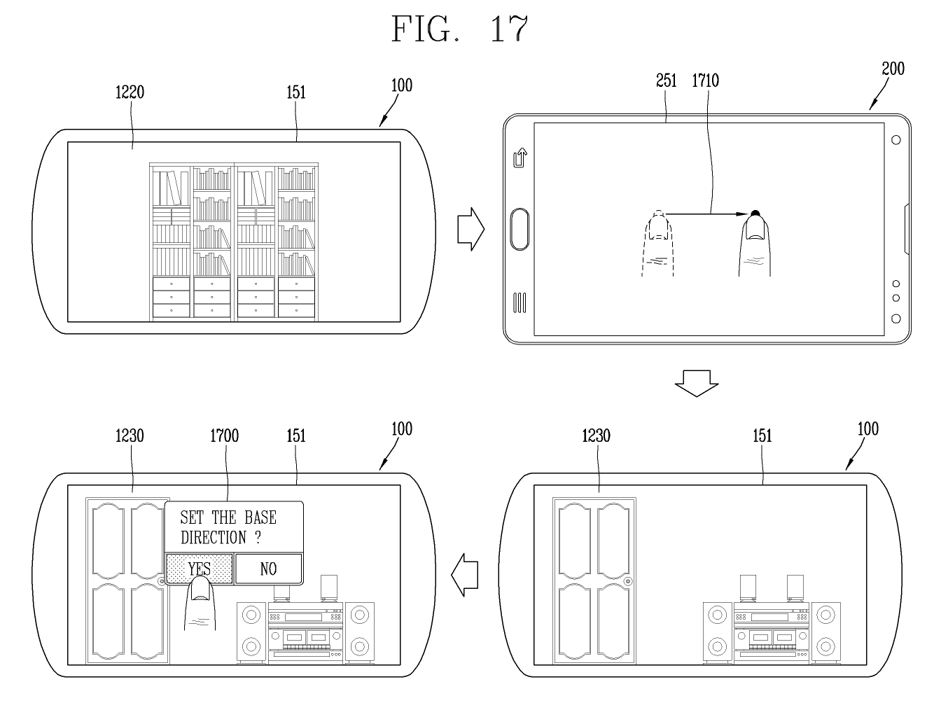

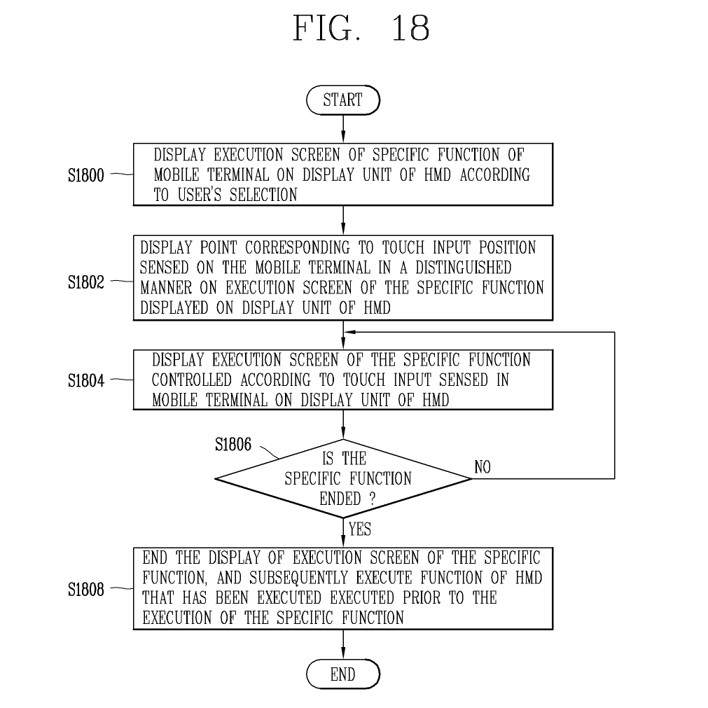

FIG. 17 illustrates an example of allowing the HMD 100 according to an embodiment of the present disclosure to reset an image of the virtual space corresponding to the forward direction 1100 of the HMD 100. Hereinafter, in the description of FIG. 17, it will be described on the assumption that the virtual space 1250 of FIG. 12A is formed for the sake of convenience of explanation. In addition, as shown above in 12B, it will be described on the assumption that the first region 1200 among the regions of the virtual space 1250 is set to correspond to the forward direction of the HMD 100.

First, referring to the first drawing of FIG. 17, the first drawing of FIG. 17 shows an example in which an image of the third region 1220 in the virtual space 1250 is displayed on the display unit 151 according to the user's head movement. In this state, subsequent to the occurrence of a preset situation, as shown in the second drawing of FIG. 17, when a drag input 1710 applied in the left direction on the display unit 251 of the mobile terminal 200 is applied, the controller 180 may display an image of a region located on the left side of the third region 1220 in the virtual space 1250, that is, the fourth region 1230, on the display unit 151. Accordingly, as described above, the HMD 100 according to an embodiment of the present disclosure may further use the user's input sensed through the mobile terminal 200 to display an image of a region in the virtual space, which is difficult to display it as the user's head movement in the human structure.

On the other hand, the controller 180 may set a region in the virtual space displayed on the display unit 151 as a region corresponding to the forward direction of the HMD 100 while an image of another region other than a region currently corresponding to the front direction of the HMD 100 as described above is displayed on the display unit 151. In other words, as illustrated above in FIG. 14, when there is a user's input for changing a region of the virtual space corresponding to the forward direction of the HMD 100, the user may check whether or not an image of the virtual space region currently displayed on the display unit 151 is set as a “region corresponding to the forward direction 1100 of the HMD 100.” The fourth drawing of FIG. 17 shows an example in which a menu screen 1700 for allowing the user to select a base direction, that is a “region corresponding to the forward direction 1100 of the HMD 100” is displayed on the display unit 151.

When the user selects a change of the “region corresponding to the forward direction 1100 of the HMD 100” as shown in the fourth drawing of FIG. 17 while the menu screen 1700 is displayed, the controller 180 may determine a direction in which the user looks at a region of the virtual space currently displayed on the display unit 151, that is, the fourth region 1230, as the base direction. Accordingly, the fourth region 1230 may be set as a region corresponding to the forward direction 1100 of the HMD 100, and thus a virtual space image of the specific region may be displayed on the display unit 151 based on the user's head movement sensed through the HMD 100 and/or the user's input sensed through the mobile terminal 200 with respect to the fourth region 1230.

On the other hand, as described above, the controller 180 of the HMD 100 according to an embodiment of the present disclosure may control the mobile terminal 200 to execute a specific function according to the user's selection among functions executable in the mobile terminal 200. In addition, a screen related to the execution of the specific function executed in the mobile terminal 200, that is, an execution screen, may be displayed on the display unit 151 of the HMD 100.

FIG. 18 is a flowchart illustrating an operation process of displaying an execution screen of a specific function executed by the mobile terminal 200 on the display unit 151 of the HMD 100 according to an embodiment of the present disclosure.

Referring to FIG. 18, the controller 180 of the HMD 100 according to an embodiment of the present disclosure may execute at least one of functions executable in the mobile terminal 200 connected to the HMD 100 while content selected by the user is played back. Then, a screen related to the executed function may be displayed on the display unit 151 (S1800). Furthermore, when an execution screen of the function executed in the mobile terminal 200 is displayed on the display unit 151 of the HMD 100 as described above, the controller 180 may maintain the content currently being played back in the HMD 100 in a suspended state.

Here, at least one function executable in the mobile terminal 200 may be related to an event occurring in the mobile terminal 200. For an example, when a preset event occurs in the mobile terminal 200, the controller 180 may display alarm information for notifying the occurrence of the event on the display unit 151 of the HMD 100. In this case, the user may select whether to continue watching the content of the HMD 100 or execute a specific function corresponding to an event that has occurred in the mobile terminal 200.

For example, when the user selects the execution of a function corresponding to the occurred event according to the alarm information displayed on the display unit 151, or when a preset user's input is applied while the alarm information is displayed, it may be recognized that the user has select the execution of a specific function of the mobile terminal 200 corresponding to the event.

In addition, when the user selects the execution of a specific function according to an event occurred in the mobile terminal 200, the controller 180 may control the mobile terminal 200 to execute a function corresponding to the occurred event in the mobile terminal 200. Moreover, a screen related to the execution of a function executed in the mobile terminal 200 may be displayed on the display unit 151 of the HMD 100.

Alternatively, the at least one function may be a function according to the user's selection. In other words, the controller 180 may control the mobile terminal 200 to execute at least one of the functions of the mobile terminal 200 connected to the HMD 100 according to the user's selection in the step S1800. Besides, a screen related to a function executed by the mobile terminal 200, that is, an execution screen of the at least one function, may be received from the mobile terminal 200 and the received execution screen may be displayed on the display unit 151.

Meanwhile, the at least one function may be selected in various ways. For example, when there is a preset user's input, the controller 180 of the HMD 100 may control the mobile terminal 200 to execute its resultant specific function of the mobile terminal 200. Here, the preset user's input may be a preset user's head movement (preset gesture) sensed through the HMD 100 or a preset touch input applied to the touch screen 251 of the mobile terminal 200 or a user's gesture sensed through the mobile terminal 200. In this case, the controller 180 of the HMD 100 may execute a specific function of the mobile terminal 200 corresponding to a touch input applied to the touch screen 251 or a movement sensed through the HMD 100 or the mobile terminal 200, and display the execution screen on the display unit 151.

Alternatively, the controller 180 of the HMD 100 may display a list of functions that can be executed through the mobile terminal 200 on the display unit 151 according to the user's selection. In other words, the controller 180 may display a list of the executable functions on the display unit 151 when there is a preset user's input. In addition, the controller 180 may select at least one of the executable functions from the user's movement sensed through the HMD 100 or the mobile terminal 200, and execute the selected function in the mobile terminal 200. Moreover, the controller 180 may receive image information related to the executed function from the mobile terminal 200 and display the received image information on the display unit 151 to allow the execution screen of the function to be displayed on the display unit 151.

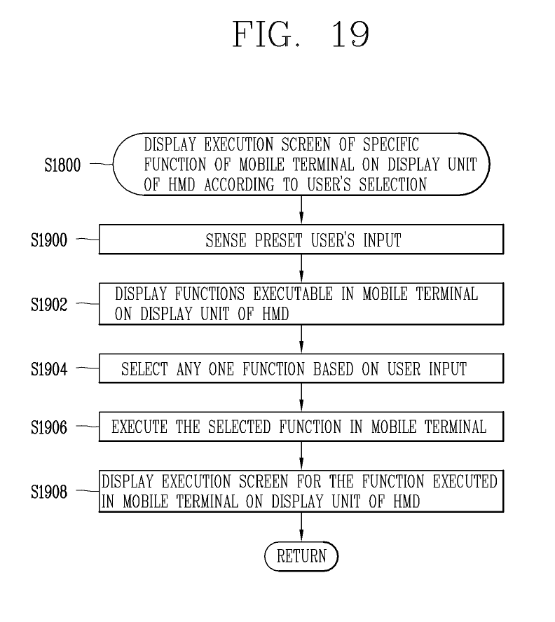

An operation process of displaying the executable functions of the mobile terminal 200 and displaying an execution screen of any one of the functions on the display unit 151 according to the user's selection will be described in more detail with reference to FIG. 19.

Meanwhile, here, it is needless to say that the image information related to the “function executed in the mobile terminal 200” may not be displayed on the touch screen 251 of the mobile terminal 200. It is because when the HMD 100 according to an embodiment of the present disclosure is connected to the mobile terminal 200, and the HMD 100 is worn by the user, the mobile terminal 200 operates in a “doze mode.” Here, the “doze mode” may be a mode in which the touch screen 251 is turned off and the touch sensor, the acceleration sensor, and the gyro sensor of the mobile terminal 200 are all turned on, as described above. Accordingly, though the movement of the mobile terminal 200, such as a touch input applied to the touch screen 251, an acceleration sensed through the acceleration sensor of the mobile terminal 200, a rotation sensed through the gyro sensor, or the like, can be sensed, a light emitting device for displaying image information on the touch screen 251 may be turned off in a state image information is not displayed.

Meanwhile, when the content is played back through the HMD 100, the controller 180 may allow the mobile terminal 200 to be driven in an inactive state in which the user's control command input is restricted. It is to prevent a specific function of the mobile terminal from being executed due to a malfunction of the user while the content is played back by the user through the HMD 100.

The inactive state in which the input of the control command is restricted may be an operation state of allowing the mobile terminal 200 to sense only a preset user's input. Furthermore, the specific user's input may be a specific touch input (for example, a plurality of touch inputs forming a specific pattern or a drag input for applying a specific trace) applied to the touch screen 251 of the mobile terminal 200.

Meanwhile, as described above, the controller 180 may sense a user input applied to the mobile terminal 200 through the mobile terminal 200 operating in a doze mode. Here, the mobile terminal 200 may be in a doze mode while in an inactive state. When the sensed user input is the specific user's input in this state, the controller 180 may switch the operation state of the mobile terminal 200 from an inactive state in which the input of the control command is restricted to an active state in which the input of the control command is not restricted Then, the mobile terminal 200 may sense the user's input applied through the touch screen 251 without restriction while the mobile terminal 200 operates in a doze mode. In addition, only for a case where the mobile terminal 200 is driven in an inactive state as described above, a specific function of the mobile terminal 200 according to the user's input may be executed, or one point corresponding to the touch input sensed from the touch screen 251 of the mobile terminal 200 may be displayed on the display unit 151 of the HMD 100.

On the other hand, when an execution screen of a function executed in the mobile terminal 200 is displayed on the display unit 151 of the HMD 100 as described above, the controller 180 may control a function executed in the mobile terminal 200 according to the user's input. Moreover, the controller 180 may sense the user's touch input applied through the touch screen 251 of the mobile terminal 200 as the user's input for controlling the function to be executed.

Meanwhile, the controller 180 may display a point to which a touch input is applied to the touch screen 251 on the display unit 151 of the HMD 100 to control the function to be executed using the touch input.

Here, when a touch object (e.g., user's finger) for applying a touch input to the touch screen 251 of the mobile terminal 200 is located within a predetermined distance from the touch screen 251, the controller 180 may sense touch object. Furthermore, the position of the sensed touch object may be displayed on an execution screen displayed on the display unit 151. Accordingly, when the touch object moves within a predetermined distance without being brought into contact with the touch screen 251 (in case of hovering), a movement trace of the touch object may be displayed on an execution screen displayed on the display unit 151.

In addition, when the touch object applies a touch input to the touch screen 151, the controller 180 may display one point on the execution screen corresponding to the position on the touch screen 251 at which the touch input is sensed. Here, the position to which the touch input is applied may be displayed separately from the position of the sensed touch object.

On the other hand, the controller 180 may regard one point displayed on the execution screen according to the touch input as a point applied to the touch input. Moreover, the controller 180 may control a function executed in the mobile terminal 200 according to one point on the execution screen to which the touch input is regarded as being applied. Accordingly, the user may apply a user input related to a function currently executed in the mobile terminal 200 based on the display displayed on the display unit 151.

For example, the applied user input may be a drag input from a specific point to a specific point on an execution screen displayed on the display unit 151, or a touch input to a specific menu or a specific item or a specific graphic object. Then, the controller 180 may transmit information on the user's touch input displayed on the execution screen, such as a specific item selected by the drag input or the touch input, or a specific graphic object, to the mobile terminal 200.

Besides, the controller 180 may control the mobile terminal 200 such that a function being executed by the mobile terminal 200 is controlled according to information transmitted to the mobile terminal 200. Furthermore, the controller 180 may receive image information corresponding to an execution screen of a function controlled according to the user's touch input displayed on the execution screen from the mobile terminal 200. Furthermore, the controller 180 may display an execution screen of a function (a function executed in the mobile terminal 200) controlled according to the user's touch input on the display unit 151 using the received image information (S1804).

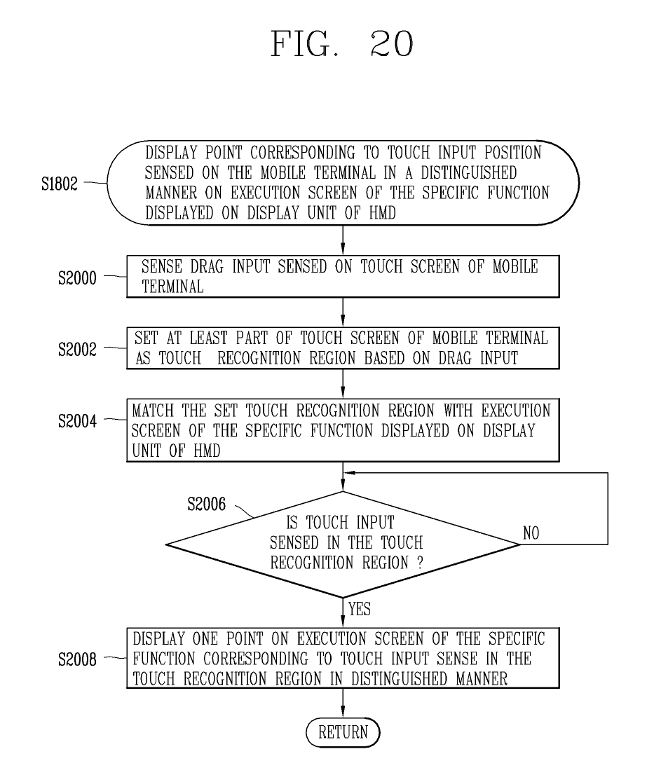

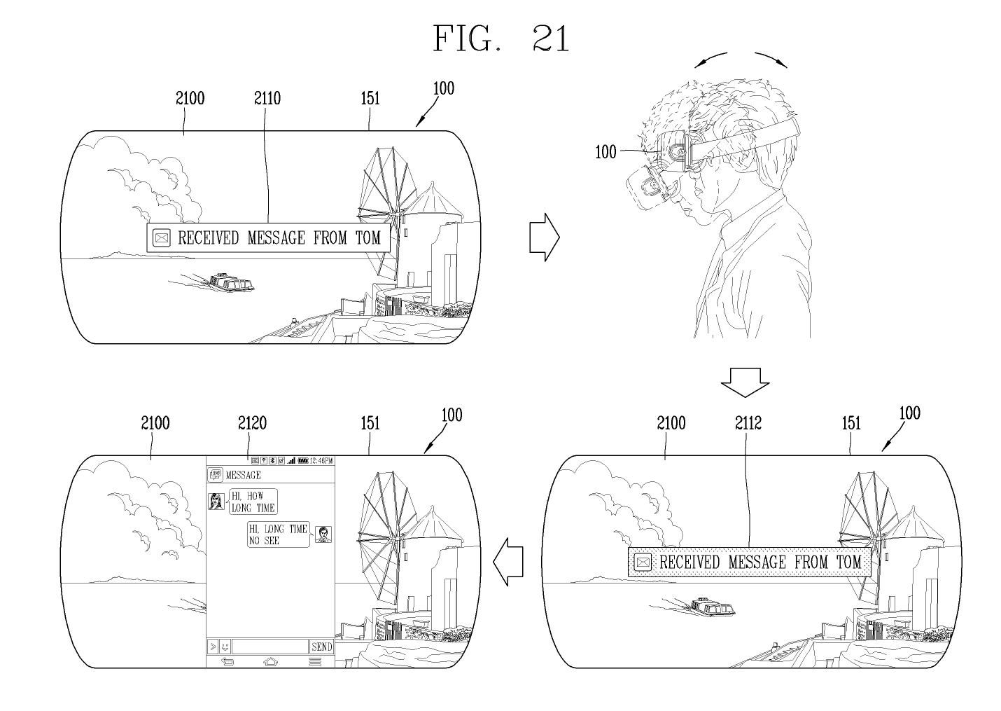

Meanwhile, in the step S1802, the controller 180 may allow the execution screen displayed on the display unit 151 to be matched with at least a part of the touch screen 251 of the mobile terminal 200. In other words, the controller 180 may allow the execution screen displayed on the display unit 151 to correspond to at least a part of the touch screen 251 of the mobile terminal 200, thereby displaying one point on the execution screen corresponding to a touch input point of the touch screen 251 to be distinguished according to the touch input. For this purpose, the controller 180 may set at least a part of the touch screen 251 as a “touch recognition region” for recognizing the user's touch input. In addition, the controller 180 may match each region of the “touch recognition region” to correspond to each region of the execution screen displayed on the display unit 151 of the HMD 100. An operation process of setting a touch recognition region from the user and matching the set region with the region displayed with the execution screen will be described in more detail with reference to FIG. 20.

Meanwhile, the controller 180 may sense whether or not the end of a function executed in the mobile terminal 200 is selected (S1806). For example, the controller 180 may sense whether or not the user's touch input point displayed on the execution screen is to select a graphic object or menu for ending a function executed in the mobile terminal 200. Besides, when the end of the function to be performed is not selected by the touch input, the controller 180 proceeds again to the step S1804 to display an execution screen of a function controlled according to the user's touch input (a function executed in the mobile terminal 200) on the display unit 151.

On the contrary, in the step S1806, when the user's touch input sensed on the touch screen 251 of the mobile terminal 200 is to select a graphic object or menu for ending a function executed in the mobile terminal 200 on an execution screen displayed on the display unit 151 of the HMD 100, 200, the controller 180 may terminate the function executed in the mobile terminal 200 according to the touch input.

When the function executed in the mobile terminal 200 is ended as described above, the controller 180 terminates the display of the execution screen displayed on the display unit 151 of the HMD 100. Furthermore, when the display of the execution screen is ended, the controller 180 may subsequently play back the content of the HMD 100 that the user has watched prior to executing the function of the mobile terminal 200 (S1808). In this case, the controller 180 may control image information displayed on the display unit 151 according to the user's head movement sensed by the HMD 100.

In this case, the controller 180 may control image information displayed on the display unit 151 according to a movement or a touch input sensed through the mobile terminal 200, as the need arises. In addition, the controller 180 may of course control image information displayed on the display unit 151 by further using the user's input sensed from the mobile terminal 200 while displaying image information according to a movement sensed by the HMD 100.

Moreover, it is needless to say that, in the step S1808, the controller 180 may play back new content according to the user's selection without subsequently playing back the content. In this case, the controller 180 may allow the user to display information including a content list for selecting the new content on the display unit 151.

Meanwhile, according to the foregoing description, it has been mentioned that the controller 180 of the HMD 100 according to an embodiment of the present disclosure displays a list of functions that can be executed by the mobile terminal 200 according to the user's selection, and display any one execution screen among the functions according to the user's selection on the display unit 151 of the HMD 100. FIG. 19 is a flowchart showing in more detail an operation process of executing a specific function of the mobile terminal according to the user's selection and displaying a screen related to the executed function.

Referring to FIG. 19, the controller 180 of the HMD 100 according to an embodiment of the present disclosure may sense whether or not there is a preset user's input while the image information of the content according to the user's selection is displayed on the display unit 151 (S1900).

Here, the preset user's input may include various inputs. For example, the preset user input may be at least single touch input applied to the touch screen 251 of the mobile terminal 200. The touch input may be a touch-and-drag input of a user who draws a specific trace, or a plurality of touch inputs that form a specific pattern. Alternatively, it may be at least single touch input applied to a specific region of the touch screen 251.

Alternatively, the preset user's input may be a specific user's gesture. For example, the specific user's gesture may be a head gesture taken by the user while wearing the HMD 100 or a gesture taken while holding the mobile terminal 200. This gesture may be sensed according to an acceleration or angular acceleration measured through the sensors (e.g., gyro sensors or acceleration sensors, etc.) provided in the HMD 100 or the mobile terminal 200, and the controller 180 may determine whether or not the user's gesture is a preset specific gesture according to the sensing result.

On the other hand, where there is a preset user's input as a result of sensing in the step S1900, the controller 180 may display a list of functions executable in the mobile terminal 200 on the display unit 151 (S1902). For example, the executable functions may be transmitted from the mobile terminal 200 to the HMD 100 when the mobile terminal 200 is connected to the HMD 100. Alternatively, the executable functions may be at least one function preset by the user before the mobile terminal 200 is connected to the HMD 100.

The controller 180 of the HMD 100 may display the functions in various ways. For example, the controller 180 may display graphic objects corresponding to the functions in at least one region on the display unit 151 of the HMD 100. Furthermore, the graphic objects may be displayed in a designated specific region on the display unit 151 in a form in which the graphic objects are listed or arranged. Alternatively, the controller 180 may of course display the functions in the form of a text list.

In this state, the controller 180 may select at least one of the listed or arranged functions of the mobile terminal 200 (S1904). In the step S1904, the controller 180 may select any one of the functions based on the user's head movement sensed through the HMD 100 or the user's gesture or touch input sensed through the mobile terminal 200. In other words, when the user turns or nods his or her head to the left or the right or nods his or her head, the controller 180 may select any one of graphic objects of functions displayed on the display 151 according to the head movement of the user who is turning or nodding. Moreover, the selected graphic object may be displayed to be distinguished from other graphic objects. Besides, when the user nods his or her head back and forth more than a predetermined number of times, it may be recognized that a function corresponding to any one of the graphic objects currently displayed in a distinguished manner is selected by the user.

Similarly, when the mobile terminal 200 is rotated or moved to the left or right, or according to a direction in which a touch input or drag input is applied, the controller 180 may select any one of the graphic objects corresponding to the respective functions. Furthermore, when the mobile terminal 200 moves for more than a preset number of times or a preset period of time in an upward direction (for example, a direction opposite to the gravity direction) or downward direction (a gravity direction), it may be recognized that a function corresponding to a currently selected graphic object is selected by the user.

When a specific function is selected as described above, the controller 180 may control the mobile terminal 200 to execute the selected function in the mobile terminal 200 (S1906). Accordingly, the mobile terminal 200 may execute a specific function selected by the user through the HMD 100.

On the other hand, it is needless say that even if the function of the mobile terminal 200 is executed, no image information may be displayed on the touch screen 251 of the mobile terminal 200. In other words, as described above, when the mobile terminal 200 is operating in a doze mode, through the mobile terminal 200 executes a specific function according to the user's selection, the light emitting device of the touch screen 251 may maintain an off state.

On the other hand, in the mobile terminal 200 as described above, when a function selected by the user is executed, the controller 180 may receive image information related to the executed function from the mobile terminal 200. Furthermore, the controller 180 may display the received image information on the display unit 151, and allow the user to check an execution screen of a function being executed by the mobile terminal 200 through the display unit 151 of the HMD 100 (S1908). In addition, the controller 180 may proceed to the step 1802 of FIG. 18, and display a touch input sensed through the touch screen 251 of the mobile terminal 200 on the display unit 151 of the HMD 100, and control the mobile terminal 200 such that a function executed in the mobile terminal 200 to be controlled according to the touch input.

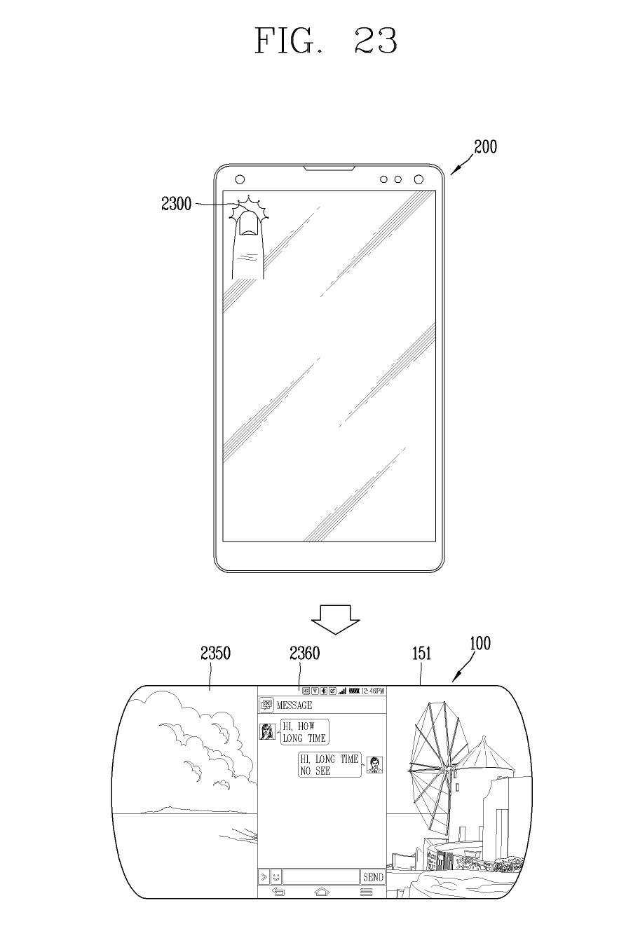

An example of displaying a list of functions executable in the mobile terminal 200 on the display unit 151 of the HMD 100 according to the user's selection and displaying a screen on which any one of the displayed functions is executed on the display unit 151 of the HMD 100 will be described in more detail with reference to FIG. 23.

Meanwhile, the HMD 100 according to an embodiment of the present disclosure may allow the user to set a partial region of the touch screen 251 of the mobile terminal 200 in advance, and control a function being executed in the mobile terminal 200. For this purpose, the controller 180 of the HMD 100 according to the embodiment of the present disclosure may match at least a partial region of the touch screen 251 of the mobile terminal 200 set by the user with a region on the display unit 151 of the HMD 100 on which an execution screen for a function of the mobile terminal 200 is displayed. Furthermore, one point corresponding to the user's touch input applied to the touch screen 251 may be displayed on an execution screen displayed on the display unit 151 of the HMD 100.

FIG. 20 is a flowchart illustrating an operation process of allowing the HMD 100 according to the embodiment of the present disclosure to display one point on the execution screen corresponding to a touch input entered through a mobile terminal 200.

Referring to FIG. 20, the controller 180 of the HMD 100 according to the embodiment of the present disclosure may sense a drag input applied to the touch screen 251 of the mobile terminal 200 while an execution screen of a function executed in the mobile terminal 200 is displayed on the display unit 151 of the HMD 100 (S2000).

In addition, the controller 180 may set at least a partial region on the touch screen 251 as a “touch recognition region” based on the drag input (502). For example, when the drag input is performed a plurality of number of times in a horizontal or vertical direction, the controller 180 may set one region on the touch screen 251 formed by the plurality of drag inputs as the “touch recognition region.” Alternatively, when the drag input is applied once in a specific direction, one region on the touch screen 251 may be set as the “touch recognition region” according to the applied length and direction of the drag trace. In this case, the controller 180 may set a region having a length of the drag input, a distance between the two vertexes facing each other, that is, a length of a diagonal line as the “touch recognition region.”

Meanwhile, when the touch recognition region is formed in the step S2002, the controller 180 may match the formed touch recognition region and a region on the display unit 151 of the HMD 100 displayed with an execution screen of a specific function executed in the mobile terminal 200 with each other (S2004). For example, the controller 180 may allow each part of the touch recognition region set in the mobile terminal 200 to correspond to each part of a region of the display unit 151 displayed with the execution screen.

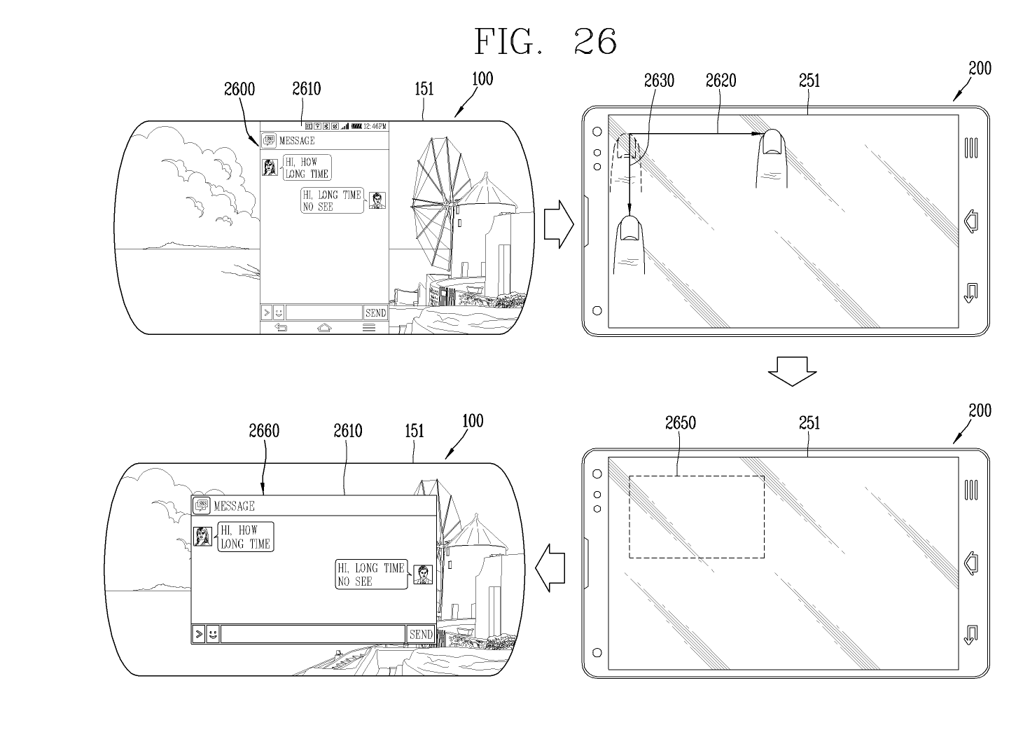

On the other hand, in this case, the controller 180 may change a shape of the execution screen displayed on the display unit 151 of the HMD 100 based on a shape of the touch recognition region formed on the touch screen 251. In this case, the shape of the execution screen may have the same shape as that of the touch recognition region. Accordingly, the user may more precisely check a position to which the touch input is applied on the execution screen, and more easily control a function executed in the mobile terminal 200 through the execution screen displayed on the HMD 100. An example in which the shape of the execution screen is changed according to the shape of the touch recognition region will be described below in more detail with reference to FIG. 26.

Meanwhile, when a touch recognition region formed on the touch screen 251 of the mobile terminal 200 and a region on the display unit 151 of the HMD 100 displayed with the execution screen match with each other in the step S2004, the controller 180 may sense whether or not a touch input is applied within the touch recognition region (S2006). In the step S2006, even though there is a touch input applied to the touch screen 251, when the touch input is sensed outside the touch recognition region, it is determined that the touch input is not applied.

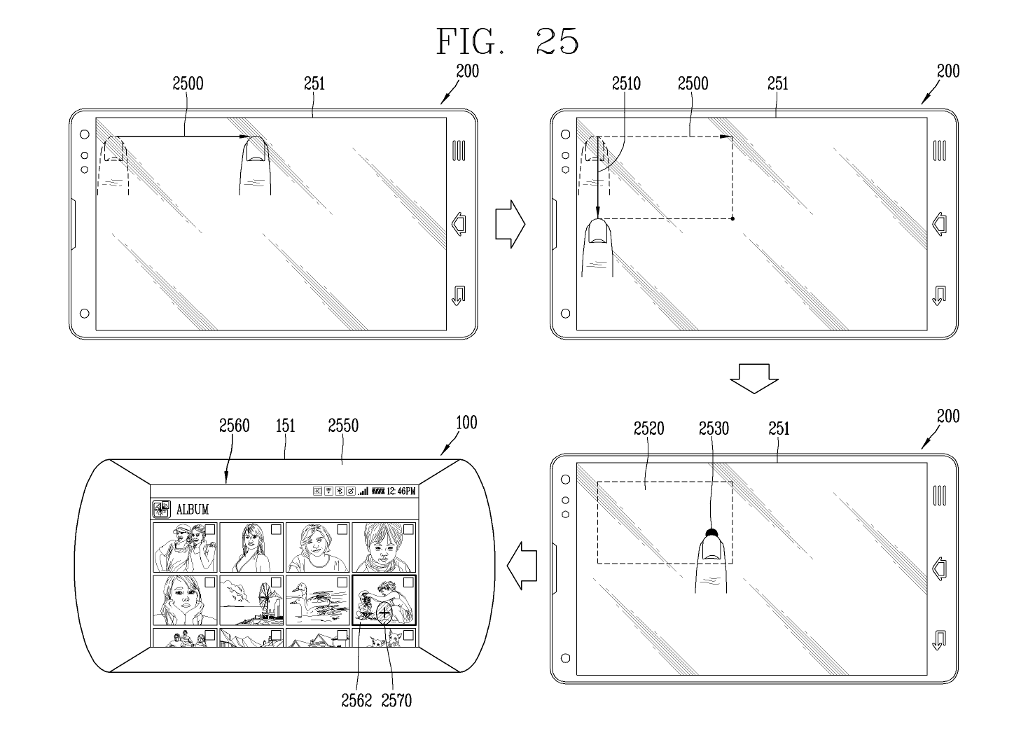

On the other hand, when there is a sensed touch input as a result of sensing in the step S2006, the controller 180 may display one point on the display unit 151 displayed with the execution screen corresponding to one point within the touch recognition region at which the touch input is sensed in a distinguished manner (S2008). In other words, the controller 180 may display one point on the execution screen corresponding to the touch input through the distinguished display. Accordingly, in the present disclosure, the user may control a function to be executed in the mobile terminal 200 through an execution screen displayed on the display unit 151 of the HMD 100 using a touch input applied by the user to the touch screen 251 (step S1804 in FIG. 18). An example of displaying a touch input point sensed in the touch recognition region formed on the touch screen 251 of the mobile terminal 200 at one point on an execution screen displayed on the display unit 151 of the HMD 100 will be described below in more detail with reference to FIG. 25.

In the above description, an operation process of allowing the HMD 100 according to an embodiment of the present disclosure to execute a specific function executable in the mobile terminal 200, and display a touch input applied to the touch screen 251 of the mobile terminal 200 on the execution screen of the specific function has been described in detail with reference to a plurality of flowcharts.

In the following description, examples of allowing the HMD 100 according to an embodiment of the present disclosure to execute a specific function executable in the mobile terminal 200 and examples of displaying a touch input point sensed through the touch screen 251 of the mobile terminal 200 on an execution screen displayed on the display unit 151 of the HMD 100 will be described in more detail with reference to exemplary views.

First, in the present disclosure as described above, an example of selecting any one of various functions executable in the mobile terminal 200 according to a user's selection or a specific situation (e.g., a preset situation occurs in the mobile terminal 200, etc.) and displaying an execution screen of the selected function on the display unit 151 of the HMD 100 has been described.

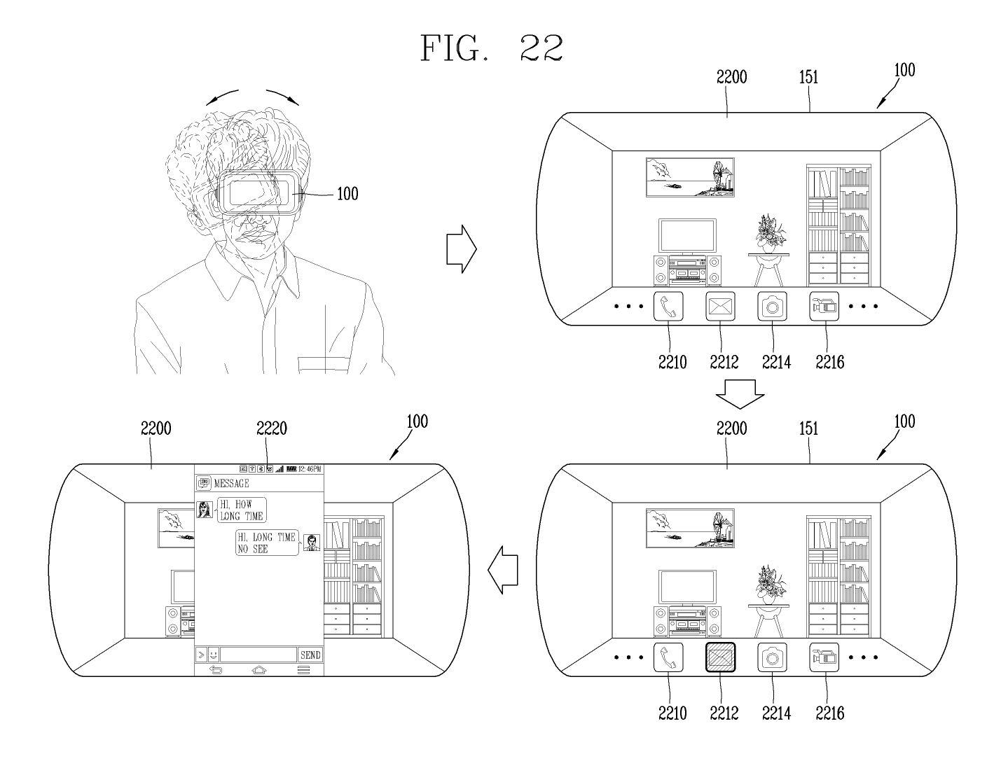

FIGS. 21 through 23 are exemplary views illustrating examples of allowing the HMD 100 according to an embodiment of the present disclosure to execute a specific function in the mobile terminal 200 and examples of displaying a screen related to the executed function on the display unit according to the user's selection.

First, FIG. 21 illustrates an example of executing a specific function of the mobile terminal 200 according to an event occurred in the mobile terminal 200 and displaying the execution screen thereof on the display unit 151.

For example, when a preset event occurs in the mobile terminal 200, the controller 180 of the HMD 100 according to an embodiment of the present disclosure may notify the HMD 100 of the occurrence of the occurred event. Then, the controller 180 may display alarm information 2110 corresponding to the event occurred in the mobile terminal 200 on the display unit 151 as shown in the first drawing of FIG. 21. In this case, the alarm information 2110 may be displayed on at least a part of the screen 2100 of the display unit 151 in which the content currently being played back in the HMD 100 is displayed, as shown in the first drawing of FIG. 21.

Meanwhile, in this state, the controller 180 of the HMD 100 may sense the user's input. For example, the user's input may be the user's preset head movement sensed through the HMD 100, as shown in the second drawing of FIG. 21. In other words, as shown in the second drawing of FIG. 21, when the user nods his or her head back and forth, the controller 180 may sense the user's head movement, and sense it as the user's input for executing a specific function of the mobile terminal 200 corresponding to the currently displayed alarm information.

On the other hand, in the above description, it is assumed that the user's input is a preset head movement of the user, but it is needless to say that various user's gestures may also be the user's input. For example, the controller 180 may sense the user's gesture sensed through the mobile terminal 200 or a movement of such as rotation (angular acceleration) or movement (acceleration) sensed by the mobile terminal 200, or sense whether or not there is the user's input based on a touch input applied through the touch screen 251 of the mobile terminal 200. On the other hand, when the user's input through the preset gesture or the like is sensed as shown in the second drawing of FIG. 21, the controller 180 of the HMD 100 may display alarm information 2112 currently displayed on the display unit 151 in a distinguished manner according to the sensed user's input as shown in the third drawing of FIG. 21. Through this display, the controller 180 of the HMD 100 may display for the user that the execution of a specific function of the mobile terminal 200 corresponding to the current alarm information is selected.

Meanwhile, when the specific alarm information 2112 is displayed in a distinguished manner, the controller 180 may execute a specific function of the mobile terminal 200 corresponding to the alarm information 2112 displayed in a distinguished manner. For example, as shown in the first drawing of FIG. 21, when the currently displayed alarm information 2112 is to notify the user of a message received by the mobile terminal 200, the controller 180 may sense that the user's input as shown in the third drawing of FIG. 3 is to allow the user to select the display of the received message content and the execution of a message function to reply the receive message.

Therefore, the controller 180 may execute a message function of the mobile terminal 200 as shown in the fourth drawing of FIG. 21. Here, the controller 180 may control the mobile terminal 200 to execute the message function in the mobile terminal 200. Furthermore, image information 2120 for a message function executed in the mobile terminal 200 may be received from the mobile terminal 200 and displayed on the display unit 151 of the HMD 100. The fourth drawing of FIG. 21 illustrates an example in which an execution screen 2120 of a message function executed in the mobile terminal 200 is displayed on the display unit 151 of the HMD 100.

On the other hand, in the above description, a message reception event occurs in the mobile terminal 200 for the sake of convenience of explanation, and a message function is executed in the mobile terminal 200 accordingly. However, the present disclosure is not limited thereto. In other words, various events, for example, an incoming call alarm or an alarm according to a preset schedule may be included in the event, and in this case, a function of the mobile terminal 200, which is executed according to the preset user's gesture may be different according to the occurred event.

Meanwhile, as shown in FIG. 21, a function executed in the mobile terminal 200 may of course be determined not only according to an event occurring in the mobile terminal 200, but also according to a user's selection. For example, the user may select any one of a plurality of functions executable in the mobile terminal 200 and execute the relevant function or apply a preset user's input corresponding to a specific function to execute a specific function corresponding to the user's input in the mobile terminal 200. Hereinafter, FIGS. 22 and 23 are exemplary views showing examples of such cases.

First, referring to FIG. 22, the controller 180 of the HMD 100 according to an embodiment of the present disclosure may sense a preset user's input while playing back the selected content. For example, the preset user's input may be a preset user's head movement sensed through the HMD 100, a movement of the mobile terminal 200, or the like, as described with reference to FIG. 21.

Accordingly, as shown in the first drawing of FIG. 22, when a gesture in which the user turns his or her head in a leftward direction and a rightward direction is sensed, it may be sensed as the preset user's input. Then, the controller 180 may display information on at least one function executable in the mobile terminal 200 on the display unit 151 of the HMD 100 in response to the user's input.

The second drawing of FIG. 22 illustrates such an example. Referring to FIG. 22, the second drawing of FIG. 22 shows an example in which graphic objects 2210, 2212, 2214, 2216 corresponding to each function executable in the mobile terminal 200 are displayed on the screen 2200 of the display unit 151 on which the currently selected content is displayed. For example, when the functions executable in the mobile terminal 200 include a call function, a message function, a camera function, and a camcorder function, a first graphic object 2210 corresponding to the calling function of the mobile terminal 200, a second graphic object 2212 corresponding to the message function, a third graphic object 2214 corresponding to the camera function, and a fourth graphic object 2216 corresponding to the camcorder function may be displayed on the display unit 151 of the HMD 100.

In this state, the controller 180 may select any one function according to the user's selection. For example, the controller 180 may display any one of the graphic objects 2210, 2212, 2214, 2216 in a distinguished manner based on the user's head movement or the movement of the mobile terminal 200 sensed through the HMD 100 or the user's touch input sensed in the mobile terminal 200 in a state as shown in the second drawing of FIG. 22. The third drawing of FIG. 22 shows an example in which the second graphic object 2212 is displayed in a distinguished manner according to the user's input.

On the other hand, as shown in the third drawing of FIG. 22, in a state in which one of the graphic objects is displayed in a distinguished manner, the controller 180 may execute a specific function of the mobile terminal 200 corresponding to the displayed graphic object. For example, when the display is maintained for the same graphic object for more than a preset period of time, or when another preset user's input of is sensed, the controller 180 may execute a function corresponding to the graphic object currently displayed in a distinguished manner on the mobile terminal 200.

For example, when the second graphic object 2212 is displayed in a distinguished manner as shown in the third drawing of FIG. 22, the controller 180 may control the mobile terminal 200 to execute a function corresponding to the second graphic object 2212, that is, a message function, in the mobile terminal 200. Furthermore, image information 2220 for a message function executed in the mobile terminal 200 may be received from the mobile terminal 200 and displayed on the display unit 151 of the HMD 100. The fourth drawing of FIG. 22 illustrates an example in which an execution screen 2220 of a specific function (message function) of the mobile terminal 200 selected by the user is displayed on the display unit 151 of the HMD 100.

On the other hand, as shown in FIG. 22, the controller 180 of the HMD 100 according to an embodiment of the present disclosure may of course immediately execute a specific function of the mobile terminal 200 corresponding to a specific user's input instead of displaying functions executable in the mobile terminal 200 according to the user's input.

For example, the specific user's input may be a specific touch input applied through the mobile terminal 200. In other words, when a plurality of touch inputs forming a specific pattern are applied to the touch screen 251, or a drag input forming a specific trace is applied to the touch screen 251, the controller 180 of the HMD 100 may control the mobile terminal 200 to immediately execute a preset function of the mobile terminal 200 corresponding to the specific pattern or the specific trace.

Alternatively, the specific user's input may be a touch input applied to a specific region of the touch screen 251 of the mobile terminal 200. In this case, the controller 180 may partition at least a partial region of the touch screen 251 into a plurality of regions. Furthermore, the plurality of partitioned region may be set to correspond to different functions of different mobile terminal 200, respectively. Accordingly, when the user applies a touch input to any one of the plurality of regions, the mobile terminal 200 may be controlled such that a specific function corresponding to the region is executed in the mobile terminal 200. FIG. 23 illustrates an example of such a case.

In other words, as shown in the first drawing of FIG. 23, when the user applies a touch input 2300 to a specific region of the touch screen 251, one region on the touch screen 251 to which the touch input 2300 is applied may be a region preset to correspond to the message function. Accordingly, the controller 180 of the HMD 100 may control the mobile terminal 200 to execute a specific function corresponding to the touch input 2300, that is, a message function, as shown in the second drawing of FIG. 23. In this case, as shown in the second drawing of FIG. 23, a function executed in the mobile terminal 200, that is, an execution screen 2360 of the message function, may be displayed in at least a partial region of the display unit 151 displayed with a content screen 2350 played back in the HMD 100.

Meanwhile, in the above description, it has been described that when a user's touch input is applied to the touch screen 251 of the mobile terminal 200, a specific function corresponding to a point to which the touch input is applied is executed, but a specific function may of course be executed according to the touch input in a different manner therefrom. For example, the controller 180 may recognize the touch input as a “preset user's input” that is entered when a specific event occurs. In this case, the controller 180 may of course execute a currently occurred event, that is, a function corresponding to currently displayed alarm information, in response to the touch input instead of executing a specific function corresponding to one region on the touch screen 251 in which the touch input is sensed.

On the other hand, in the above description, a touch input applied to the touch screen 251 of the mobile terminal 200 has been described as an example, but a preset movement (rotation or displacement) of the mobile terminal 200 or a preset user's head movement as well as the touch input may be used as the specific user's input.

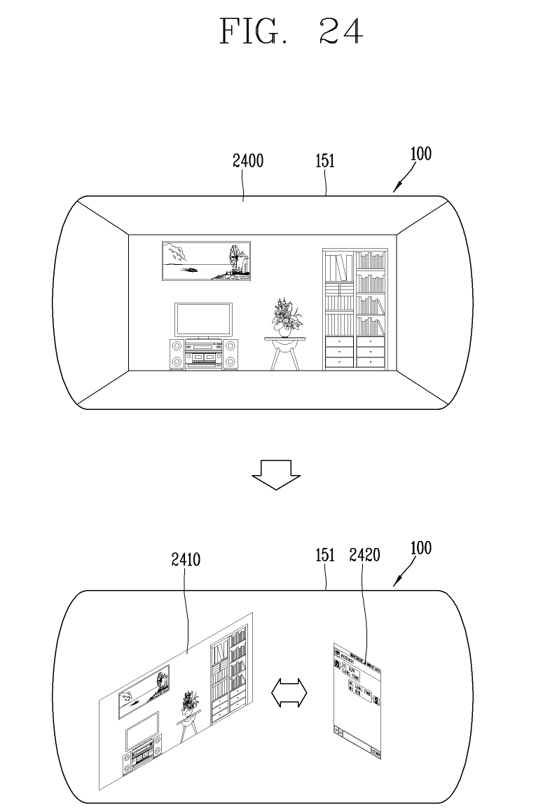

Meanwhile, In the above description, a specific function of the mobile terminal 200 is immediately executed according to an event occurred in the mobile terminal 200 or the user's selection has been described as an example, but on the contrary, the user may of course select either one of content played back in the HMD 100 and the execution of a specific function of the mobile terminal 200. FIG. 24 illustrates an example of such a case.

For example, as shown in the first drawing of FIG. 24, the controller 180 of the HMD 100 according to an embodiment of the present disclosure may display a menu for executing a specific function of the mobile terminal 200 according to the user's selection while a screen 2400 of the content played back in the HMD 100 is displayed on the display unit 251.

For example, as shown in the second drawing of FIG. 24, the controller 180 may display any one graphic object 2410 corresponding to the content played back in the HMD 100 and another graphic object 2420 corresponding to a specific function executed in the mobile terminal 200 on the display unit 151. In this state, the controller 180 may select any one graphic object according to the movement of the HMD 100 or the mobile terminal 200 or the touch input of the mobile terminal 200. In this case, when the user selects the any one graphic object 2410, the controller 180 may maintain a state in which the screen of the content played back in the HMD 100 is displayed on the display unit 151. However, when the another graphic object 2420 is selected, the controller 180 may execute a specific function of the mobile terminal 200 and displays a screen (execution screen) related to the executed function on the display unit 151 of the HMD 100. In this case, the content played back in the HMD 100 may be maintained in a paused state.

On the other hand, as shown in the second drawing of FIG. 24, one graphic object 2410 corresponding to the content played back in the HMD 100 and another graphic object 2410 corresponding to a specific function executed in the mobile terminal 200 may be displayed on the display unit 151 of the HMD 100 in various situations. For example, a user's menu for selecting either one of the graphic objects 2410, 2420, that is, the content played back in the HMD 100 or the specific function executed in the mobile terminal 200, may be displayed when a preset event occurs in the mobile terminal 200. Alternatively, it may be displayed when a preset user's input is sensed. In addition, when a graphic object 2420 corresponding to a specific function executed by the mobile terminal 200 is selected, the controller 180 may execute a currently displayed alarm or a specific function of the mobile terminal 200 corresponding to the preset user's input, and display an execution screen on the display unit 151 of the HMD 100. Alternatively, the functions executable in the mobile terminal 200 may be displayed on the display unit 151 of the HMD 100, as shown in the second drawing of FIG. 22.

On the other hand, it has been described that the HMD 100 according to an embodiment of the present disclosure may allow the user to set a touch recognition region through the touch screen 251 of the mobile terminal 200 when a specific function is executed in the mobile terminal 200 and an execution screen of the specific function is displayed on the display unit 151 of the HMD 100. Furthermore, it has been described that one point corresponding to a touch input point sensed in the touch recognition region on the execution screen of a function of the mobile terminal 200 displayed on the display unit 151 of the HMD 100 can be displayed in a distinguished manner.

FIG. 25 is an exemplary view illustrating an example of allowing the HMD 100 according to the embodiment of the present disclosure to display a touch input sensed through a region set in the mobile terminal 200 on the display unit 151 of an HMD 100.

First, referring to the first drawing of FIG. 25, the first drawing and the second drawing of FIG. 25 show an example in which the user's drag input 2500 and 2510 is applied to the touch screen 251 of the mobile terminal 200. In addition, as shown in the first drawing and the second drawing of FIG. 25, when the user's drag input 2500 and 2510 is applied, the controller 180 may set at least partial region 2520 on the touch screen 251 as a “touch recognition region” according to the applied drag input. Here, the “touch recognition region” may be a region preset by the user to apply a touch input for controlling a function executed in the mobile terminal 200, and may be formed in at least a part of the region of the touch screen 251.

Accordingly, the controller 180 may set one region 2520 on the touch screen 251 formed according to the user's drag input as the “touch recognition region.” Then, the controller 180 may match the set touch recognition region 2520 with an execution screen 2560 currently executed in the mobile terminal 200. In other words, the controller 180 may allow each part of the touch recognition region 2520 to correspond to each part of the execution screen 2560.

In this state, the controller 180 may sense the user's touch input 2530 applied to the touch recognition region 2520, as shown in the third drawing of FIG. 25. Then, as shown in the fourth drawing of FIG. 25, the controller 180 may display one point 2570 corresponding to a touch input point of the touch recognition region 2520 in a region on the display unit 151 of the HMD 100 on which the execution screen 2560 is displayed, in a distinguished manner. Besides, according to the touch input 2530, a thumbnail image 2562 corresponding to the touch input 2530 applied to the touch screen 251 may be displayed in a distinguished manner. On the other hand, according to the above description, it has been described that the shape of an execution screen displayed on the display unit 151 of the HMD 100 can be changed according to the touch recognition region in the HMD 100 according to an embodiment of the present disclosure.

FIG. 26 is an exemplary view illustrating an example of adjusting a size and shape of an execution screen of the specific function displayed on the display unit 151 of the HMD 100 according to a touch recognition region set through the mobile terminal 200 in the HMD 100 according to the embodiment of the present disclosure.

First, the first drawing of FIG. 26 illustrates in which an execution screen 2610 of a specific function (for example, a message function) executed in the mobile terminal 200 is displayed in one region 2600 on the display unit 151 of the HMD 100. In this state, the controller 180 may form a touch recognition region based on the user's drag input applied through the touch screen 251 of the mobile terminal 200.

In other words, as shown in the second drawing and the third drawing of FIG. 26, when the drag inputs 2620, 2630 are applied through the touch screen 251, the controller 180 may form a touch recognition region 2650 according to the drag inputs 2620, 2630 on the touch screen 251 of the mobile terminal 200.

Besides, as shown in the third drawing of FIG. 26, when the touch recognition region 2650 is formed, the controller 180 may change the shape of the execution screen 2610 to correspond to the shape of the touch recognition region 2650. In other words, as shown in the third drawing of FIG. 26, when the currently generated touch recognition region 2650 is formed with a rectangular shape having a larger length in a horizontal direction than that in a vertical direction, the controller 180 may change the shape of the execution screen 2610 according to the shape of the formed touch recognition region 2650. Therefore, if it is in a state that the execution screen 2610 prior to forming the touch recognition region 2650 is formed in one region 2600 on the display unit 151 having a larger length in a vertical direction than that in a horizontal direction as shown in the first drawing of FIG. 26, the controller 180 may display the execution screen 2610 in one region 2660 on the display unit 2660 having a larger length in a horizontal direction than that in a vertical direction according to the shape of the formed touch recognition region 2650. The fourth drawing of FIG. 26 illustrates such an example.

Meanwhile, in the above description, it has been described that while the execution screen of a function executed in the mobile terminal 200 is displayed on the display unit 151, the content played back in the HMD 100 can be maintained in a paused state, but the playback of the content may be continuously maintained regardless of the display of the execution screen. For example, the controller 180 may of course display an execution screen of a function executed in the mobile terminal 200 in a partial region of the virtual space currently displayed through the HMD 100. Accordingly, the controller 180 may of course control a function executed in the mobile terminal 200 based on a touch input sensed through the mobile terminal 200, and display an execution screen of the controlled function in the execution screen region (a region of the virtual space in which the execution screen is displayed). In addition, it is needless to say that the content can be continuously played back in the HMD 100 without pausing to allow the user to view the content played back in the HMD 100 through another region of the virtual space. In this case, the user may selectively check a content screen played back in the HMD 100 or an execution screen of a function executed in the mobile terminal 200.

Moreover, in the above description, it has been described as an example that only one of functions executable in the mobile terminal 200 is executed, but the present disclosure is not limited thereto. In other words, a plurality of functions may be executed at any time, and execution screens corresponding to the plurality of functions, respectively, may be displayed on the display unit 151 of the HMD 100, respectively. Besides, in this state, when a touch recognition region is formed on the touch screen 251, the controller 180 may control any one of the execution screens according to a touch input sensed in the formed touch recognition region. Alternatively, the displayed shape of all the execution screens or at least one of the execution screens according to the user's selection may of course be changed according to the shape of the formed touch recognition region.

On the other hand, in the above description, it has been described as an example that only one touch input is applied to the touch screen 251, but the controller 180 may of course sense a plurality of touch inputs applied to the touch screen 251. In this case, the controller 180 may perform a specific function according to all of the plurality of touch inputs, or control the mobile terminal 200 such that different functions corresponding to the plurality of touch inputs are carried out.

On the other hand, in the above description, it has been described that the shape of an execution screen displayed on the display unit 151 of the HMD 100 can be changed by a touch recognition region formed on the touch screen 251 of the mobile terminal 200, but a size of the execution screen may also be changed. For example, the controller 180 may sense a preset user's touch input gesture on the touch screen 151, and enlarge or reduce a size of the execution screen according to the sensed touch input gesture. For example, the preset touch input gesture may be a pinch-in gesture or a pinch-out gesture.

In other words, when the user applies the pinch-in gesture to the touch screen 251 of the mobile terminal 200, the controller 180 may enlarge a size of the execution screen displayed on the display unit 151 of the HMD 100. On the contrary, when the user applies the pinch-out gesture to the touch screen 251 of the mobile terminal 200, the controller 180 may also reduce a size of the execution screen displayed on the display unit 151 of the HMD 100. Herein, the pinch-in or pinch-out gesture may of course be applied within the touch recognition region, or may be applied regardless of the touch recognition region.

On the other hand, in the above description, it has been disclosed that a user's control instruction input is restricted in the mobile terminal 200 when content is played back in the HMD 100, and the state in which the user's control command input is restricted is released only when there is a specific user's input again. However, the specific user's input may be a user input such as a user's input for selecting any one of functions executable in the mobile terminal 200, or a user's input for displaying a list of functions executable in the mobile terminal 200 on the display unit 151.

In this case, when the preset user's input is sensed, the controller 180 may switch the mobile terminal 200 from an inactive state to an active state while at the same time controlling the mobile terminal 200 to execute a specific function according to the preset user's input, the state of the mobile terminal 200 may of course be immediately switched to a state in which the control command input restriction is released without additionally performing an input for releasing the state in which the control command input is restricted.

The foregoing present disclosure may be implemented as codes readable by a computer on a medium written by the program. The computer-readable media includes all types of recording devices in which data readable by a computer system can be stored. Examples of the computer-readable media may include ROM, RAM, CD-ROM, magnetic tape, floppy disk, and optical data storage device, and the like, and also include a device implemented in the form of a carrier wave (for example, transmission via the Internet). In addition, the computer may include the controller 180 of the electronic device. The foregoing embodiments are merely exemplary and are not to be considered as limiting the present disclosure. The scope of the invention should be determined by reasonable interpretation of the appended claims and all changes that come within the equivalent scope of the invention are included in the scope of the invention.

What is claimed is:

1. An head mounted display (HMD) device connected to a mobile terminal, the HMD comprising:
a communication unit configured to perform wired or wireless communication with the mobile terminal;
a display unit configured to display image information;
a sensing unit configured to sense a movement of the HMD; and
a controller configured to control the display unit to display image information controlled according to a result of sensing the movement of the HMD,
wherein the controller controls the display unit to display image information controlled according to a movement sensed by the mobile terminal when any one of preset situations occurs, and controls the display unit to display image information controlled according to a movement of the HMD when the occurred situation is ended.

2. The HMD device of claim 1, wherein the display unit displays an image of a virtual space according to previously stored content, and
the controller controls the display unit to display an image corresponding to a specific region of the virtual space according to a result of sensing the movement of the HMD, and controls the display unit to display an image corresponding to another region of the virtual space, around an image of the virtual space displayed according to the movement of the HMD, according to a user input sensed from the mobile terminal when a specific situation is sensed, and controls the display unit to display an image of the virtual space controlled according to the movement of the HMD when the sensed specific situation is ended.

3. The HMD device of claim 2, wherein the controller displays a menu screen for allowing a user to select an input for controlling an image of a virtual space displayed on the display unit on the display unit when the specific situation is sensed, and
the menu screen comprises menus for selecting either one of a movement of a user's head sensed through the HMD and a user input sensed through the mobile terminal or both the movement of the user's head and the user input as an input for controlling an image of the virtual space.

4. The HMD device of claim 3, wherein the controller displays either one menu according to the movement of the user's head sensed through the HMD or the user input sensed through the mobile terminal to be distinguished from the other menus, and controls an image of a virtual space displayed on the display unit according to a control method corresponding to the either one of the menus displayed in a distinguished manner.

5. The HMD device of claim 2, wherein when the specific situation is sensed, the controller displays information on devices that control an additional graphic object or the displayed image of the virtual space on the displayed image, and indicates that the HMD is in a state where an image corresponding to another region of the virtual space is displayed based on both the user's head movement sensed by the HMD and the user input sensed by the mobile terminal.

6. The HMD device of claim 2, wherein the user's input sensed through the mobile terminal is at least one of a drag input applied to a touch screen of the mobile terminal or an angular velocity or acceleration sensed by the mobile terminal.

7. The HMD device of claim 2, wherein the controller controls the display unit to display an image corresponding to another region of the virtual space according to the user's head movement sensed by the HMD or the user input sensed through the mobile terminal, based on a specific region preset to correspond to a forward direction of the HMD among regions of the virtual space, and changes a preset specific region according to a user's selection to correspond to the forward direction of the HMD.

8. The HMD device of claim 1, wherein the display unit displays image information of content previously stored in the mobile terminal, and
the controller displays image information controlled according to a result of sensing the movement of the HMD, executes a specific function of the mobile terminal according to a user's selection, displays a screen related to the execution of the specific function controlled according to a user input sensed through the touch screen of the mobile terminal on the display unit, controls the mobile terminal to restrict a user's control signal input when the image information of the content is displayed on the display unit, and controls the mobile terminal to release the restricted user's control signal input when a specific user's input is sensed.

9. The HMD device of claim 8, wherein the specific function is a function corresponding to an event occurred in the mobile terminal or a function selected according to a preset user's input among functions executable in the mobile terminal.

10. The HMD device of claim 9, wherein, when the preset user's input is sensed, the controller displays graphic objects corresponding to functions executable in the mobile terminal, respectively, on at least a part of the display unit, and
the specific function is a function corresponding to any one of the graphic objects selected by a user.

11. The HMD device of claim 9, wherein the touch screen of the mobile terminal is partitioned into a plurality of regions set to correspond to a plurality of different functions executable in the mobile terminal, respectively, and
the specific function is a function corresponding to any one of the plurality of regions in which the touch input is sensed.

12. The HMD device of claim 8, wherein the controller displays one point on the display unit corresponding to one point on the touch screen at which the touch input is sensed, on which a screen related to the execution of the specific function is displayed, in a distinguished manner, and determines that the touch input is applied to the one point displayed in a distinguished manner to control a function executed in the mobile terminal.

13. The HMD device of claim 12, wherein when a touch object that applies the touch input to the touch screen approaches within a predetermined distance from the touch screen, the controller senses the touch object, and displays a position of the sensed touch object on a screen related to the execution of the specific function.

14. The HMD device of claim 12, wherein the controller sets one region on the touch screen of the mobile terminal as a touch recognition region according to a user's input, and sets each part of the touch recognition region to correspond to each part a region on the display unit displayed with a screen related to the execution of the specific function, and displays one point on the display unit displayed with a screen related to the execution of the specific function corresponding to one point in the touch recognition region in which the touch input is sensed, in a distinguished manner.

15. The HMD device of claim 14, wherein when a touch recognition region is set on the touch screen, the controller changes the shape of a screen related to the execution of the specific function displayed on the display unit according to the shape of the set touch recognition region.

16. The HMD device of claim 1, wherein the controller senses a case where a preset user's touch input is sensed on the touch screen of the mobile terminal or a specific touch input gesture is sensed through the mobile terminal as an event that the preset situation has occurred, and senses a case where a specific function executed according to the preset user's touch input or the specific touch input gesture is ended or the preset user's touch input or the specific touch input gesture is sensed again as an event that the occurred situation is ended.

17. The HMD device of claim 16, wherein the mobile terminal operates in a doze mode when connected to the HMD, and
the doze mode is an operation state capable of sensing at least one of a touch input applied to the touch screen of the mobile terminal and a movement of the mobile terminal while a light emitting device of the touch screen of the mobile terminal is off.

18. The HMD device of claim 1, wherein the controller further senses a case where specific image information is displayed on the display unit or the remaining amount of power of the HMD is less than a preset level as an event that any one of the preset situations has occurred, and senses a case where the display of the specific image information is ended or the remaining amount of power of the HMD is above the preset level as an event that the occurred situation is ended.

19. The HMD device of claim 18, wherein the specific image information corresponds to a specific graphic object, and
the controller displays the specific image information corresponding to the specific graphic object on the display unit when a user gazes at one region on the display unit displayed with the specific graphic object for more than a predetermined period of time.

20. A method of controlling a head mounted display (HMD) connected to a mobile terminal, the method comprising:
displaying image information related to selected content on a display unit provided in the HMD;
sensing a user's head movement through a sensor provided in the HMD;
controlling image information displayed on the display unit according to the sensed movement;
sensing an occurrence of a preset situation;
sensing a movement of the mobile terminal based on the occurred specific situation;
controlling image information displayed on the display unit according to the sensed movement of the mobile terminal; and
controlling image information displayed on the display unit based on a movement sensed through the HMD when an end of the preset situation is sensed.
